(19) United States
(12) Patent Application Publication
(10) Pub. No.: US 2025/0015083 A1
(43) Pub. Date: Jan. 9, 2025

(54) Shallow Buried Guard Ring (SBGR) Isolation Structures and Fabrication Models to Enable Latchup Immunity in CMOS Integrated Circuits Operating in Extreme Radiation Environments and Temperatures Ranges

(71) Applicant: Wesley Harold Morris, Austin, TX (US)

(72) Inventor: Wesley Harold Morris, Austin, TX (US)

(21) Appl. No.: 18/706,367

(22) PCT Filed: Oct. 31, 2022
(86) PCT No.: PCT/US22/79006

§ 371 Date: Apr. 30, 2024

(51) Int. Cl. H01L 27/092; H01L 29/06; H01L 29/16; H01L 29/78

(52) U.S. Cl. CPC H01L 27/0921; H01L 27/0928; H01L 29/0623; H01L 29/16; H01L 29/78

(57) ABSTRACT

A CMOS inverter modified by implementing p-type doping regions in the inverter layout and during semiconductor wafer manufacturing creating a novel low resistivity shunt region in PWELLs preventing parasitic thyristor diodes from forward bias and eliminating latchup triggering. Latchup trigger can only occur when all thyristor diodes forward biased thereby establishing the parasitic current flow causing latchup. As voltage scales lower and temperature increases, latchup trigging doesn't recover and leads to a “non-destructive stuck state” in addition to catastrophic latch-up. The root cause of latch-up is high resistivity PWELLs. Shallow Buried Guard Ring (SBGR) doping application is a novel solution that solves the “stuck state” and prevents latchup thereby enabling digital circuits to operate in the most extreme environments without latching up and can be integrated without redesigning and through retrofit in commercial CMOS as well as in solar power procurement through photovoltaic cells.

### CROSS-REFERENCE TO RELATED APPLICATIONS

U.S. Provisional Patent Application No. 63/274,363 filed Nov. 1, 2021 PCT Application No. PCT/US22/79006 filed Oct. 31, 2022

### FEDERALLY SPONSORED RESEARCH OR DEVELOPMENT

Non-Applicable

### SPECIFICATION

### Field of the Invention

The present invention relates generally to integrated circuit wafer production through CMOS (Complementary Metal Oxide Semiconductor) fabrication, using PWELL technology, whereby a Shallow Buried Guard Ring (SBGR) structure is created using multiple boron implants, masked over a photoresist, to form a high concentration P+ doped region within each PWELL region. Specifically, this manufacturing process uses masking and multiple ion implants, implanted with high and lower implant energies suitable for forming low resistivity (P-type) doping regions, that reduce silicon resistivity in PWELL regions formed in CMOS integrated circuit layouts and minimizes (i.e., controls) ion implant defects, thereby forming a high current conduction region, low R current divider within the PWELL region, enabling high current conduction thus preventing excess transient current from biasing the local potential more positively within the PWELL region.

### SUMMARY OF THE INVENTION

Shallow Buried Guard Ring (SBGR) relates to forming novel P-type doping regions (multiple structural shapes and sizes) within P-type doping regions or into PWELL regions of any distinct shape related to implementation into the CMOS or COS-MOS (complementary-symmetry metal-oxide-semiconductor) integrated circuit layout (non-invasively) by implementing high dose/high energy ion implants, using masking and high temperature annealing, to dissolve implant defects. This can be done only during the wafer manufacturing process at a CMOS generation node. SBGR can be implemented into all types of integrated circuit (IC) devices and will make each type of CMOS IC device latchup immune to both overvoltage and radiation transient upsets while operating in high or low temperature extreme environments within a wide range of temperatures (−55° C. TO >250° C.) and ambient radiation environments simultaneously. IC devices with SBGR implemented will not permanently upset and cannot be destructively “latched up” (i.e., short circuited via the creation of a low-impedance path between the power supply rails of a MOSFET circuit) which can be a single latchup event or a plurality of events leading to malfunction or complete destruction due to overcurrent.

SBGR can be (non-invasively) integrated into any CMOS device type, subcircuit or inverter design layouts in P-type silicon regions. The Shallow Buried Guard Ring (SBGR) is implemented into a silicon wafer and IC device during the manufacturing process using masking and multiple ion implants that are implanted with (high and lower implant energies) boron implant dosing suitable for forming low resistivity (P-type) doping regions that reduce silicon resistivity in PWELL regions formed in any CMOS integrated circuit layouts and minimize (controls) ion implant defects.

The SBGR structure is formed using multiple boron implants, with masking for each boron implant, to form a high concentration P+ doped region within PWELL regions in order to lower resistivity in specific regions (e.g., low doped isolation PWELL regions) that are non-invasive to NMOS transistor doping specifically forming a high current conduction region that lower the resistivity below the other PWELL regions even with decreased and increased temperatures. SBGR forms a low resistivity conducive shunt region and forms a low R current divider within the PWELL which enables high current conduction to PWELL VSS preventing excess transient current from biasing the local potential more positively within the PWELL region due to self-bias (dV)=(dI)*R where the forward bias of the N+/P− diode is proportional to the Resistivity (current path) to the VSS (supply ground voltage) terminal in PWELL and will thereby preventing activation of the Thyristor and latch up triggering in CMOS devices of any generation at low temperature and extreme high temperatures >250° C. where all preventing permanent radiation transient upset at temperatures >25° C. to >250° C. is proven.

Implementing the SBGR doping structure non-invasively into the PWELL region either below the NWELL bottom Xj (or above) will lower the silicon resistivity (within P+ doping masked regions) within the inverter PWELL region and any other IC device for selected PWELL regions in different IC layouts. SBGR is implemented with ion implantation, implant masking which can be implemented into any shape or regions below STI such as, for example, isolation regions. PTAP spacing regions is proven in TCAD simulation characterizations to prevents the forward bias of N+/P− diode from any PTAP and PWELL geometric layout location with or without use of HDBL.

SBGR can be implemented into any silicon Integrated Circuits (IC) type to create a family of high temperature IC devices, CMOS logic, microprocessors, microcontrollers, SRAM, NV memory, BCD, DRAM, FRAM, MRAM, flash, sensors, solar (photovoltaic) cells, solar inverters, ASIC devices of any ITRS generation which use either MOSFET (metal-oxide-semiconductor field-effect transistor) transistors (planar) or finFET (fin field-effect transistor) generation reducing resistivity in PWELL regions increasing hole current conduction especially when operating at high temperature ambient >250° C. to all IC ground terminals (VSS) preventing forward bias of the (N+/P−) diode and activation of the CMOS parasitic thyristor.

### BACKGROUND OF THE INVENTION

Silicon is atomic element #14 and is classified as a semiconductor material because undoped silicon resistivity (ρ) is very high and silicon is therefore a poor conductor. But this can be modified by implementing N and P type dopants (i.e., doping agents) into silicon to create doping regions which can be high or low concentrations and are used to further modify electrical current properties.

Silicon resistivity (doped or undoped) is described in terms of sheet resistance in units of ohm-cm2. Intrinsic silicon resistivity is too high for efficient current conduction but can be made conductive by introducing doping into silicon regions that are N-type dopants (electron negative charge carries) or P type dopants for (positive charge hole mobile carriers) to reduce this resistivity. Doping regions (differential layout regions) are accomplished by masking where dopants are implemented to control where and how much dopant is introduced into silicon regions. Doping can be implemented by chemical deposition diffusions or ion implantation which can be varied to any doping type, concentration or depth as needed to achieve electrical current conduction and/or isolation behavior proportionate to doping density and doping location.

Current conduction in silicon doped regions without diode blocking is in 3 dimensions. Any conduction in PWELL silicon regions depends on doping concentration to lower resistivity and physical sizing (volume) (L×W×H). The electrical current conductance is proportional to doping resistivity, area and length with units of (OHMS/sq) which can be converted to ohmic resistance (magnitude) as proportional to the doping regions length (X). Sheet Resistance refers to electrical current conducted in thin films used by Semiconductor wafer process engineers to measure doping regions during wafer manufacturing to control wafer doping concentrations and is measured to control the dopant uniformity (Sheet RHO) AREA regions (A)=(L*W)=Resistivity expressed as OHMS−SQ.

FIG. 1 is called “sheet Rho” wherein sheet Rho units are OHMS/SQ measured by AREA=L*W in sq meter units or “SQ”. Resistance is an electrical measurement relating to current which is related to (area) geometry (shape/area/depth and doping concentration). Dopant concentration is a measure of silicon doping concentration in silicon doped regions and is called “Resistivity”.

The patterned three-dimensional doped region that conducts electrical current through a silicon doped region is resistance (R) which is the product of sheet Rho multiplied by length (L) and divided by the width of the doping region with units of OHMS wherein R=ρ(L/A). See FIG. 2.

The silicon resistivity in semiconductor devices is controlled by atomic doping implemented during the wafer manufacturing process using various doping methods (deposition+ diffusion or ion implantation) wherein doped regions can be uniquely tailored to create a range of resistivities. NWELL are doped with n-type phosphorous impurities or PWELL doping regions will be doped with P-type boron impurities at lower doped concentrations and MOSFET source/drain diffusions (N+ or P+) diffusion will be highly doped with resistivities closer to metal conductors for MOSFET transistors.

Below are some examples:
Intrinsic (undoped) silicon wafer<1e12) (approx.)=5e3 Ohm/cm highest R
PWELL P− doping CMOS inverter<5e17 (approx.) BORON=2e−1 Ohm/cm high R
NWELL N− doping CMOS inverter<5e17 (approx.) PHOSPHOROUS)=4.5 Ohm/cm
SBGR doping region add to P-WELL>1e19 (approx.)=2e-3 Ohm cm 100× lower R
Aluminum Resistivity=2.82e-6 ohm/cm conductor
Copper Resistivity=1.72e-6 ohm/cm conductor

CMOS isolation wells (i.e., PWELL or NWELL regions) are categorized as “lightly doped regions” wherein, if current is conducted in PWELL regions, it would be characterized as high impedance (resistive to current conductions). Well doping is used to form P/N diodes for MOSFET transistor diffusions and are the electrical active area isolation regions diodes critically important to electrical conductivity as there is no other way to electrically isolate voltage and current without P/N diodes to control shorting and reduce static leakage for the MOSFET transistor or bipolar transistors.

Whenever, a transient upset event occurs (either by electrical overvoltage or an atomic particle passing thru the silicon device) the interaction with silicon causes the release of “excess”+/− mobile charge carriers that create instantaneous current that will flow to the anode or cathode electrical terminal (VDD)/(VSS). Electrons are subatomic and move thru both silicon and silicon dioxide regions and are negative charge carriers. Positive charge carriers are atomic+charge vacancy and are not mobile. Positive current require charge exchanged to migrate positive charge to the ground terminal constituting a much slower process.

Electrical current flow in silicon in electrically charged segments wherein +/− charge carries are polarized (hall current flow) with strong interactions between the charge carrying negative charge (−) carriers (electrons) and positive charge (+) carriers (holes) which seek to recombine and neutralize the excess charge. See FIG. 3.

PWELL regions are formed in Silicon with P-type dopants at low doping concentrations which yield high resistivity values where PWELL regions are used for two main reasons:
Voltage biasing to create reverse-biased diodes (N+ doping diffusion regions) which are associated with MOSFET transistors (also called Source and Drain diffusions); and
N+/P− doping creates a chemical doping junction (diode) that will self-bias to electrically isolate the diffusion region from current conduction the diffusions within PWELL regions.

Positive current (hole current) mobility will be slower to conduct and slower to recover due to high resistivity and poor current conduction in the PWELL regions.

High PWELL resistivity is the critical factor that contributes to latchup triggering in CMOS Integrated Circuits (ICs).

Pointedly, resistivity also increases with temperature and, when combined with low doping (high resistivity at 25° C.), further increases the conduction impedance. This effect reduces the latchup trigger current (increasing risk of latchup). All CMOS devices that operate at temperatures >25° C. are at higher risk of latching up (defined by a short circuit in the IC).

### Digital IC Devices

The CMOS inverter is a switch that enables resetting voltage states that can be changed by input bias to set to the output to (0V=VSS) representing a binary “0” data bit value or to supply voltage (VDD) to depicted as binary “1” data bit value and can be written or read by switching the input voltage between VSS to VDD. Multiple inverters are used in CMOS digital devices to form larger logic gates and operating instructions executed by the CPU as digital bytes or 64 bit (word) code which creates instruction commands based on Boolean logic to create the software operating systems and instruction code for programing logic processors controlled and executed by microelectronic circuits and devices. See FIG. 4 showing the CMOS inverter described in an “electrical schematic form” as an example of typical schematic descriptions.

CMOS IC circuits however are implemented in bulk silicon material (wafers) and cannot be fully enabled with metal interconnect (alone) layout or described by voltage, current behavior and spice models.

CMOS inverters include many different silicon discrete components such as (transistors (MOSFET or bipolar), isolation well regions (NWELL and PWELL) by dopant type, transistor diffusion regions, gate electrodes, contact regions for power and ground, capacitors, inductors, resistors, and P/N diodes withing the inverter layouts which are used in larger cells implemented from a cell library which describes subcircuits made from the inverters forming subcircuits layouts that make up for the IC design and are connected with the metal interconnects.

FIG. 5 is a silicon cross section of an CMOS inverter pair active area and well doping regions than implement a high resistivity NWELL and PWELL silicon doping regions that inadvertently form the CMOS parasitic thyristor (multiple P/N diode network). FIG. 5 also shows a CMOS inverter (SRAM) Pair formed with discrete elementals and well isolation regions that are designated within IC schematic layout overlaid and listed of silicon discrete components on the left side of FIG. 5. The entire CMOS Inverter silicon region is electrically isolated by multiple P/N junction diodes which can be forward biased or reversed biased to block current and are used to control current flow within the “silicon regions” as intended by the chip design. These regions are sensitive to latchup failure that can be caused by signal overvoltage (clocking errors) or operation in extreme environments such as radiation and high temperature.

### SUMMARY

“Latchup” or “Latching-up” is an electrical short circuit within silicon doping regions which can electrically connect power (VDD) and ground (VSS) which is caused by electrical transients that accidentally forward bias the 3 critical blocking diodes (highlighted in FIG. 6) and is unintendedly implemented in CMOS inverters which makeup the foundation logic for CMOS devices. The PNPN thyristor (See FIG. 6), if activated, can destroy the CMOS device and/or cause loss of data. Expressly, FIG. 6 shows the 3 junction diodes that form the thyristor forward biasing wherein all three junction diodes are activating current conduction between the positive and ground terminals. In CMOS devices thyristor diodes are formed by the silicon doping regions associated with MOSFET transistors and well isolation regions with semiconductor naming conventions (NWELL, PWELL, N-diffusions, P-diffusions, P/N diodes and the like) which collectively form the three critical diodes of a thyristor that interact electrically from biased diodes formed by the doping junctions (Xj) which are also elements of bi-polar transistors, PNP and NPN that are implemented in CMOS Inverters.

Well isolation regions are formed from opposite dopants (P+ and N− and N+ and P−) wherein doping types are used to form the MOSFET diffusion regions in the “Active Areas” (i.e., silicon regions) surrounded by dielectric oxide regions (Shallow Trench Isolation (STI)) which dielectrically isolate the silicon active electrical biased areas where the MOSFET transistors are formed from other integrated circuits into device layouts connected to power and ground terminals by metal interconnect layers to form the CMOS inverter and Integrated Circuits.

FIG. 7 shows a commercial CMOS inverter layout depicting an inverter pair (2 inverters with single PWELL VSS contact PTAP region) at the center of the PWELL REGION with two NWELL doping regions on either side. There are two different MOSFET transistors (NMOS and PMOS transistors in each inverter). All MOSFET transistors implement 2 diffusion regions (source/drain) that form with high doping concentrations for low resistivity high current conduction desired. NMOS transistors Source and Drain regions use N dopants with high concentrations and industry convention is =N+ diffusion. PMOS transistors are similar but opposite doping types use P+ doping referred to as P+ diffusions. MOSFET S/D doping regions requires low resistivity to support high current conduction for data thruput clocked by the gate electrode and signals passed thru the transistor to other terminals within the CMOS device which are similar diffusion regions and inverters.

CMOS digital architecture is based on inverter switching (0 and 1) data in a silicon active area which are biased well regions to keep the junction diodes in reverse bias blocking current leakage to maintain reverse static bias. VDD is the symbolic used for Positive bias and VSS refers to the ground terminal (V=0).

NWELL and PWELL regions are lightly doped to form P-type and N-type doping regions that are butted diodes (n−/p−) formed by low doping concentrations which are suitable for static biasing but with doping insufficient for current conduction. As well, silicon regions are high resistivity regions and a poor current conductors.

FIG. 8 highlights a Commercial CMOS inverter designating the 3 unintended diode types encircled, dashed ellipses at static bias. All three junction diodes P+/N− for PMOS transistors (signified as circled, dashed Area 8a) and the N−/P-well junction diode for NWELL/PWELL butted regions (designated as circled, dashed Area 8b) and the N+/P− diode highlighted (designated as Area 8c) for NMOS transistor diffusions in reverse bias. All three diode types normally will operate in reverse bias whenever voltage is applied in varied or current is increased. If these diodes remain reversed biased, the diodes electrically block current conduction to all other regions outside the diode diffusion and is the basic static electrical isolation architecture for operating CMOS devices reliably.

FIG. 9 details the location of the three thyristor diodes numbered J₃, J₂ and J₁ shown in FIG. 8. Prior to upset events (overvoltage or SEU transients) all thyristor diodes operate in reverse bias (normal mode) and current flow restricted to MOSFET transistor diffusion regions and metal circuit design. Both PWELL and NWELL regions are lightly doped with high resistivity optimized for biasing, not current conduction.

The three critical diodes (P+/N−, or N−/P− or N+/P−) in FIG. 8 and FIG. 9 form the parasitic thyristor within the CMOS inverter that are independent discrete diodes “built in” to the inverter layout that cannot be removed or “designed out” of the CMOS inverter. The semiconductor industry refers to this defect as the “CMOS parasitic Thyristor” which, if forward biased, electrically shorts the power and ground terminals causing permanent destructive damage or nondestructive permanent latchup failure that can disable the circuit functionality during operations and requires power cycle(s) to restore operation.

The CMOS inverter is used in a digital circuit to switch voltage states at the inverter reference node from (digital 1=high voltage to a digital 0=ground voltage) that represent digital data clocked within the IC logic subcircuits that are integrated and implemented in IC devices. All inverters forming the PNPNP parasitic can trigger into latchup due to overvoltage upset or radiation transient upset at any time that will either destroy the IC device or corrupt the digital data when upset by a signal overvoltage clocking error or when exposed to “extreme environments” such as radiation and/or extreme (low or high) temperatures. Increasing temperature causes the silicon resistivity to increase which leads to local potential biasing of the well regions differentially within the well regions. This is the cause of diode forward biasing and is the main failure mechanism in all CMOS devices. The only solution possible to minimize permanent transient upsets and overvoltage failure is to address resistivity within the inverter layouts and fix it.

### DESCRIPTION OF THE RELATED ART

The invention of CMOS integrated circuits has vastly modernized society and revolutionized global communications. CMOS offers highspeed, low power microelectronic semiconductor devices which are the electronic platform for creating systems level devices like computers which can run automated logic, memory, and power management that can be integrated to create vastly automated functionality making up electrical systems on earth and in space for many applications. The IC devices used in these networks require a wide range of semiconductor IC device types, logic, memory, RF, power controller, microprocessors, microcontrollers and other related components to create modern electronic systems.

The CMOS inverter (invented in 1963) was initially used by RCA to manufacture the first integrated circuit used in the “Space Race” in the 1960S and the 1970's. Since that time the semiconductor industry has advanced IC devices by following “Moore's scaling law” with each generation reducing feature size to increase logic gate density. By 2021 leading edge IC devices (e.g., the FINFET transistor) feature sizes having reached 3 nM which are manufactured on 300 mm bulk silicon wafers. CMOS logic still depends on the CMOS inverter which continues to employ a parasitic thyristor (PNPN) and latchup remains a reliability issue in all CMOS devices to this day. Voltage scaling has eliminated destructive latchup, but the persistent non-recovery upsets persist.

High resistivity is the physical property of lightly doped silicon regions (WELLS or well regions) that make PWELLs a poor current conductor that oppose electrical current flow. In Physics materials (atomic elements), electrical properties are classified as related to electrical conduction, insulators, conductors or semiconductors. “Undoped” silicon electrical properties are classified as a semiconductor.

### CMOS Inverter Thyristor Latchup

The CMOS inverter details, first presented in 1963, showed a common gate electrode configuration with complementary (two different) MOSFET transistors (PMOS and NMOS) connected in series which could be programed by a single common gate electrode. This common gate electrode would change the voltage state (Vin) of the inverter data node (P+ source and N+ drain) diffusions to equal VDD positive voltage or VSS zero voltage which was related to a digital value of either 1=VDD or 0=VSS corresponding to the inverter switch state. This inverter enabled developers a way to create digital data values (0 or 1) that could be combined into larger data sets, single bits, (bytes=8 bits and words=multiple bytes) which were volatile but could be written or read into the inverter data node to transmit data.

CMOS inverters are used to program voltage state which are then used to represent digital data (0 or 1) to code a digital bit combining multiple bits to form word data which forms the digital coding matrixed by electrical bit switching signals to create instructions used with Boolean logic to write data or instruction code clocked into and out of CMOS devices forming the basis of the global internet and all mass communications.

The inverter itself is used as a digital data switch, enabling electronic programmability which became the basis of new low power digital logic (complimentary MOSFETS) or CMOS. Using multiple bit logic values in multiples of 4, 8, 16, 32 and 64-bit logic (bit words), instruction code could be written which enabled complex digital control software coding for CMOS electrical devices and systems that could operate at very low power since the inverter standby power (inactive switch) is nearly zero.

CMOS devices are manufactured on bulk silicon wafers and are electrically isolated by P/N diodes. The CMOS inverter (design) inadvertently implements a parasitic thyristor which can be upset under certain conditions that activates a complementary bipolar transistor (NPN and PNP) formed as a thyristor (PNPN) within the inverter layout which could be destructive if inadvertently upset.

Activation of the thyristor is caused by external electrical stimulus which can trigger latchup, for example (1) overvoltage upsets caused by inverter signal switching or mistiming, (2) radiation particle strikes that inject mobile electron/hole carriers (e/h carriers) and/or (3) voltage supply variation (either high or low).

FIGS. 10 and 11 shows overvolt latchup iv typical for bulk silicon commercial CMOS devices in which latchup trigger is initiated due to an overvoltage transient. If the overvoltage reaches maximum value (trigger current), the iv curve (reverse of Moore's Law) current is instead increased as the voltage potential drops (decreases) which represents an electrical short within the silicon body which cannot be controlled with circuit design and remains independent from well and transistors doping regions. Conversely, FIG. 12 shows an alternative bulk silicon inverter which has been implemented with low resistivity shunt regions and does not “trigger” or latchup. This new CMOS device conducts high currents ideally up to >4V (>2.5V over the operating voltage 1.5V) and simulations show that bulk CMOS IC device can be modified and manufactured in a different way than commercial wafer manufacturing process that eliminates the CMOS parasitic using high boron doping concentration into the IC device layout. The CMOS device will thus no longer latchup.

FIG. 13, Commercial Overvolt Test Structure, shows a latchup bench test structure that is used to test latchup (overvoltage) sensitively using diffusion regions (no transistors) of the N+ and P+ diffusions, isolation wells with active area layout spacing that meets the circuit layout specifications at each technology generation in this case 130 nm generation, for the overvoltage test of the NWELL region and P+ diffusion region biased to VDD. The P+ source diffusion is biased to voltage greater than VDD and activates the PNP which increases current (see FIG. 10). PnP current forward biases the N−/P− diode and current is source to the PWELL region. Current flowing from NWELL thru PWELL regions causes (induces) a body bias in the PWELL region more positively which forward biases the N+/Pwl diode. This is the 3^{rd} critical diode which causes latchup trigger. Trigger current is indicated by the IV current negative resistance (inflection change in direction) to track lower voltage even as current increases.

FIG. 14 shows a latchup IV (trigger) curve in which a sequence of diode failures (forward bias) increases current and changes the current and voltage behavior of the inverter test device leading to the latchup trigger IV. Initial overvolt upset current forward biases the P+/N− diode and source current to the Nwl which then forward biases and sources current to the PWELL region. To activate the thyristor requires forward biasing of 3 discrete “J” diodes (unwanted implemented diodes found in inverter as highlighted in FIG. 8). The forward bias (caused by the upset events) can be described as a sequence of incremental diode failure steps that ends with latchup triggering that ramps current to the saturation state and which is a short circuit of VDD to VSS that is most often destructive and a permanent failure.

The CMOS inverter layout shown in FIG. 15 details the 3 diode thyristor which are the P+/Nwl (diode J1), Nwl/Pwl (diode J2), N+dif/Pwl (diode J3) biasing sequence to get to latchup. Data switching (timing miss) causes an overvoltage on the inverter output node which forward biases the P+/N− diode and activates the first parasitic which begins sourcing current as a P/N diode, forward biased, activates the base and now amplifies current as a PNP transistor (emitter current) to the NWELL region forward biasing the NWELL local potential more positively and moving to the next parasitic step (sequenced in FIG. 16).

FIG. 14 CMOS Signal Overvolt Latchup (Trigger) IV diagram shows the current increase (caused by overvolt). This then leads to a 2^{nd} diode forward bias (N−/P−) well diode which activates and begins high current conduction into the PWELL region that causes a dV shift in (body potential) increasing the PWELL Region local potential >+0.5V above of the VSS terminal thus causing the N+/p− diode (NMOS diffusion) to forward bias and completed thyristor activation and launching a CMOS Latchup Trigger Event. Other types of electrical stimulus will result in the same latchup triggering.

One example is Power supply (voltage) variation, Radiation particle strikes, photo carriers (sunlight exposure) and off chip high current signals in the IO's (that case ESD events) can spread to the core circuit region. These are the external stimuluses that inject current and forward bias the thyristor diodes which are further amplified (made worse) by parasitic currents sourced and amplified by the parasitic bipolar pair (either PNP, NPN, or both transistors).

Higher temperature (HT) increases silicon resistivity which exacerbates body bias in PWELL and causes the reduction in latchup trigger current (See FIG. 26). As well, HT effects make timing errors more sensitive to timing failures and increases transient upset recovery times. Manifestly, increases from ambient temperature is a fundament physical effect that inherently increases latchup failure risk.

Activating the thyristor requires forward biasing of 3 discrete diodes (J₁) P+/N−), (J₂) N−/P−) and (J₃) N+/P− (represented as J₁, J₂ and J₃ in FIG. 16), where all must be forward biased to establish a low impedance current conduction (in the silicon body region) between the IC power supply (VDD) terminal (located in NWELL) and isolation by the (well) N−/P− blocking diodes and the ground terminal (VSS) located in PWELL.

Expressly, in FIG. 14, latchup trigger (diode3) signals an ONSET of several possible destructive outcomes, including:
IC electrical burn out (permanent IC device both chip and board loss);
IC data lost (permanent);
IC stuck state (normal functionality disabled until power cycled), data thruput lost;
IC missed instruction data output not transmitted (no-op events) which could be catastrophic if fail safe application; and
excess power dissipation caused by high parasitic current flow due to active non-destructive parasitic currents in the IC core region that cannot be addressed (sensed and controlled), except with power cycle reboot.

High resistivity in the N and P well regions cause a dV local potential (voltage) shift that acts to forward bias the N+/P− diode (last thyristor diode3). The initial overvoltage or radiation events are the initial activating electrical stimulus events in and of themselves are not sufficient to cause latchup in the IC device. Either stimulus will generate excess mobile charge carriers which create excess currents that interact and forward bias the thyristor diodes that activate the parasitic current flow between the blocking diodes, but in time will recombine and recover to the voltage state without causing latchup trigger. However, any increase in the operating temperature increases silicon resistivity which increases the PWELL region resistivity and causes a dV body volt potential shift that reduces the trigger current making latchup more likely to occur during operations when temperature increases above 25° C. The silicon resistivity plot vs temperature plot shown in FIG. 25 shows this effect for silicon resistivity below the PWELL contact regions for a commercial “doped” PWELL vs SBGR “doped” PWELL.

The current path for the thyristor displayed as curved, dashed lines from VDD=+V to VSS=OV in FIGS. 17a and 17b show the commercial current path to latchup illustrating a commercial inverter with active thyristor where all thyristor diodes are forward biased and current flow, where J3 diode is forward biased, and is conducting current thru N+ Diffusion Diode in PWELL To reach VSS. The 2D plot FIG. 17b shows same (latchup current path), illustrated by the circuit schematic view wherein the right plot shows 2D silicon structure overlayed with schematic view with resistor symbols, J₁, J₂, and J₃, depicted in the layout (Rₑₓₜ), overlaid, wherein the pathway from VSS anode to VDD cathode takes the path duly indicated along the “current signal-shaped” pathway as displayed. The CMOS NWELL and PWELL regions act as base regions for the bi-polar (PNP and NPN) transistors that are parasitically present in the CMOS layout. As can be seen in both figures, FIGS. 17a and 17b, where parasitic current doesn't flow thru the external metal interconnect but are conducted thru the silicon regions that are high resistivity because of PWELL low doping and high current impedance and is what causes biasing in the PWELL region static potential (dV).

Once the PNPN thyristor is activated (current mode), the only way to recover and clear the latchup state is to cycle the IC device power (on/off) before the latchup short destroys the IC device.

And while strides have been made in the field of semiconductors and integrated circuits to address the infirmities detailed above, it remains that there are inadequacies that persist in terms of constructing and maintaining a semiconductor, especially in the area of CMOS fabrication and P− well technology, to reduce resistivities in certain silicon regions and enable and facilitate current conduction and allow for operations in the presence of radiation and temperature extremes.

It is therefore the goal of inventor to remediate the deficiencies herein entailed and to provide for a new, novel device and means of overcoming these shortcomings in the prior art as detailed herein.

### BRIEF DESCRIPTION OF THE DRAWINGS

Although the novel features and method of use of the application are set forth above, the application itself, as well as a preferred modes of use, and advantages thereof, will best be understood by referencing to the following detailed description when read in conjunction with the accompanying drawings in view of the appended claims, wherein:

FIG. 1 displays sheet Rho;

FIG. 2 is a three-dimensional representation of a doped region;

FIG. 3 represents current flow in silicon in electrically charged segments;

FIG. 4 is a diagrammatic representation of a CMOS inverter;

FIG. 5 displays a cross-section of a CMOS inverter pair;

FIG. 6 shows a PNPN thyristor;

FIG. 7 depicts a commercial CMOD inverter pair layout;

FIG. 8 illustrates a commercial Bulk CMOS inverter with 3 diode types;

FIG. 9 shows a commercial CMOS inverter with three thyristor diodes;

FIG. 10 is a bulk silicon commercial CMOS exhibiting latchup;

FIG. 11 is a bulk CMOS exhibiting latchup indicating maximum trigger current;

FIG. 12 is a bulk CMOS exhibiting latchup indicating absence of trigger and latchup;

FIG. 13 exhibits a commercial overvolt test structure;

FIG. 14 is a CMOS overvolt latchup denoting current over voltage;

FIG. 15 represents a 3 diode thyristor and forward biasing;

FIG. 16 illustrates forward biasing the NWELL local potential and parasitic movement;

FIG. 17a depicts CMOS commercial path to latchup;

FIG. 17b illustrates a parasitic current to latchup;

FIG. 18 displays a CMOS inverter with SBGR high concentration doping;

FIG. 19 shows a TCAD simulation of a four terminal bias characterization structure;

FIG. 20 shows CMOS inverter layout with SBGR;

FIG. 21 shows a commercial inverter without SBGR;

FIG. 22 illustrates a commercial inverter pair without SBGR;

FIG. 23 shows the inverter pair in FIG. 22 with SBGR implemented;

FIG. 24 illustrates conductivity in the commercial inverters v. the SBGR inverter;

FIG. 25 shows resistivity (ohms/cm²) v. doping increasing at increasing temperatures;

FIG. 26 shows overlay of the CMOS Parasitic Thyristor Diodes with electrical schematic;

FIG. 27 illustrates CMOS overvolt triggering reduction v. temperature;

FIG. 28 shows a commercial inverter biased at VDD;

FIG. 29 illustrates a particle track in a commercial CMOS inverter;

FIG. 30 commercial inverter without region doping;

FIG. 31 SBGR with region doping;

FIG. 32 evidences a commercial inverter with latchup;

FIG. 33 shows commercial inverter latchup at 25° C.;

FIG. 34 is commercial inverter latched up;

FIG. 35 is commercial inverter latchup at 25° C. with current over transient time;

FIG. 36 illustrates SBGR PWELL latchup immune inverter pair;

FIG. 37 shows SBGR region, cutline PWELL region and cutline PTAP region, left to right;

FIG. 38 illustrates a low resistivity, SBGR region below PWL TAP in CMOS inverter;

FIG. 39 shows SBGR layout following a radiation particle strike and current flow to VSS;

FIG. 40 depicts recovery time in nS;

FIG. 41 shows latchup current flow from NWELL (VDD) to PWELL (VSS) “stuck state”;

FIG. 42 shows TCAD simulation of a commercial inverter;

FIG. 43 shows a commercial CMOS inverter without SBGR;

FIG. 44 is the SBGR region implemented in PWELL region and extending below the STI;

FIG. 45 shows SBGR low resistivity region below PWELL tap;

FIG. 46 displays a plot for SBGR inverter upset by radiation particle strike and recovery;

FIG. 47 shows SBGR CMOS recovery at 25° C.;

FIG. 48 shows SBGR CMOS recovery at 125° C.;

FIG. 49 shows SBGR CMOS recovery at 250° C.;

FIG. 50 displays SBGR overvolt at 25° C.;

FIG. 51 displays SBGR overvolt at 250° C.;

FIG. 52 displays SBGR overvolt at 25° C., 125° C. and 250° C.;

FIG. 53 shows SEU radiation strike and local potential increases in PWELL region;

FIG. 54 displays PWELL current with upset recovery;

FIG. 55 depicts SBGR improved PWELL inverter layout, low resistivity doping region;

FIG. 56 shows commercial CMOS inverter with high resistivity region below the PWELL;

FIG. 57 illustrates SBGR v. commercial overvolt;

FIG. 58 displays commercial CMOS overvolt at 25° C., 55° C., 85° C. and 125° C.;

FIG. 59 shows CMOS latchup at 25° C., 85° C., 125° C., 150° C.; 175° C., 200° C., 225° C. and 250° C.;

FIG. 60 shows latchup in a commercial, non-SBGR CMOS inverter;

FIG. 61 is a commercial, non-SBGR CMOS inverter at non-destructive latchup;

FIG. 62 depicts transient upset of an SBGR-implemented inverter at 25° C.;

FIG. 63 illustrates recovery as a function of time 25° C.;

FIG. 64 depicts transient upset of an SBGR-implemented inverter at 250° C.;

FIG. 65 illustrates recovery as a function of time 250° C.;

FIG. 66 is a CMOS parasitic inverter with SBGR shunt;

FIG. 67 shows overvolt IV current with no latchup triggering at 150° C.;

FIG. 68 is a 40 nM commercial CMOS depicting upset recovery;

FIG. 69 shows 40 nM test structure with SBGR below the PWELL contact region;

FIG. 70 illustrates commercial overvolt latchup at 25° C., 85° C., 125° C.;

FIG. 71 depicts commercial overvolt (top) over SBGR (bottom) at increasing temperatures;

FIG. 72 shows commercial 40 nM SEU transient upset 25° C., 125° C., 150° C.;

FIG. 73 is an SEU upset at 20 pS, 250° C.;

FIG. 74 shows terminal currents with SBGR implemented in the PWELL contact regions;

FIG. 75 displays SBGR low resistivity conductance region in the PWELL contact region across temperature ranges 25° C., 85° C., 125° C., 150° C.; 200° C., and 250° C.;

FIG. 76 shows SBGR in Photovoltaic cells (PVC);

FIG. 77 is a PVC anode structure without SBGR doping;

FIG. 78 compares current magnitudes for a SBGR PVC architecture vs commercial PVC;

FIG. 79 shows the simulation of the SBGR PVC quantum efficiency vs solar spectrum wavelengths;

FIG. 80 depicts SBGR PVC vs. commercial PVC.

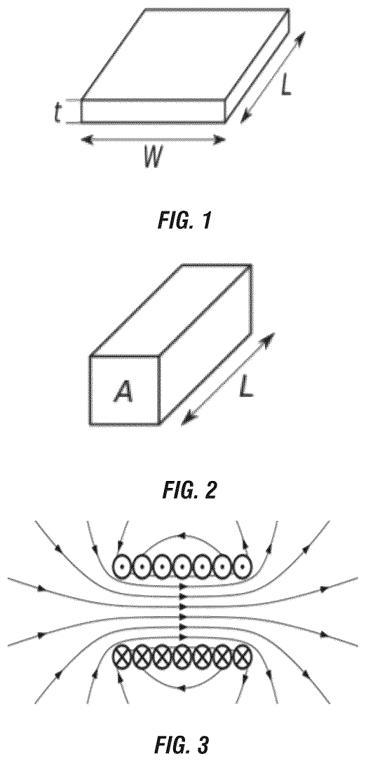

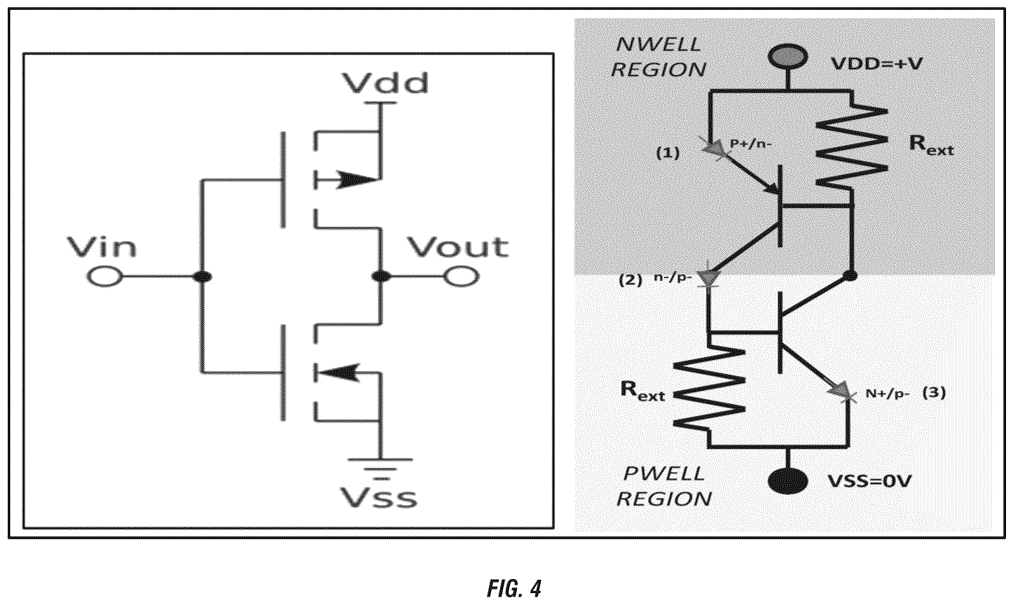

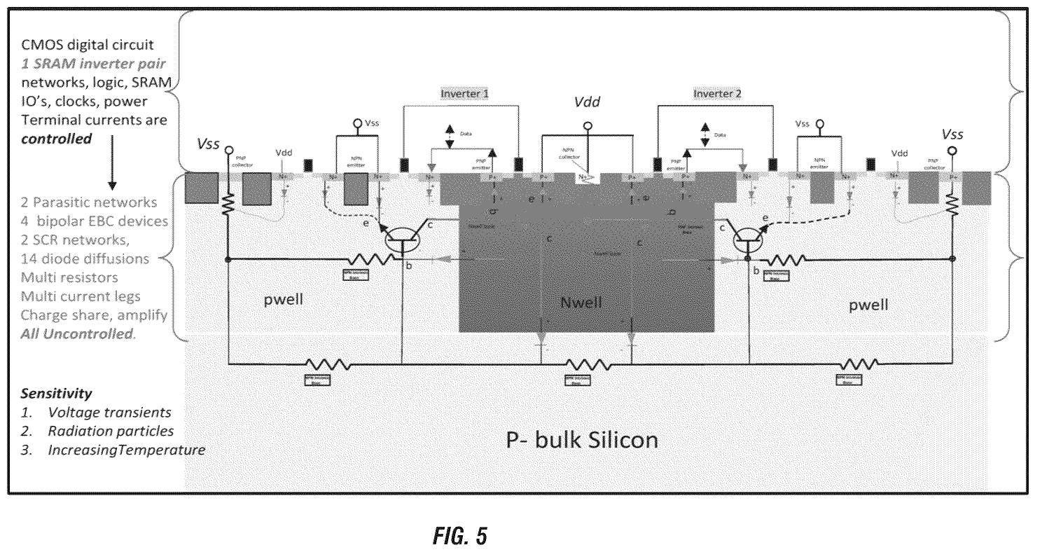

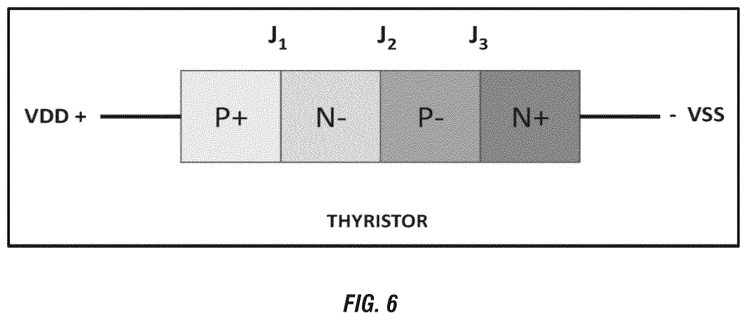

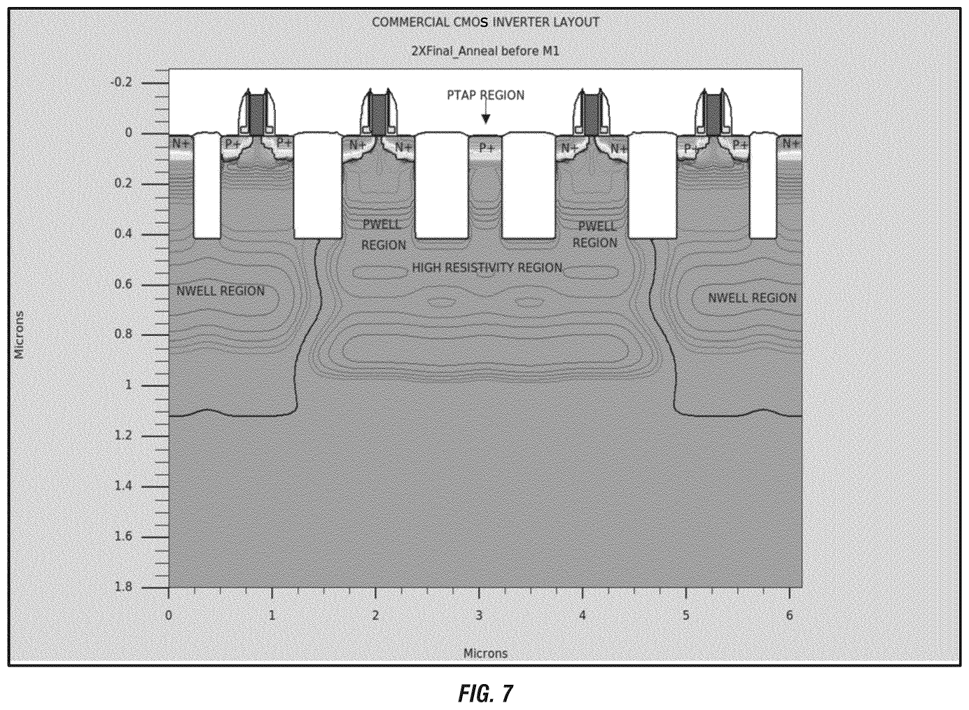

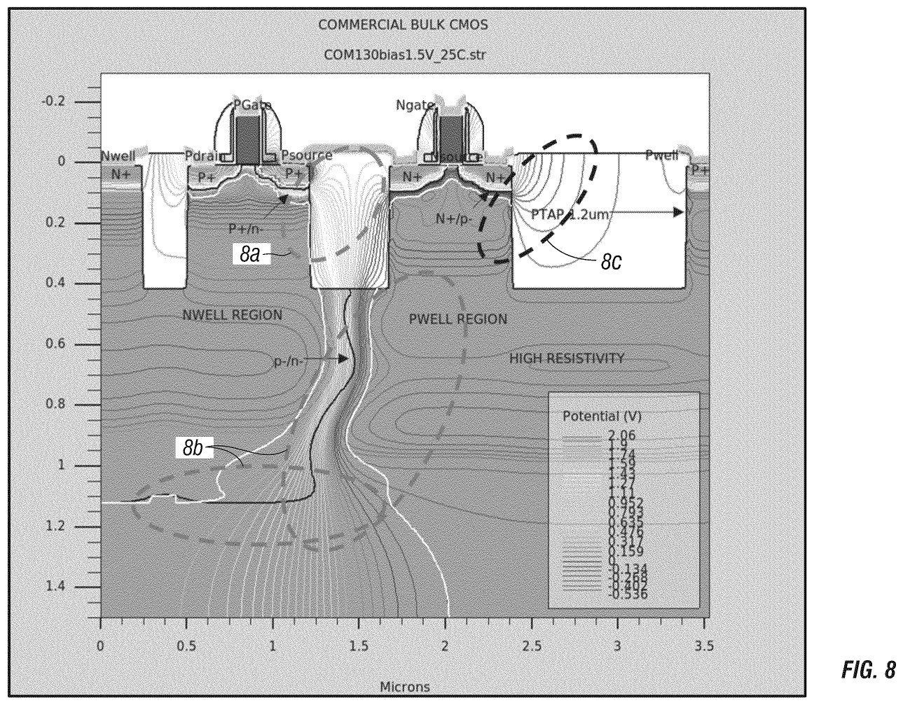

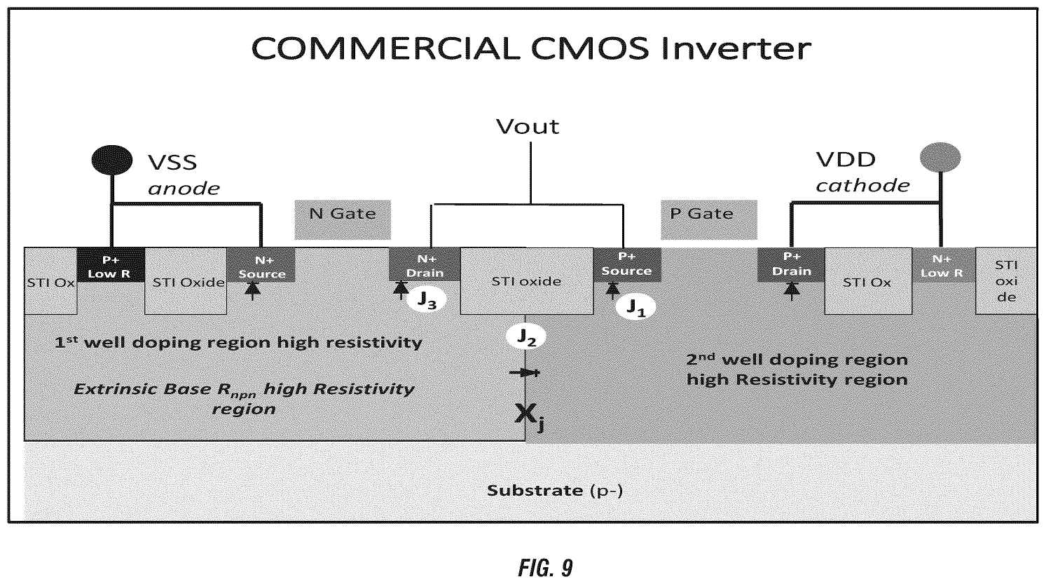

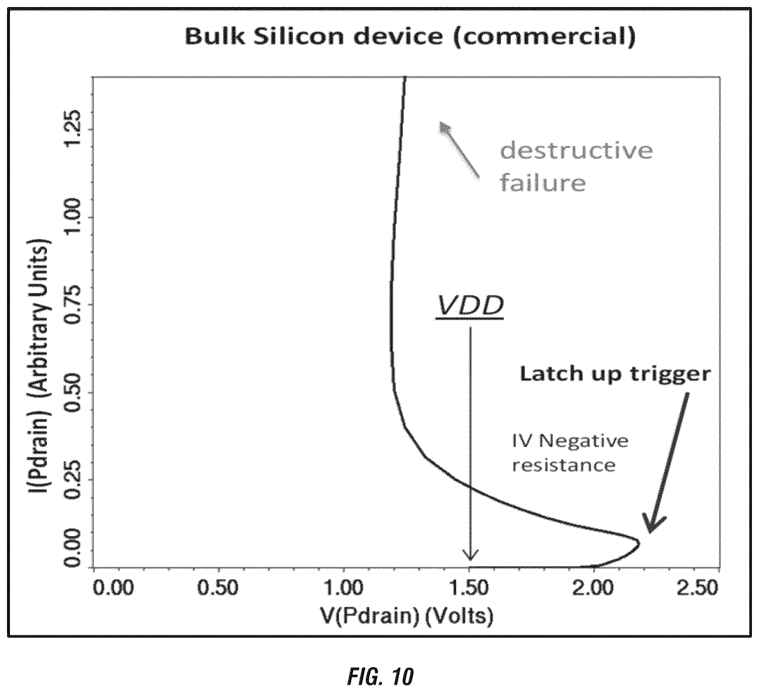

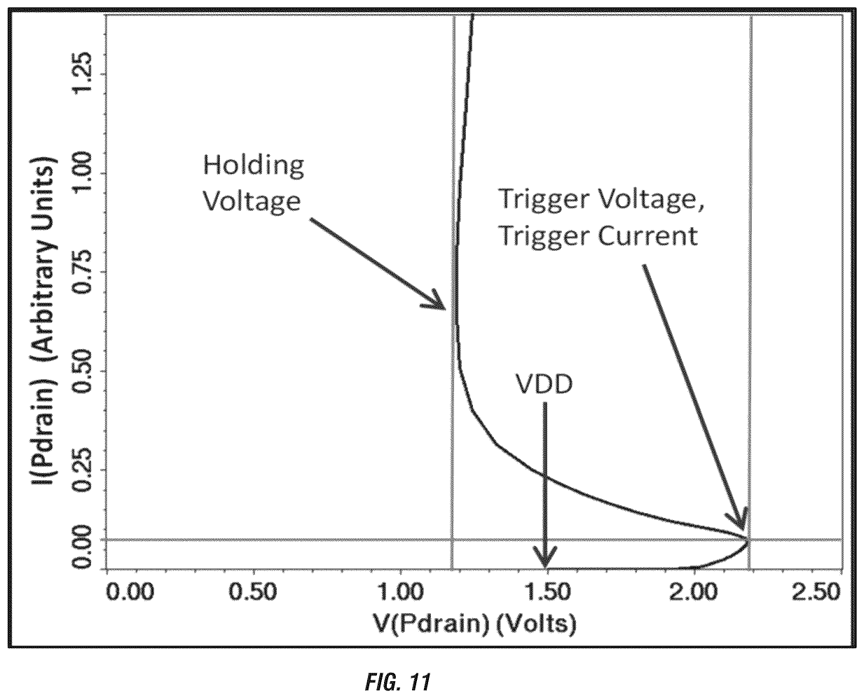

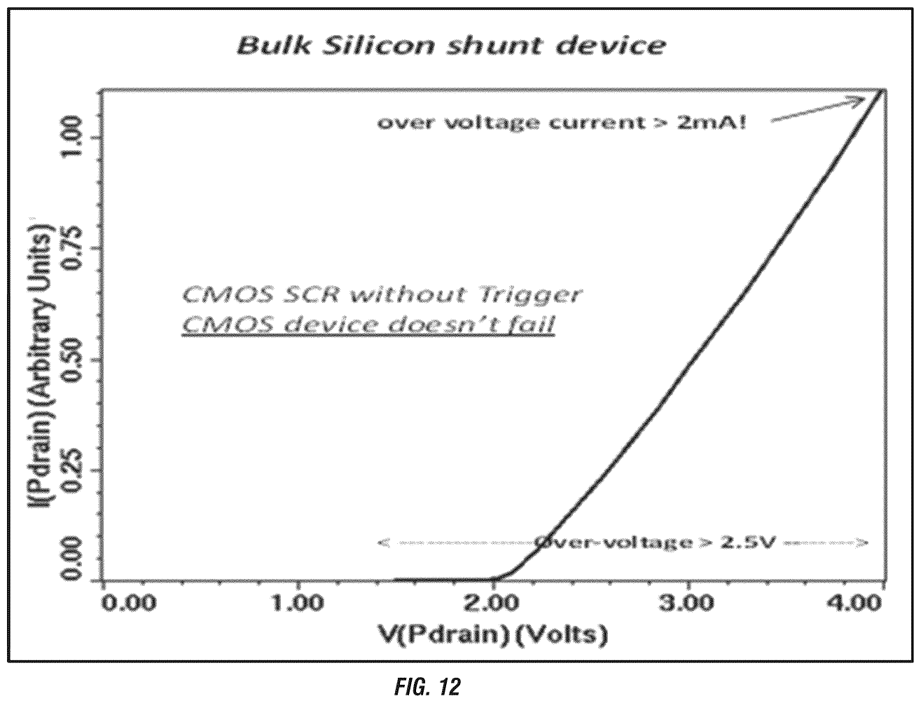

And while the invention itself and method of use are amendable to various modifications and alternative configurations, specific embodiments thereof have been shown by way of example in the drawings and are herein described in adequate detail to teach those having skill in the art how to make and practice the same. It should, however, be understood that the above description and preferred embodiments disclosed, are not intended to limit the invention to the particular embodiment disclosed, but on the contrary, the invention disclosure is intended to cover all modifications, alternatives and equivalents falling within the spirit and scope of the invention as defined within the claim's broadest reasonable interpretation consistent with the specification.

### DETAILED DESCRIPTION

Although there are described certain features, dimensions, configurations, tolerances, and parameters constituting the present invention, and examples set forth for illustrative purposes, iterations are included without surrendering any subject matter or departing from the invention's intent. And, although the following detailed description contains specific references to several preferred embodiments, one having skill in the art will certainly appreciate that modifications, alterations and variations are within the scope of the present invention. Accordingly, the following embodiments of the invention are set forth without any loss of generality to, and without imposing limitations upon, the claimed invention. While preferred embodiments are described in connection with the description herein, there is no intent to limit the scope to the embodiments disclosed below. On the contrary, the intent is to cover all equivalents.

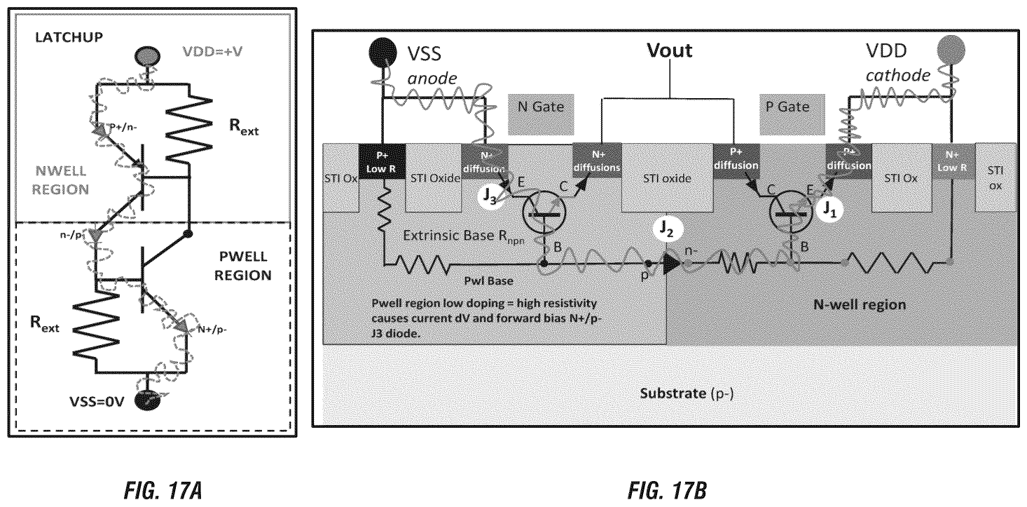

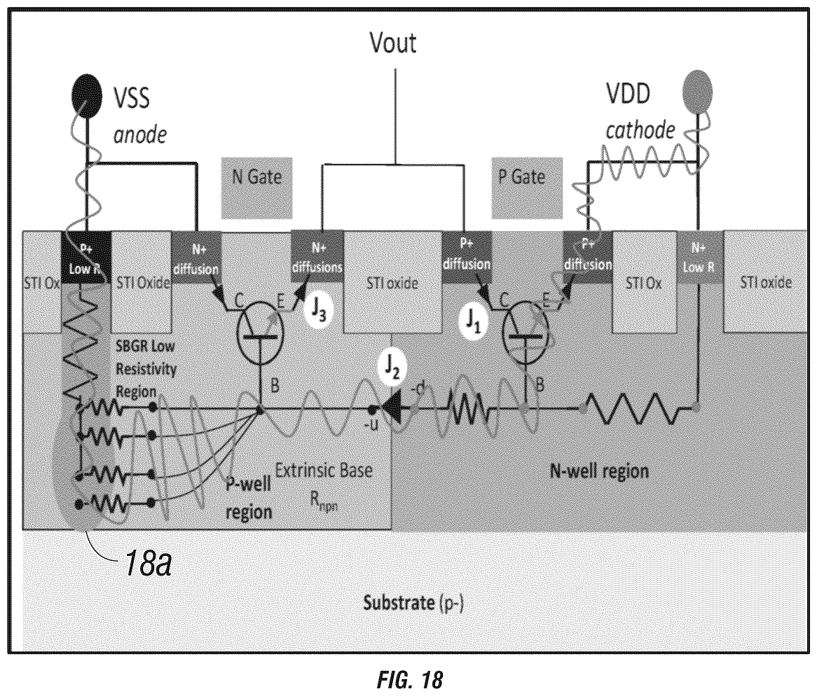

FIG. 18 plot shows the same CMOS inverter layout as FIG. 17b, but with SBGR high concentration doping region (designated as area 18a) implemented below the PWELL contact region and the thyristor parasitic PNPN bipolar device with the schematic overlay. SBGR implements increased high P type doping concentration that reduces pwell local potential (more negatively below the contact region) which induces a lower current impedance and causes the excess (upset) current to bypass and flows through the low resistivity (R) shunt to VSS. The plot shows simulation of excess trigger current density generated by an overvoltage or SEU upset event that depicts current is being conducted direct across the PWELL region where SBGR doping is implemented to the VSS terminal along with multiple current densities spread across the low impedance SBGR current region and path to the surface terminal. This schematic represents the SBGR and how the SBGR structure controls excess currents which prevents forward biasing the N+/p− J3 diode and prevents triggering. The SBGR shunt doping structure eliminates any possible forward bias of J3 and without J3 forward biased to conduct current where the inherent parasitic thyristor cannot be triggered into latchup with an SBGR doping structure fully implemented in PWELL regions.

As such bulk CMOS inverters that implement the SBGR doping region will be immune to latchup and destructive radiation effects. SBGR CMOS devices thereafter will operate reliably without failure due to upset events like overvoltage triggering and radiation single event effect and will operate reliably at extreme temperatures >250° C. without latching up.

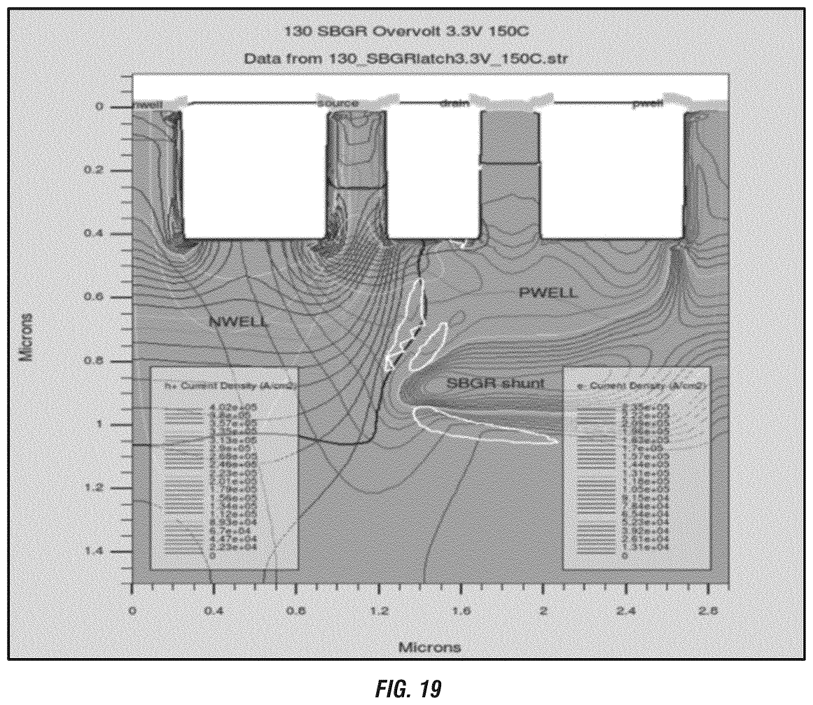

FIG. 19 shows a TCAD simulation of a four terminal bias characterization structure. The well regions are marked with NWELL/PWELL metallurgical junction (J2) indicated by black line with white lines representing the electrical field lines (depletion regions).

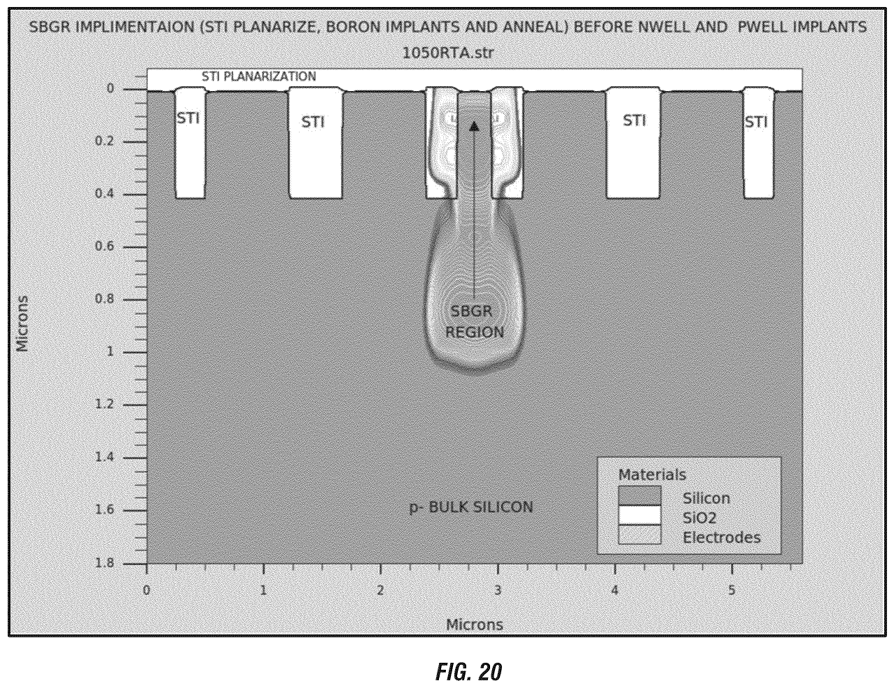

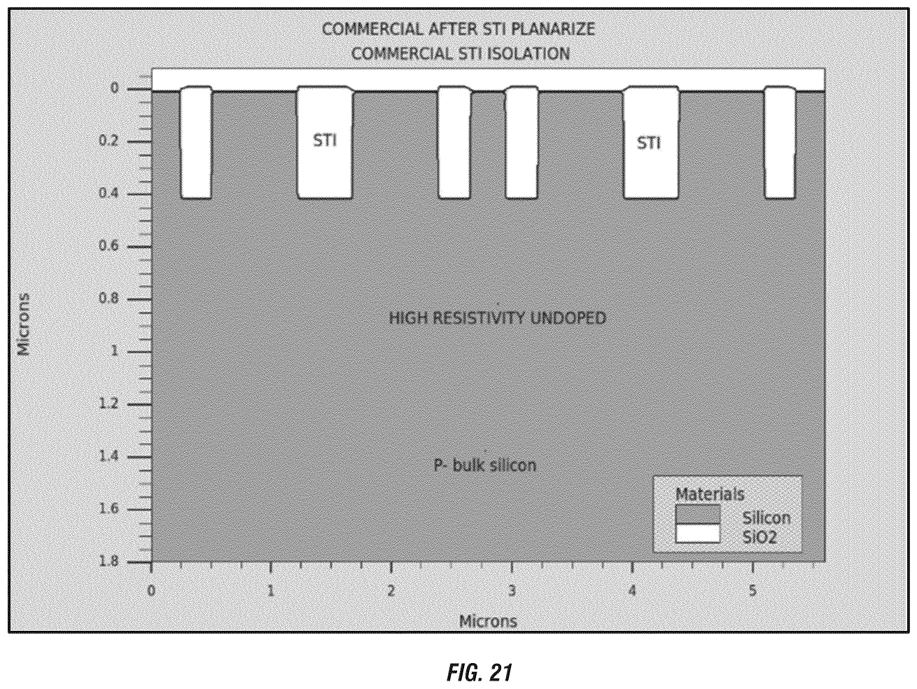

Expressly, FIG. 20 shows CMOS inverter layout with SBGR and, for contrast, FIG. 21 shows a commercial inverter without SBGR implemented in the layout before the PWELL and NWELL regions are implanted and annealed.

### SBGR Pre-Well Implimentation

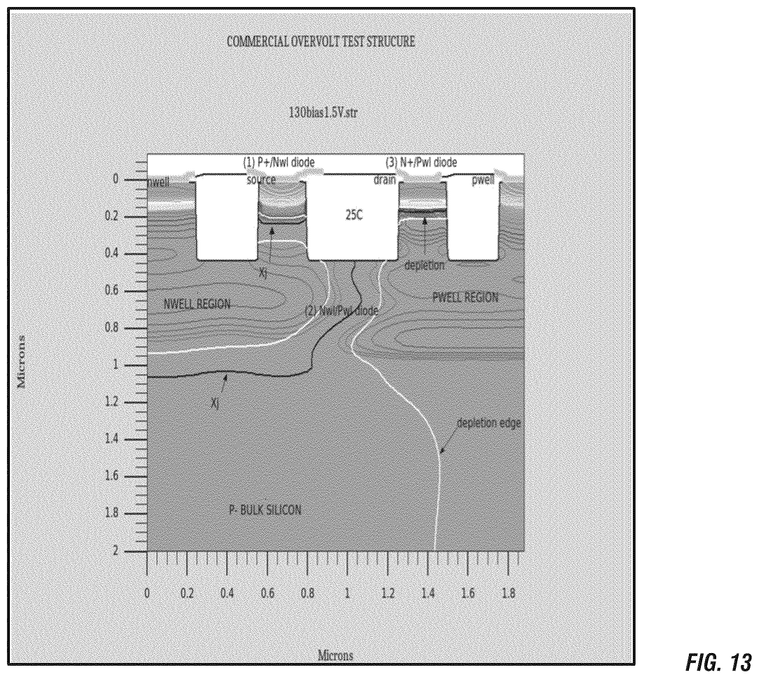

FIG. 20 shows a CMOS inverter layout in which the SBGR structure forms a low resistivity pillar shaped boron doping region that is implemented with two masks and three ION implants at a range of energies (50 Kev to 500 Kev). The implant masks are used along with ion implant angles and rotations to implant boron into the bulk silicon inverter layout region that form a P+ doping region extending from the surface to regions below STI in the center of the PWELL layout. These regions could be extended vertically (deeper) as needed. FIG. 13 is one example of this.

SBGR is implemented using multiple boron ion implants that create a continuous high concentration of P-type doping region that are masked and implanted with multiple ion implants at different implant energies with boron doses tailored to minimize implant defects within the implemented SBGR structure.

The SBGR structure is an improvement (in stack juxtaposition to the commercial CMOS inverter prior art) which can be implemented non-invasively into any CMOS device type without interfering with other electrical features or doping regions.

Also, SBGR can be fully implemented (implanted and annealed) before the NWELL or PWELL implants are implanted into the commercial wafer manufacturing process making the addition of SBGR non-invasive to other doping regions formed in the CMOS wafer process. The SBGR implementation could be done remotely from the silicon foundry with wafers shipped back to the foundry ready to continue the commercial manufacturing process to final wafer processing and passivation.

The SBGR structure also enables a means to authenticate silicon wafers and die to physically validate authentic and correctly verify processes or steps of the silicon foundry production to guarantee identity, authenticity, provenance and quality.

The implementation of SBGR masking regions is implemented using the same mask overlay alignment markers formed by STI and transistor active area regions that are planarized (already patterned) and are customarily used for well implants. This optimizes SBGR implementation as the doping is completed and annealed at high temperatures using rapid annealing tailored for dissolving silicon lattice implant defects and excess silicon interstitials before other inverter doping regions (NWELL and PWELL implants) are implemented thereby avoiding interfering or counter doping the other region in the commercial wafer manufacturing process.

The SBGR structure having been implemented and annealed to remove excess interstitials, quenching is completed before well implementation enables ideal “non-invasive” integration of the SBGR structure with no thermal Dt (time and temperature) added to the baseline commercial wafer manufacturing process (which affects other doping regions). This methodology is new and more novel and is a significant improvement over prior art. It is in the contemplation of inventor of prior art that SBGR shunt method is novel and superior to BGR implementation by adding different masking methods to stop high energy implant penetrations invents new structures improve, simplifies process integration that enables integration into all IC device types, which was limitation of prior art.

### SBGR Non-Invasive Layout

FIG. 20 shows a cross section (end view) of the inverter layout region with the SBGR pilar-shaped structure aligned to the PTAP STI active area region in PWELL regions. SBGR implemented pre-well implantation well regions enables a non-invasive method of fully implemented SBGR in silicon (after STI planarization) and before the well isolation regions (NWELL and PWELL) are implanted. The shallow implementation of the SBGR doping region extends from the silicon surface below the STI oxide region and (non-invasively) integrated into to the center of the PWELL region without passing below NMOS MOSFET transistor diffusion regions. The SBGR structure (shallow implementation) does not counter doping MOSFET transistor diffusions or channel doping that would interfere with NMOS transistor electrical behavior, Vt or IDS.

SBGR can be implemented more deeply in the same layout, if desired, that would extend below NWELL junctions and deeper masked areas as suitable. In either case, the shallow or deep SBGR Pilar structure is non-invasive to the inverter diffusion diodes and MOSFET channel doping regions.

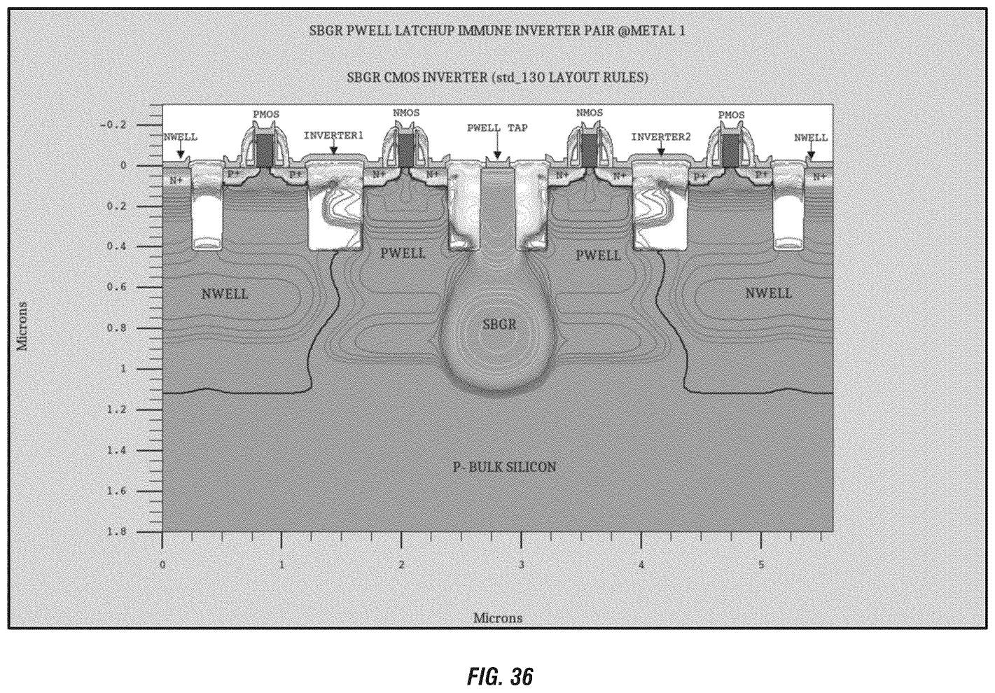

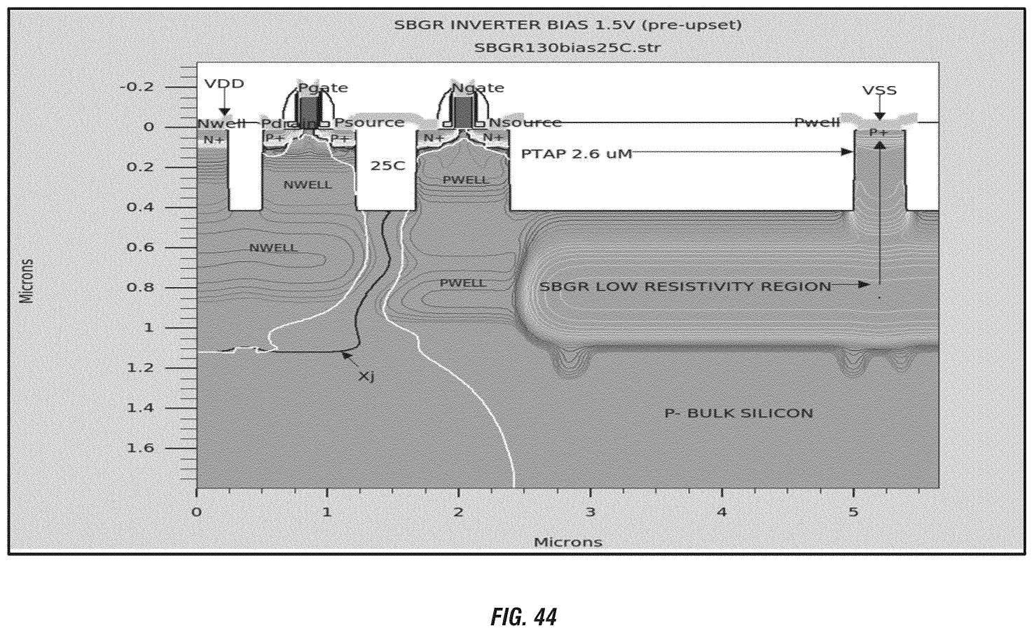

As shown in FIG. 20, the SBGR doping is a patterned distinct high boron doping structure formed to create a low resistivity region below STI regions which also extends laterally across the wafer continuously below PWELL contact regions passing between the PWELL PTAPs (tap to tap) uninterrupted and below the dielectric isolation regions within the IC PWELL layout regions either aligned to inverter PWELL regions or forming a larger SBGR regions masked to other IC regions, characterized by the below:
connected to metal interconnect at PTAP regions and across PWELL regions passing below dielectric regions from PTAP to PTAB within PWELL regions;
SBGR doping regions are formed below dielectric regions depicted in FIG. 20 and FIG. 36 with continuous doping extending from PWELL contact regions to PWELL VSS metal contacts as shown in FIG. 44;
noninvasive to other doping regions, (NWELL doping, PWELL channel doping, N+ diffusion doping);
forms a low resistivity region below STI in PWELL regions;
does not counter dope NWELL channel doping and diffusion doping of the NMOS transistors;
does not require a P+ HDBL boron doping layer be directly connected by other vertical P+ doping regions to VSS regions; and
enables SBGR integration into existing IC devices to enable latchup immunity to trigger caused by radiation, overvoltage transient and could be operated at extreme temperatures −55° C. to >250° C. without triggering into latchup and recover from all radiation effects exhibiting the intended ideal result.

This can be compared with commercial STI isolation in FIG. 21 wherein the commercial inverter layout is defined and implemented before well doping consists of silicon active area regions butted to dielectric layout regions does not include low resistivity impurity regions below PWELL regions vs FIG. 20 which shows an SBGR low resistivity doping area below PWELL contact region which can be implemented before well areas are implemented or after the PWELL region is implemented.

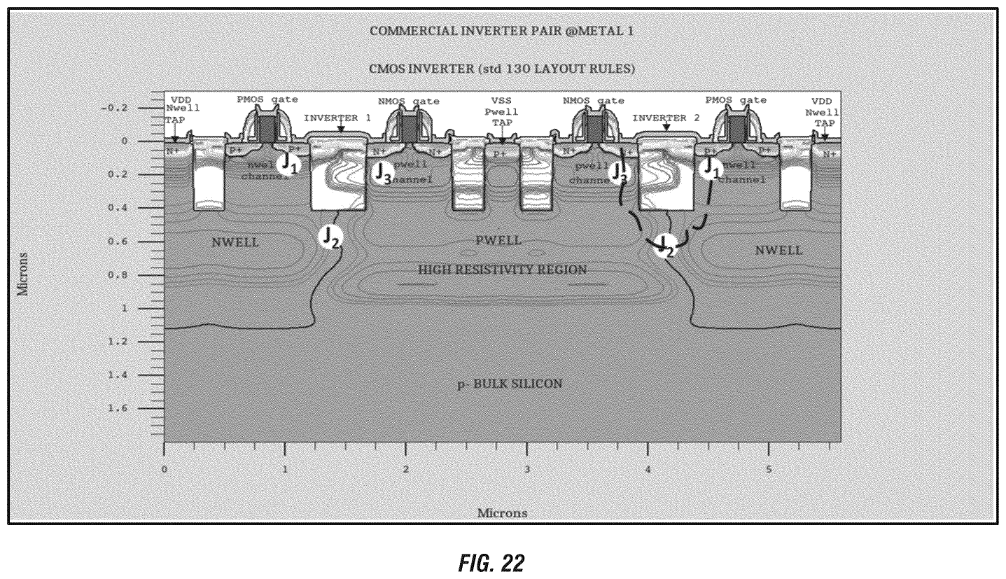

FIG. 22 shows a conventional CMOS inverter silicon layout at 130 Nm design rules with labels added (dashed lines) to highlight the inverter parasitic diodes wherein J₁, J₂, J₃ are also represented. NWELL and PWELL regions are formed with N and P dopants (ion implanted and annealed using low dose). The well regions form the N−/P− diode electrically isolates transistor current and voltage within each different well doping region. N-type dopants are used in NWELL regions and P-type dopants are used in PWELL regions.

The NWL/PWL diode breakdown voltage is high and best suited for voltage biasing to create the diode types needed for voltage isolation, transistor diffusion isolation and inverter voltage switching. The MOSFET diffusion regions (P+ diffusion) for PMOS transistor and (N+ diffusions) for NMOS transistors are connected to metal 1 (patterned layout) that make an ohmic contact with the IC metal interconnect and form the CMOS inverter. The dashed lines highlight the 3 discrete (thyristor diodes) locations (1) (P_{diff}/N_{wl}), (2) (Nwl/Pwl) and (3) (N_{diff}/Pwl) which collectively form the parasitic thyristor diode network which causes latchup trigger and failures in CMOS digital devices. FIG. 22 highlights the three inherent CMOS diodes that form the bipolar thyristor which are the J₁ diode formed by PMOS transistor diffusion (P+/n−) diodes and the (n−/p−) well diodes J₂ formed by NWELL and PWELL low doping regions and the J₃ diode formed by N+/p− diffusion diodes in NMOS transistors. Latchup activation requires all 3 diodes to forward bias and if any diode is not forwarded biased then the thyristor parasitic cannot source emitter/collector currents within the inverter between VDD to VSS and leading to the SBGR permanent latchup solution within PWELL.

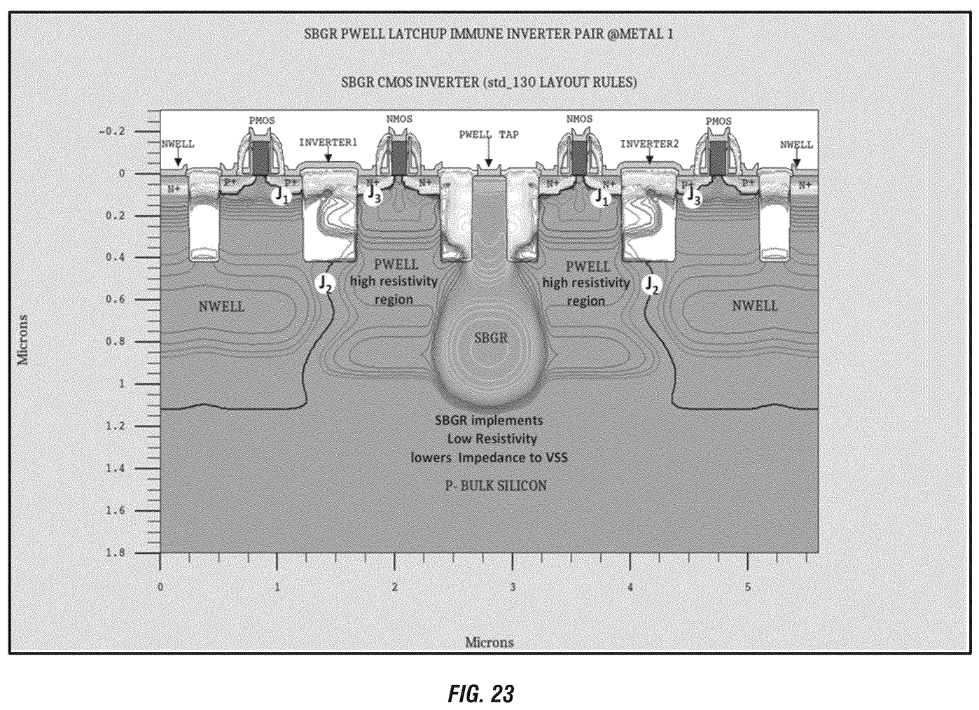

FIG. 23 shows the same inverter pair and layout as the commercial inverter layout but with SBGR implemented centrally and below PWELL TAP. FIG. 23 shows a CMOS inverter pair implemented with SBGR low resistivity doping pillar implemented at center PWELL region (PWELL Tap) for the 130 nm inverter layout rules. SBGR can also be implemented in PWELL regions before NWELL regions are implanted or can be implemented before either well region (N or P) wells are implanted to optimize non-invasive integration and wafer manufacturing simplicity.

### PWELL Resistivity and SBGR Enhanced Current Conductance

PWELL regions are lightly doped P− regions with doping concentrations wherein approximately (5e13 ions/cm3) is typical. At this concentration the PWELL is at high resistivity and is a poor conductor of current. A 1^{st} derivative of Ohms Law (dV=dI*R) shows for commercial PWELL regions a small current magnitude causes voltage shift more positive which shows a self-biasing effect observed in PWELL regions. A small amount of current sourced from the NWELL forward biased diode (N−/P− parasitic) forward biases the PWELL local potential and this causes the N+/P− diode to forward bias, activating the NPN parasitic and triggering into full latchup following any upset event. For PWELL regions doping at 5e17 the Hole carrier mobility (+charge) is approx. 190 cm²/V−s at 25° C. and resistivity=7.2e-2 (ohms). If certain PWELL regions' boron doping concentration is increased to SBGR concentration levels (3e19) and Hole mobility is 58 cm²/V−s., current conductance is the product of (carrier mobility)*(carrier concentration) with RHO units (ohm-cm) for a 1M×1M unit area where the length of the unit area is layout spacing for the inverter. For commercial PWELL doping, the current conductivity (5e17*190)=9.5e19 ohm-cm. for SBGR the conductance is =(58*3e19)=1.7e21. SBGR is current conductivity is 17.96× higher conductance than PWELL doping.

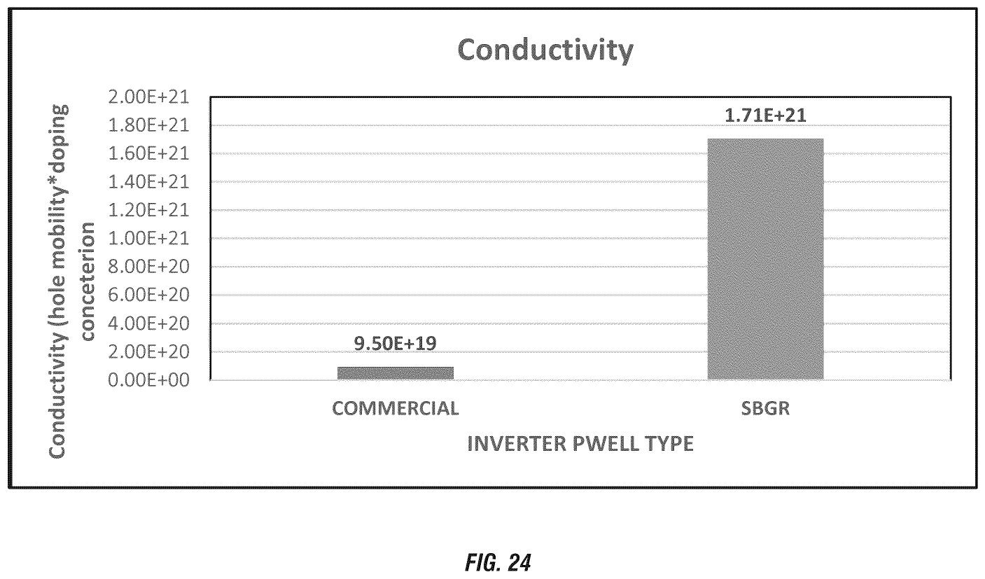

Hole conductance depends on temperature, lower doping=higher resistivity, higher temperature=higher resistivity. Higher doping concentration=lower resistivity*(unit area) is resistance. Current conductivity (as illustrated in commercially available vs. SBGR inverter Pwell type in FIG. 24) is the most critical property of the present invention for at least two reasons:
1. higher conductivity reduces the resistivity and body bias is proportional to R . . . dV=dI*R Current conductance is reciprocal of resistance; high resistance causes lower current conduction vs. low R enables high current conductions for the same V;
2. higher doping=lower Resistivity, higher doping minimizes changes in resistivity related to ambient temperature increase and minimizes any current reduction (electrical conductance).

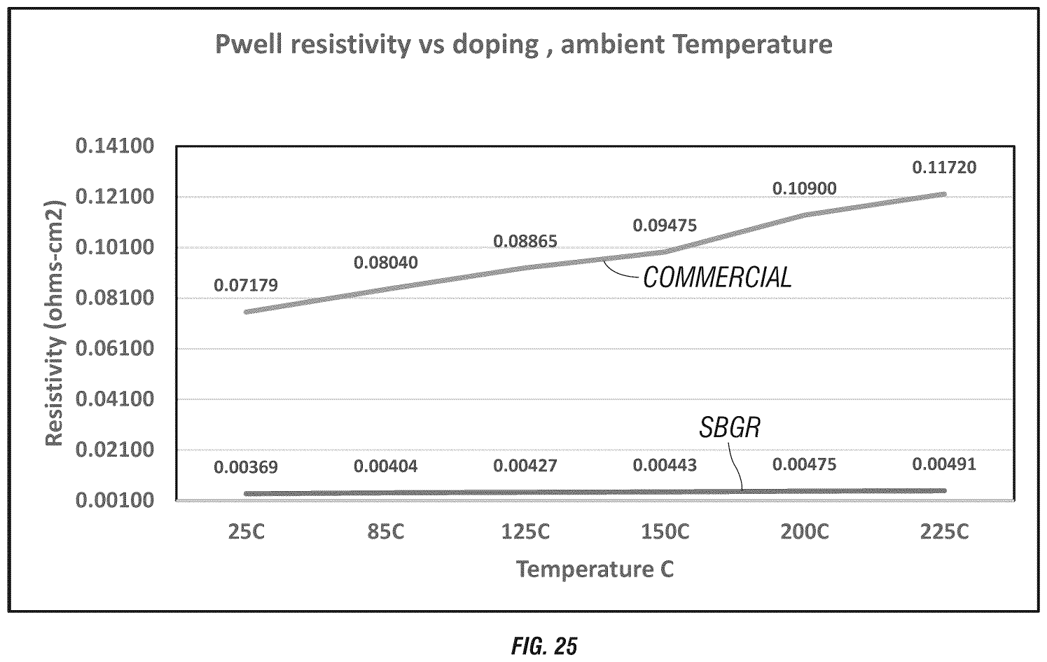

FIG. 25 compares PWELL doping resistivity and SBGR doping resistivities vs. temperature. The data shows as temperature increases commercial PWELL resistivity increases (top line) with increasing temperature, whereas the SBGR resistivity does not (bottom line) increase with temperature.

SBGR implements low resistivity doping column in the center region of the PWELL which acts as a buried VSS doping terminal to extending a P+ doping regions lowering PWELL series resistance below PWELL contact regions to VSS and also increases the negative voltage potential in the silicon regions below the PWELL contact regions. Upset currents that arise from all transient upsets will be collected by the SBGR low Resistivity region and this prevents forward bias of PWELL regions during excess current conduction and blocks forward bias of the N+/p− diode with remains in a reverse bias off state. With SBGR implemented, the J3 diode can't be forward biased and latchup triggering is permanently eliminated and CMOS devices will not latchup.

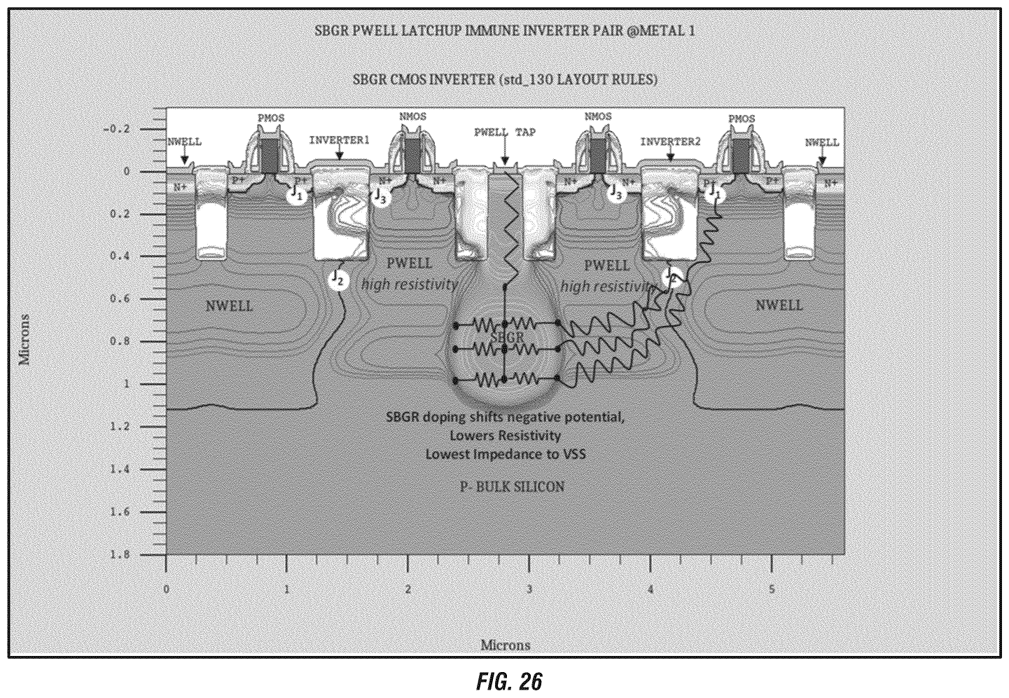

FIG. 26 shows overlay of the CMOS parasitic thyristor diodes with electrical schematic describing current flow track initiated from a transient upset at the right-side inverter which highlights sold state silicon current conduction from the emitter current source from J2 diode which is collected by the SBGR existing at lower impedance and conducts upset current to VSS thereby preventing forward bias of PWELL region and the J3 diffusion diode. Latchup trigger is not initiated and CMOS inverter recovers without failures.

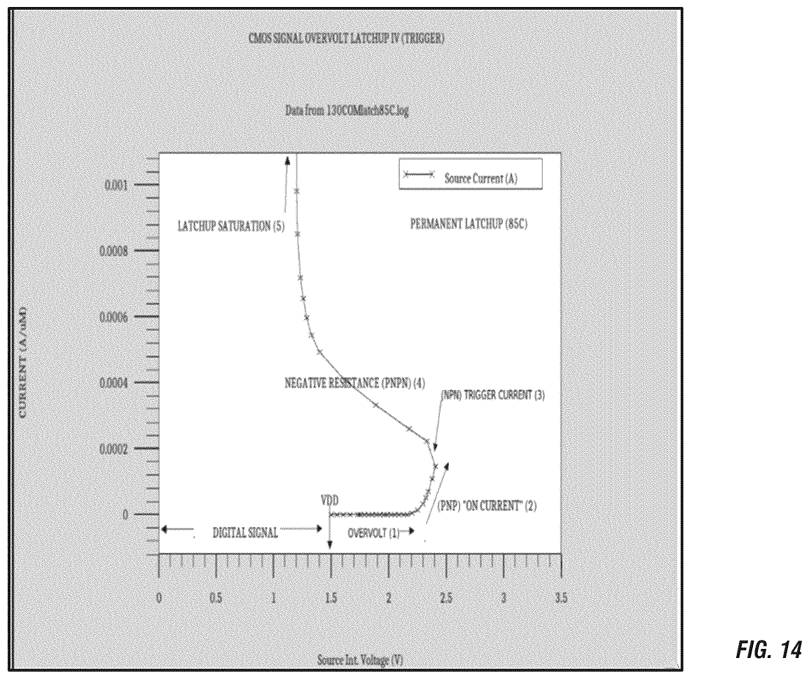

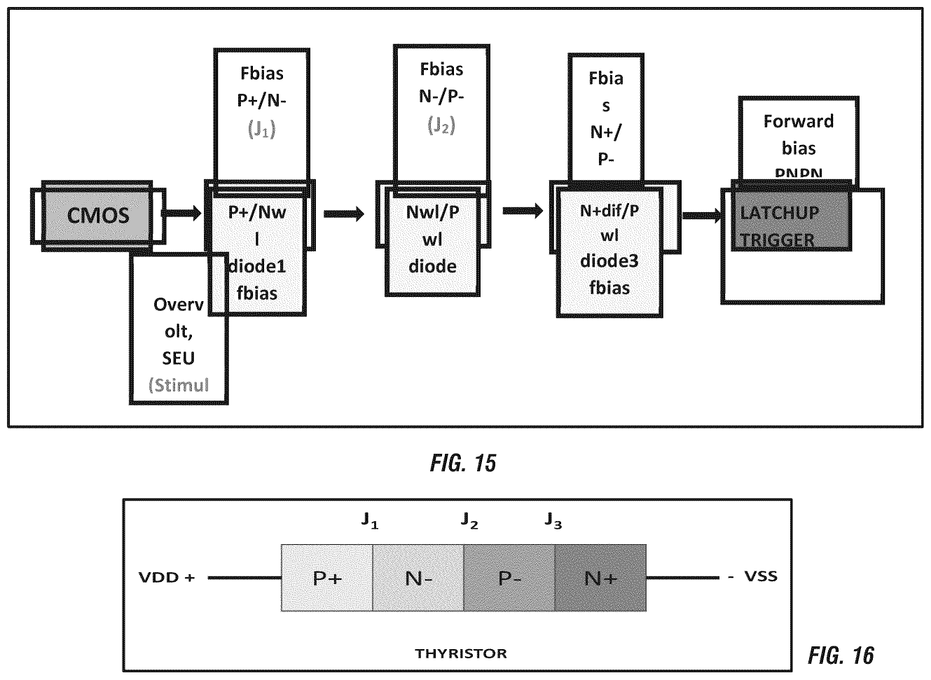

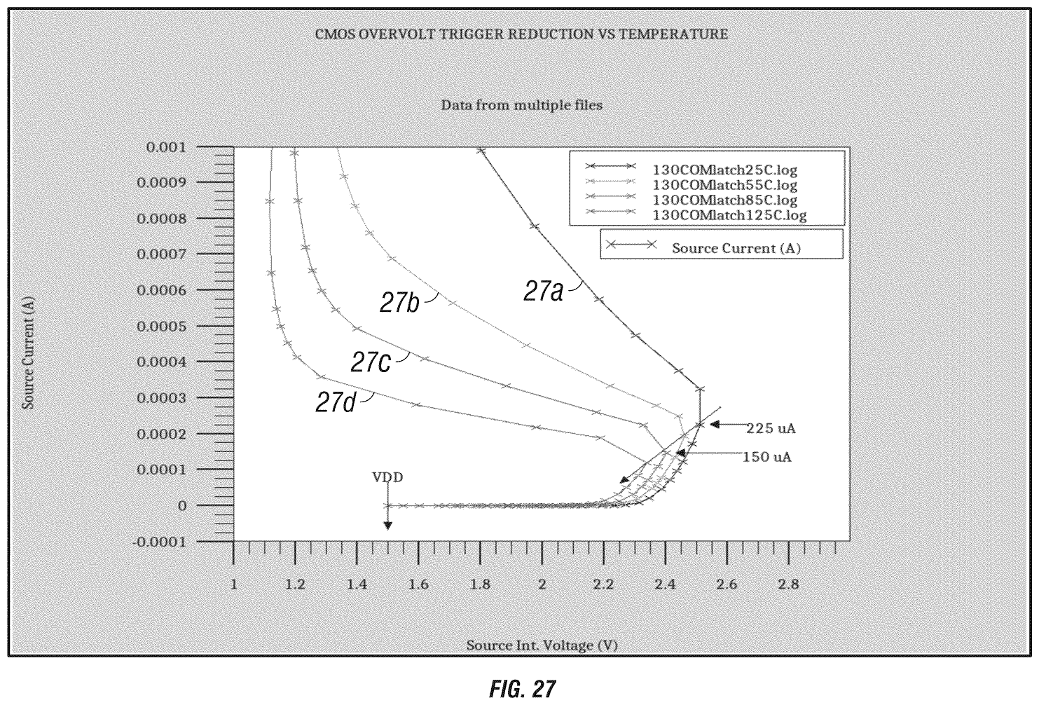

FIG. 27 shows ‘Commercial Inverter’ data showing for overvolt trigger current reduced as ambient temperature is increased from 25° C. to 85° C. by more than 56%. Specifically, overvolt triggering temperature 25° C. is labeled as 27a, temperature 55° C. is depicted by 27b, temperature 85° C. is labeled 27c and temperature 125° C. is labeled 27d. Simulations for overvolt trigger vs. temperature show that the latchup trigger current is reduced by >33% as temperature is increased from 25 C to 55 C and by >56% (lower trigger current) at 85 C is shown previously in FIG. 14. Lowering the trigger current makes latchup failure more likely in CMOS devices and as such most commercial device service lifetimes are not specified at temperature greater than 25° C. And when specified at higher temperatures, the time is shortened to a few days or hours of operations.

The N+/P− diode (3^{rd} diode in thyristor) is self-biasing due to high resistivity in the PWELL region which induces a dV bias (local PWELL potential) shift >0V is the key diode which activates the NPN bi-polar which initiates latchup trigger and shorts VDD to VSS. Transient upset failures (overvolt) cause bit errors as overvolt transient upsets due to timing failures will persist as a reliability risk for CMOS devices executing cause code errors.

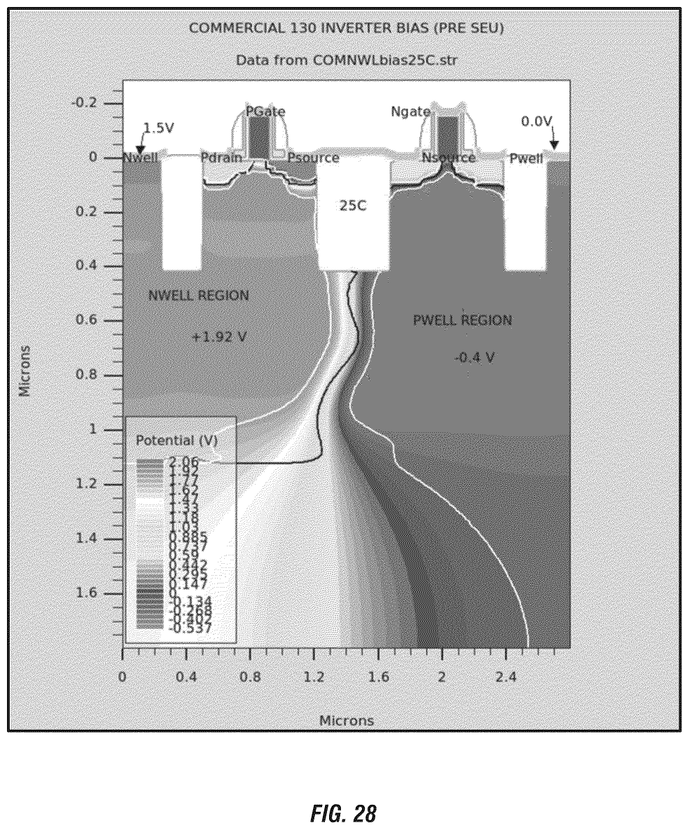

FIG. 28 shows a commercial inverter biased at VDD. The potential (bias magnitude) is highlighted by shading in the voltage data list and shows within the NWELL body the static potential is 2.06 V and normal since in semi devices the actual “silicon potential” is =the applied external bias (1.5V)+ “built in potential” charge along the junction diode=(0.7V). Whereas in PWELL regions, the potentials are opposite VSS=0V−built in potential drop across the diode=−0.4V and more negative voltage values are listed shown in darker shades.

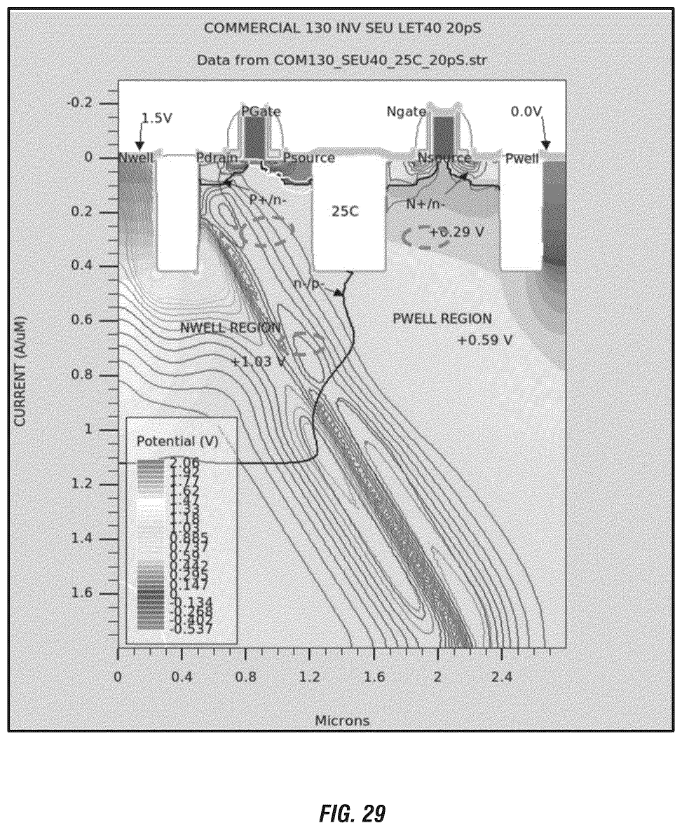

FIG. 29 shows the same 2D cross section with a particle track from a radiation particle. Mobile carriers are injected radially along the track which are mobile pairs (+ holes and − electrons). The mobile charges interact and are neutralized by recombination and others that become current which flows to the terminals or diffusion regions in time until depleted. However, the potential within each well potential has changed from its bias state and with it the thyristor diodes are activated and begin sourcing large terminal currents that far exceed the upset currents caused by the particle strike (or overvoltage). This is the detailed mechanism of latchup caused by upsetting thyristor diodes which cause much worse triggering and destructive latchup. SBGR increases the boron doping to (>1e18 ion/cm-3 concentration, within the SBGR contact region and below STI pwell regions of the PWELL (non-invasively) and this shifts the static potential more negative than PWELL doped regions (low boron doping <5e17 concentration).

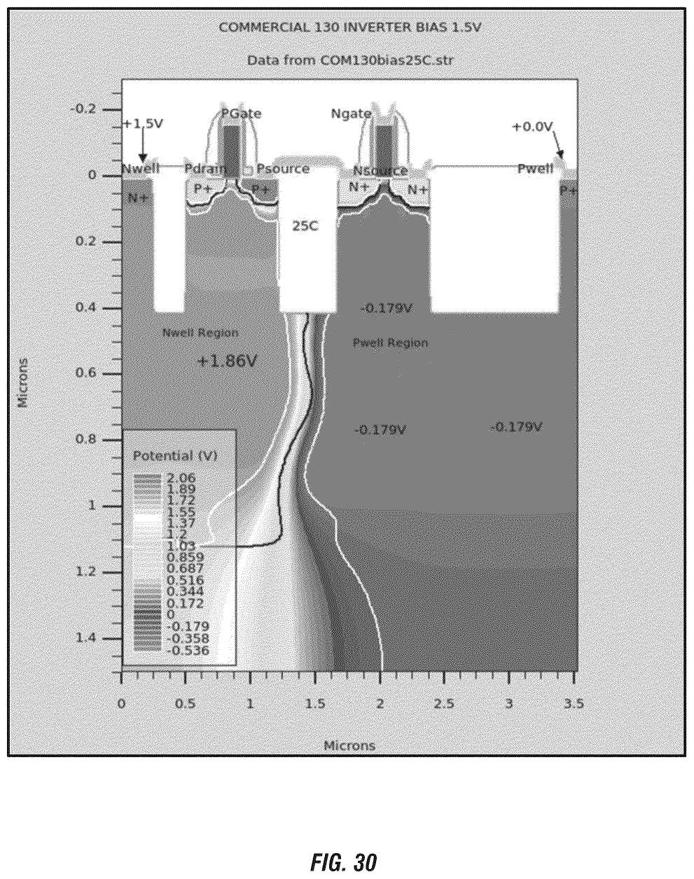

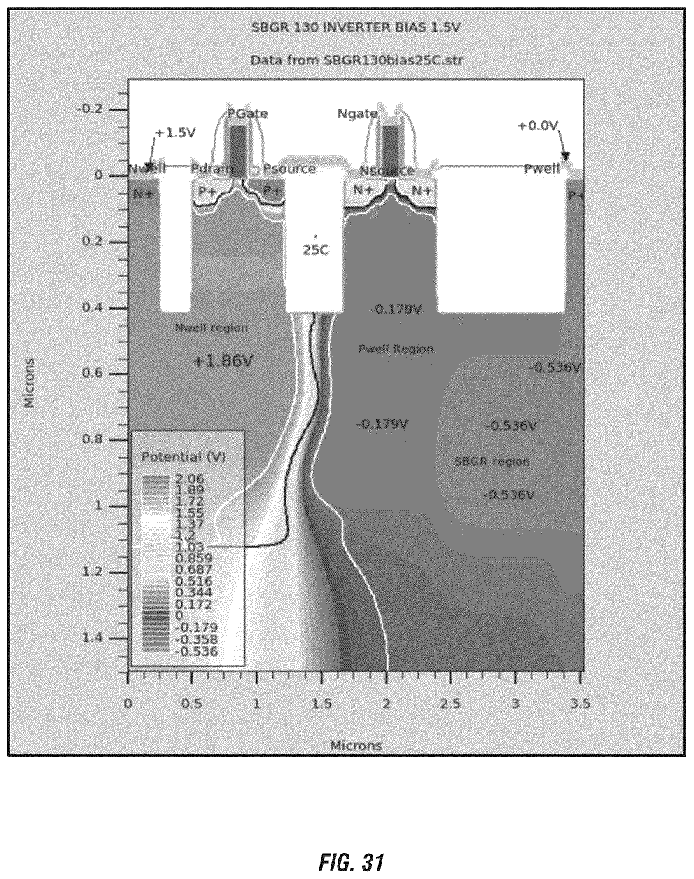

FIG. 30 illustrates wherein a commercial inverter is compared to an SBGR inverter, evidencing an SBGR region, at the static bias potentials in FIG. 31. FIG. 31 shows the SBGR region which is lower local potential bias (−0.536V) vs Commercial for the same area at −1.79V, is more than −0.35 V lower. This is due to the high boron concentration in this region below PWELL contact and dielectric regions which will act to electrically offset positive charging due to upsets (overvoltage or radiation particle) and increased temperatures also. All self-bias attributes are very helpful for preventing overvoltage latchup triggering and facilitates fast recovery of transient upsets while also enabling the inverter to operate at high temperatures.

### SBGR Solution

SBGR implemented in PWELL reduces the resistivity within the PWELL region with masked ion implantation of boron to create a high concentration region that increases current conductivity to terminate the mobile and upset currents by eliminating the forward biasing of the PWELL regions during a transient upset. Prior art architecture implements a blanket HDBL boron doping layer which implants the whole wafer and was connected to surface terminals via multiple masked implants that were integrated into the wafer manufacturing process at multiple steps. While this was moderately effective, the prior art BGR structure invention was invasive to both isowells, deep NWELLS and NWELL regions (causing counter doping of n-type regions) which decreased NWELL breakdown voltage and causes shorting to VDD could not be integrated into other types of CMOS device types such as.
BCD device BGR shorted the deep NTUB SBGR does not
Mixed Signal device BGR increased noise SBGR does not
RF device BGR lowered Q inductance SBGR does not
Embedded flash device BGR shorted deep NTUB iso-wells SBGR does not
ESD IO protection BGR reduced HB voltage to <2000V SBGR does not
SBGR avoids these issues since it is fully masked, shallow and does not require the blanket implant to implement a low resistivity doping region (that is invasive) and can be implemented only where needed (anywhere in the layout). Moreover, SBGR will remain low ohmic connected to upset regions from PTAPs that are farther away from the PTAPs and enable higher temperature latchup free operation

By modifying the doping to reduce resistivity in CMOS PWELL regions for all layouts, advanced CMOS devices will not trigger into latchup and can be operated in extreme environments like high radiation and high temperature (>25° C.). While transient upsets are unavoidable (as radiation strike or overvoltage transient conditions will still cause upset events), with SBGR implemented the upset will latchup and will not persist and allow for recovery of the upset regions to normal operation more quickly and without fear of permanent latchup.

### Commercial CMOS High Resistivity Effects (Radiation Upset Characterization)

FIG. 30 shows a commercial inverter cross section with a PWELL metal contact region (PTAP) and minimum layout spacing. Whenever a commercial CMOS inverter is struck by a radiation particle (or upset by overvoltage event) the parasitic thyristor diodes all forward bias into the active state and begin sourcing current to other diffusion regions that persists and causes the latchup trigger to increase because the PWELL region is a poor conductor (exhibits high resistivity). Current conducted thru the PWELL regions increase the well potential, positively increasing the forward bias the N+/p− diode, and ramps current to the saturation level. FIG. 30 shows current that is conducted from PMOS transistor diffusions thru the NWELL being terminated (VSS) by the NMOS transistor diffusions with very little current flowing to the PWELL to the VSS terminal.

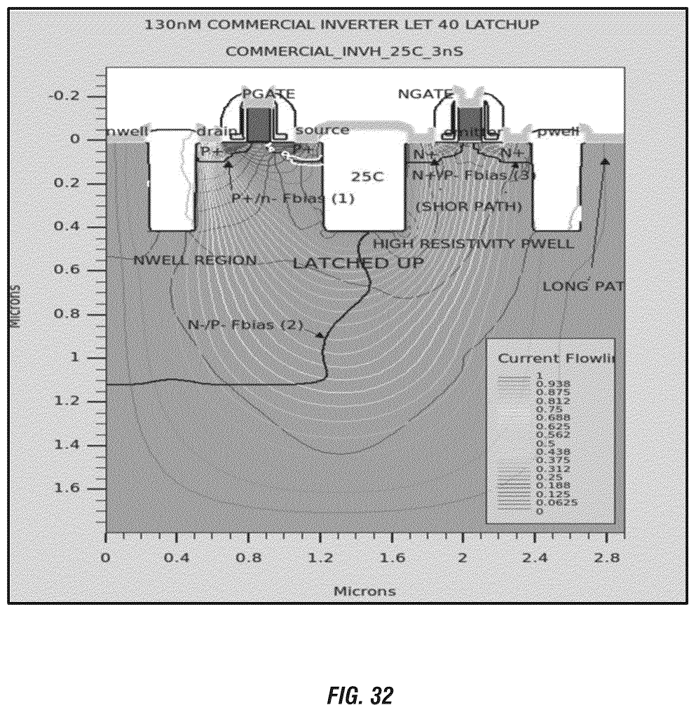

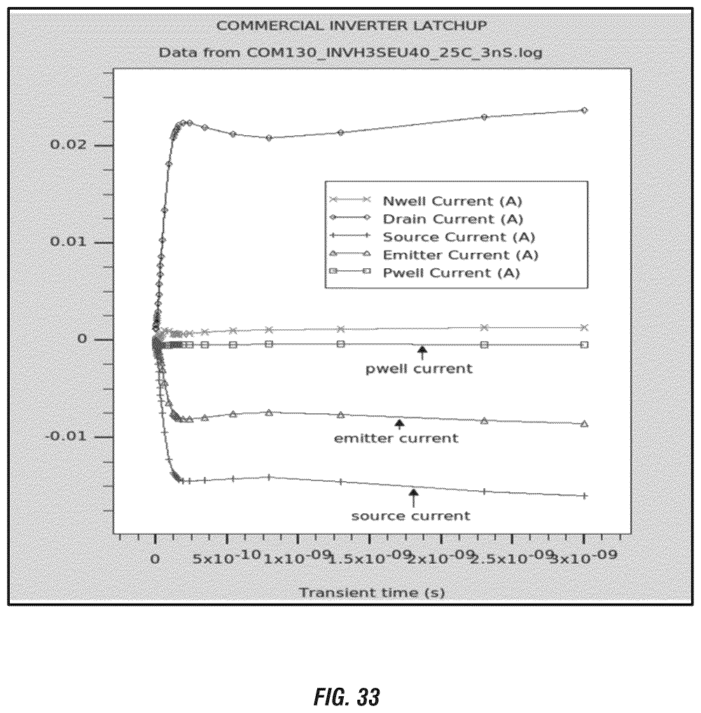

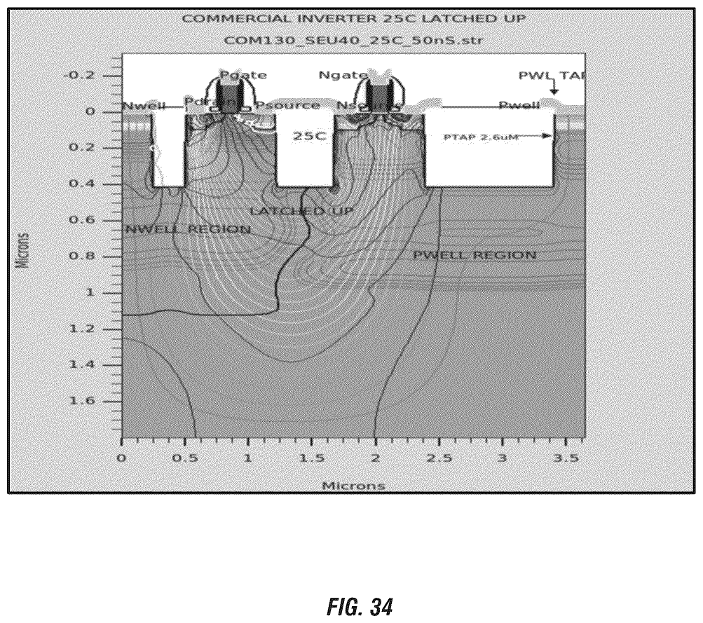

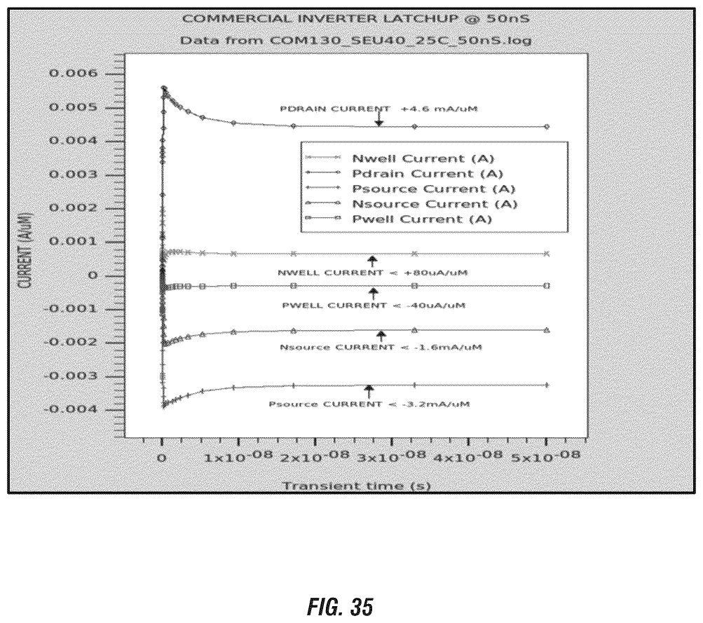

Following the particle strike, all the thyristor diodes are forward biased #1 (P+/N−), #2 (N−/P−), #3 (N+/P) and initiate a latchup trigger event. At 3 nS the parasitic currents are increasing in magnitude. The IV plot in FIG. 31 shows upset and thyristor diode currents for all diodes. Very little current is terminated at VSS where less than 2% of total upset currents. Therefore, commercial PWELLs are poor conductors and ineffective due to high resistivity. This is the primary cause of trigger (due to both dV and the body potential increase and makes commercial devices incapable of recovery), as currents are reinforced by the parasitic network and make upset persistence (long time to recovery) or can become a permanent “stuck state” due to low current conduction (rate) to VSS as shown in FIGS. 30, 31, 32 and 33. The high PWELL resistivity initially causes the PWELL internal voltage to increase which forward bias the N+/P− diode and activates the NPN parasitic and all inverter diffusions and well terminals are shorted leading to an inability to recover which is the legacy of bulk CMOS latchup failure. FIG. 33 shows the same commercial inverter at 50 nS which does not recover. The PWELL and NWELL terminal currents are lowest and commercial inverter is permanent and not recovered at 50 nS (FIG. 33).

### SBGR Implemented in CMOS Inverter Layout During Wafer Manufacturing is Latchup Immune Solution:

The SBGR implementation forms a new type of PWELL which can support both inverter switching performance and implementation of a low resistivity region preventing latchup in operation in extreme environments such as high temperature >250° C. and radiation at the same time.

FIG. 36 shows an inverter region with SBGR implementing a high boron doping concentration region within the broader PWELL region of an inverter layout that is non-invasive to a MOSFET transistor reducing resistivity within PWELL region(s) to improve current conduction. This cut plot shows boron doping in the PTAP wherein said region is significantly higher below PTAP and STI region.

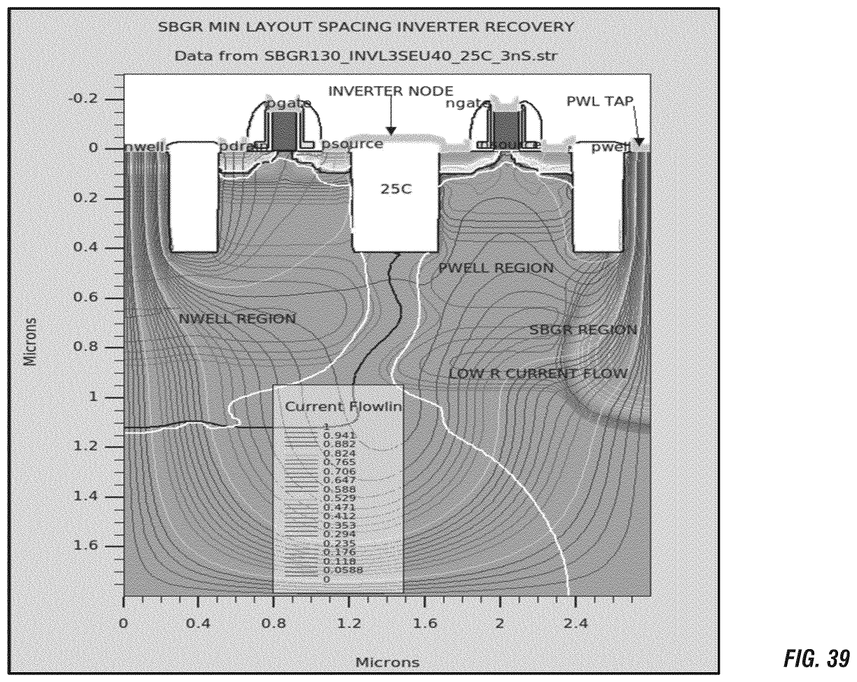

The SBGR region enables significantly higher current conduction across the PWELL region from the N/P well junction to the VSS metal terminal and high current density conduction shown in FIG. 19 and FIG. 39 preventing the forward bias of the N+/Pwl diode and eliminates latchup. And with SBGR implemented the LATCHUP trigger current is eliminated and does not decrease with temperature increase as low resistivity offsets temperature (small) effect on resistivity is offset by higher doping concentration in contrast to commercial devices shown in FIG. 27 the latchup trigger current is reduces with temperature increase. Additionally, self-biasing is avoided. SBGR offers the CMOS inverter several improvements including:
Latchup immunity;
High temperature operations >250° C.;
Low temperature operations down to −55° C. or lower; and
Faster transient upset recovery times.

The SBGR implementation layout example (FIG. 28) is based on 130 nm layout rules. And for more advanced layout rules (40 nm and 28 nm), layout regions will be the same pattern but repeated at smaller region geometry.

The novelty of the SBGR region is this region can be formed non-invasively within the inverter layout using masked implantation without use of the blanket boron layer of prior art (BGR patents) thus making it possible to control SBGR implant doping regions and doping profile depth to enable integration without interfering with other doping regions used in modern CMOS devices (deep NWELL regions for flash memory, BCD doping regions for power devices, analog devices, RF devices without degrading or electrical shorting or a combination thereof.

The depth of the boron doping region is much shallower than prior art making the SBGR far more effective (closer to upset regions) than any prior art. The SBGR doping region (shown in FIG. 36) is a cross sectional view wherein the profile would extend continuously (into the Z direction PWELL region layout length geometry) below the silicon dioxide (STI regions) with periodic extensions to the silicon surface-making ohmic contact with VSS metallization (PTAP regions) typical in CMOS design art.

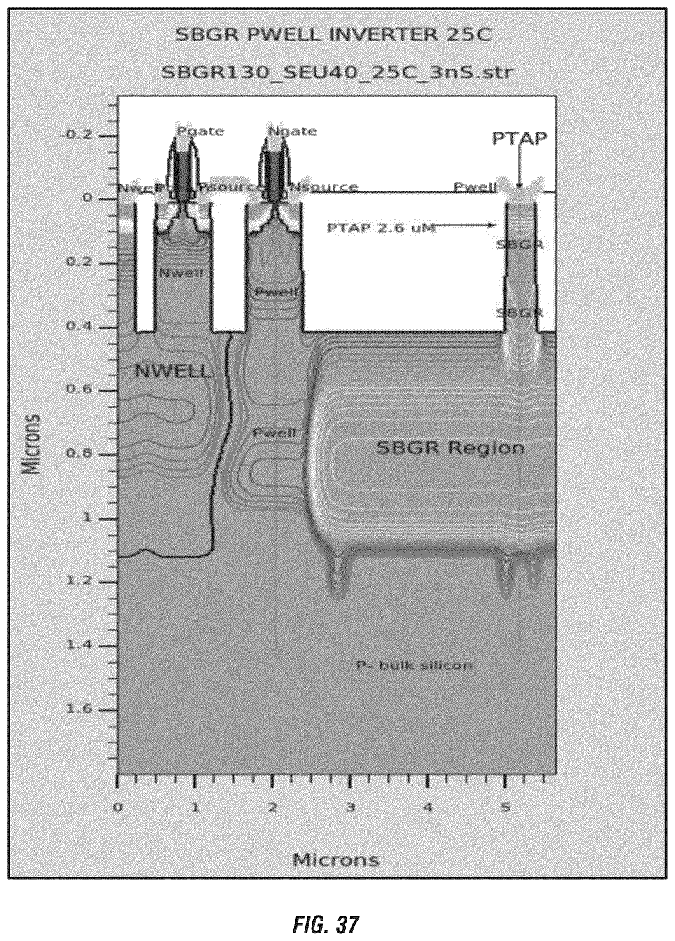

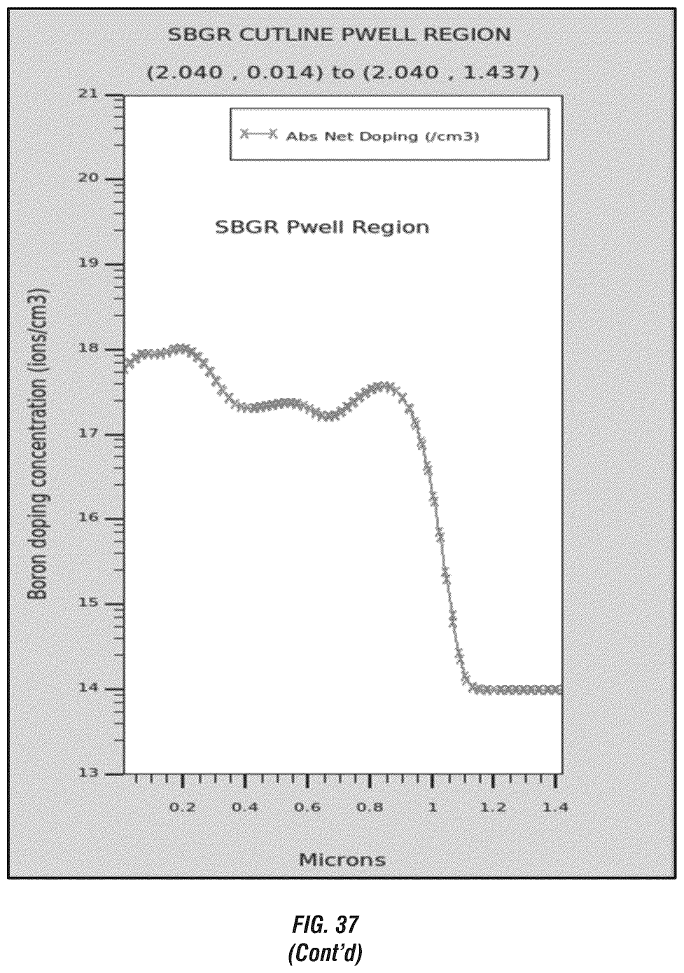

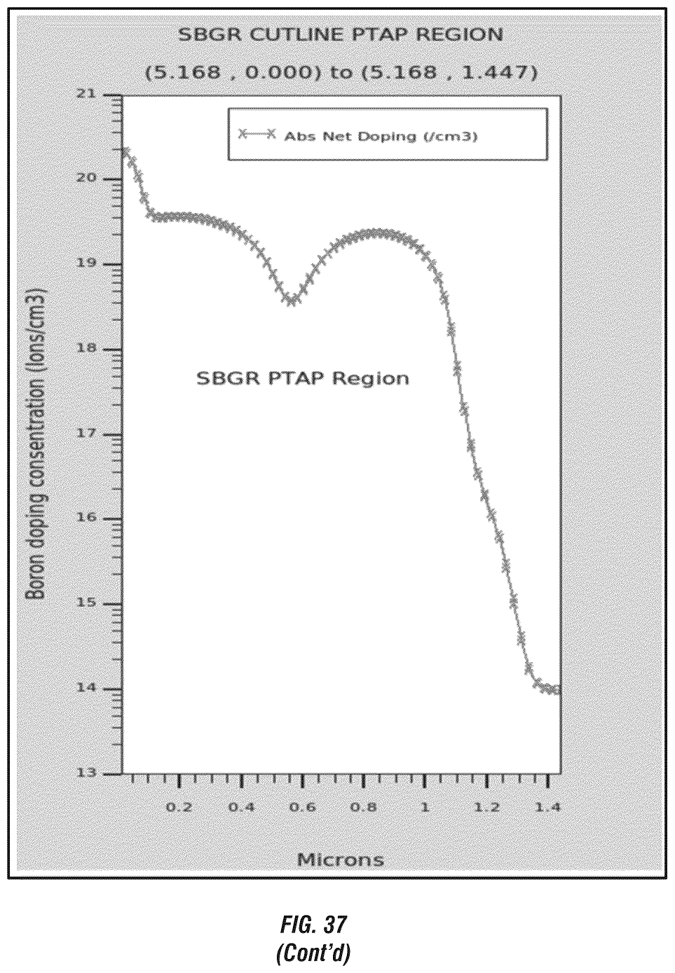

The PWELL doping region can be polygon, square, rectangular, L shaped doping, or any similar or like regions, which is along the length (longer length than in width). The SBGR doping region is centered in the inverter center PWELL width region and extending below STI maximum depth and extensions alone PWELL length within the PWELL regions (parallel to NWELL Xj) and can extend its length between PWELL spacing PTAPS, (PTAP to PTAP) or any to other Pwell layout regions as shown in FIG. 37.

SBGR doping can be short or long extended regions below STI or LOCOS regions utilized continuous doping region between PTAP region termination and other PTAPS (contracting metal) or can be implemented as a single pillar structure at the PWELL minimum VSS spacing taps spacing (or individual P+ doping regions) to form minority carrier guard rings deeper (i.e., below the silicon) to form recombination centers for minority carriers and terminate mobile electrons (lifetimes).

SBGR doping is a continuously doped region implemented below the STI extending between the PTAP regions and below STI or LOCOS dielectric regions which is implemented in all CMOS inverter PWELL regions in the CMOS IC chip design to create a low resistivity PWELL region that can be implemented into the manufacturing process and existing IC design inverter layouts consisting of a non-invasive novel CMOS doping structure that can be implemented into a CMOS device without redesign and integrated into multiple wafer manufacturing fabs.

As evidenced in the below figure, FIG. 37, left, shows a CMOS inverter layout region with SBGR doping implemented in the PWELL center region that extends from the PTAP region to the inverter transistor region. A high boron doping concentration is implemented into the PWELL region, below PWL TAP, extending more than 2.6 um below the STI region to the inverter region. The SBGR boron doping extends along the length of the PWELL layout at a spacing to NWELL as desired. Boron doping placement is controlled by implant masking and implant energy (angle, twist and tilt) so as to ensure boron is implanted thru the STI region into the silicon region below STI at a control depth to optimize the boron peak doping below STI region in the PWELL region or any greater depths as desired. The doping cut plots compare the boron doping profiles for PWELL regions versus SBGR doping regions (shown in FIG. 37 plots middle and right) doping cut lines are visible. This shows the difference in doping magnitude and profile for SBGR regions vs PWELL doping profiles are significantly different.

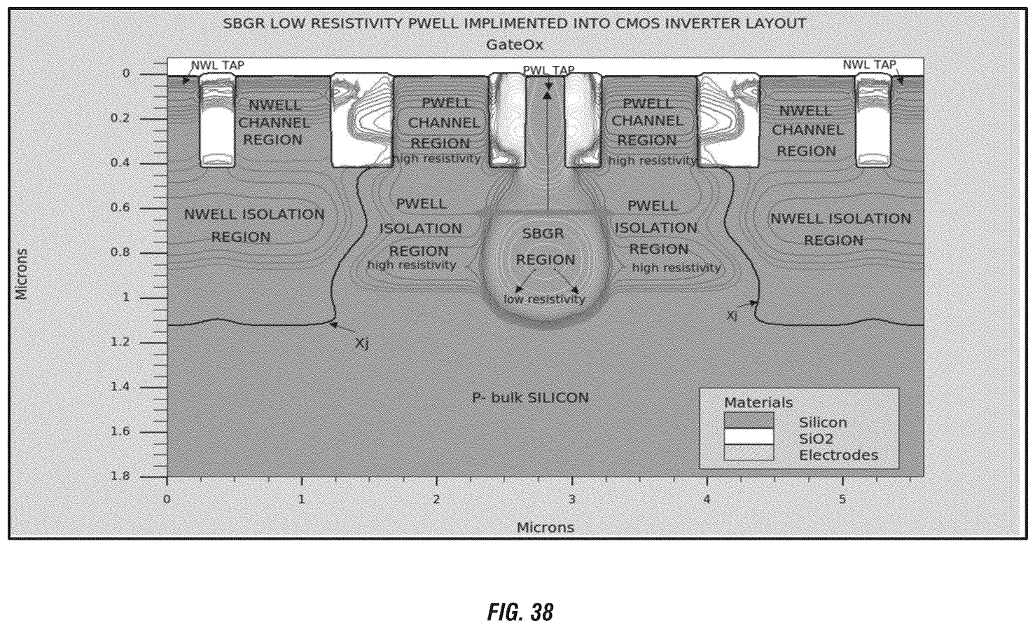

In FIG. 38, the boron doping (lateral width marked with red arrow) doesn't exceed the STI width for minimum Active Area/VSS ground rule spacing and extends within PWELL below STI field ox regions between PTAPs. The boron doping for SBGR implemented is done with different (higher boron dose and higher energy) using new implant layers for the IC chip design. PWELL doping is implemented using different PWELL masking and multiple ion implants tailored for NMOS transistor performance normally used in the wafer manufacturing process. NMOS transistor channel regions are doped by PWELL implants, LDD implants and S/D implants to implement the NMOS transistor. PWELL doping implants overlay the PWELL region and extend to an increased P− doping depth similar and butted to NWELL for form n/p Xj depths.

SBGR implants are masked to not counter doped PWELL channel regions or other any PWELL isolation regions (shown in FIGS. 26, 36 and 38). The PWELL channel and isolation regions are lower doping regions with high resistivity and form the n/p junction (Xj) diode with the NWELL regions (left and right) at ground rule layout dimensions. SBGR doping can be implemented in the PWELL region at greater depths (below PTAP and STI field regions non-invasively) if desired.

The SBGR region (shown in FIG. 38) is implemented with masked boron implants at the PWELL center region below the vertical PWELL tap and extends to the silicon surface making ohmic contact with VSS metal. The PWELL transistor channel doping and isolation regions are formed with low dose PWELL implants uniformly low doping concentration below the NMOS transistor active areas and on either side of the SBGR region. IC design layout rules are different for each CMOS generation related to (PWELL width and length) and layout shapes determined by the chip design. The cross section (shown in FIG. 38) of the SBGR implemented into the PWELL region (in width). SBGR doping is or may be centered within the PWELL region width or at the design rule min AA/PTAP spacing rules. SBGR doping may be implemented continuously in the PWELL length with SBGR doping region extending continuously or interrupted if needed between the VSS PTAP regions (PTAP to PTAP throughout the IC device within PWELL doping regions or below NWELL doping junctions and contacted to surface VSS metal interconnect. And as technology scales to smaller geometry, the SBGR doping region also scales in area (size width, depth dimensions), implant energy for vertical placement and implant dose doping, can be changed but high concentration is implemented.

SBGR acts as current divider (low resistive shunt) which redirects the excess current to VSS and prevents PWELL body biasing (dV), which in turn prevents the forward biasing the N+/P− diode thus preventing the parasitic thyristor from activation. SBGR low resistivity redirects upset current away from the NMOS transistor (N+ diffusions) and prevents latchup.

### SBGR Vs Commercial Latchup Characterization

Current conduction density will vary in silicon with doping concentration and spacing to the well taps (PWELL/Metal 1) ohmic contact region. Commercial CMOS inverters are contacted to VSS thru PWELL doping where uniformly low doping density (<5e13 ions/cm3) is nominal and spacing to the VSS PWELL tap can be several micros. The current resistance then relates to area and doping density as R=(rho)*(resistivity)*(L/W). The only way to reduce resistances is to increase local doping concentration (add SBGR region) that reduces the resistance in PWELL regions between PTAP gaps to distant AA region spacing. Transient upset and recovery time is proportional to current conduction, reducing resistivity minimized recovery time.

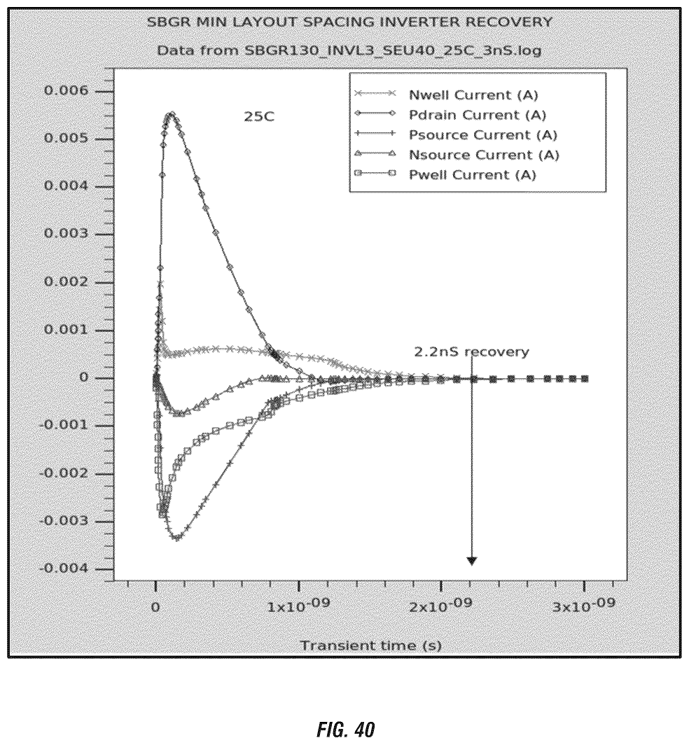

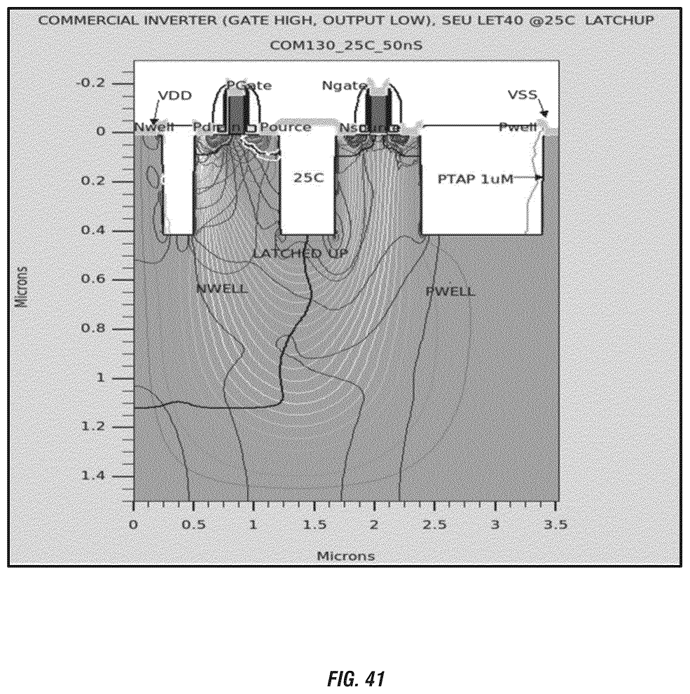

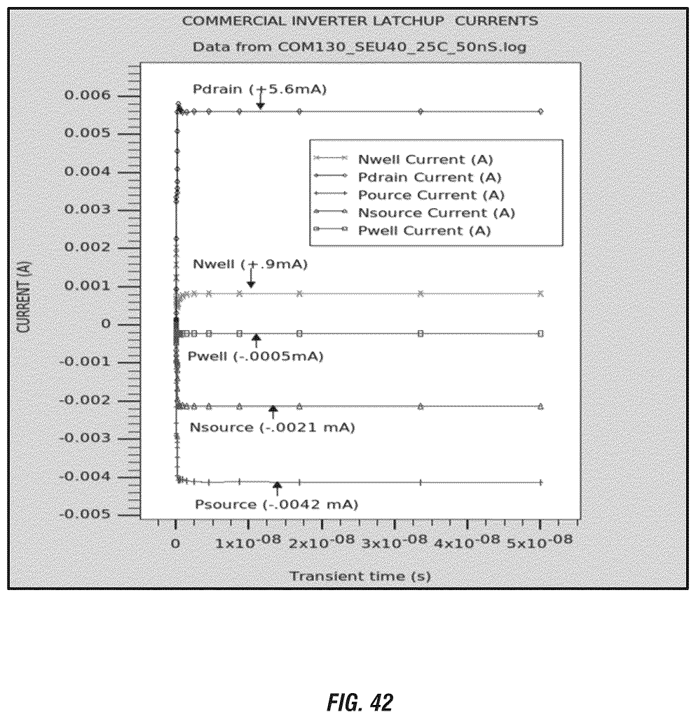

FIG. 39 shows a CMOS inverter with SBGR implemented recovering following a radiation particle strike and current flow to VSS. The upset mobile currents track low resistivity (low impedance) current paths through the SBGR regions for upsets occurring in the single inverter at minimum PTAP spacing that is extended to the surface PTAP metal layers. At this spacing the PTAP resistance is minimized and the IV plot shows with SBGR implemented the CMOS inverter upset recovery time is <2.2 nS shown in FIG. 40. And FIG. 42 shows for the commercial inverter which does NOT recover at 50 nS. After the upset is recovered the SBGR inverter will operate normally since no latchup occurs and the transient does not permanent. FIG. 41 shows 2D plot of latchup current flow from NWELL*J2 diode to PWELL N+ diffusion diode (J3) which is latched up and is an active thyristor that is permanently latched and will never recover. FIG. 42 shows TCAD simulation of a commercial transient upset has not recovered (at 50 nS) and because of the high resistivity below the PWELL contact region the upset current causes a dVin PWELL that forward bias the PWELL local potential to positive and CMOS inverter devices triggers into in a permanent non-destructive “stuck state”. The reason why it is non-destructive is due to low core operating voltage less than 1.2 volts which is not enough to drive the thyristor into saturation, but the upset is permanent and cannot recover until power-cycled (on-off).

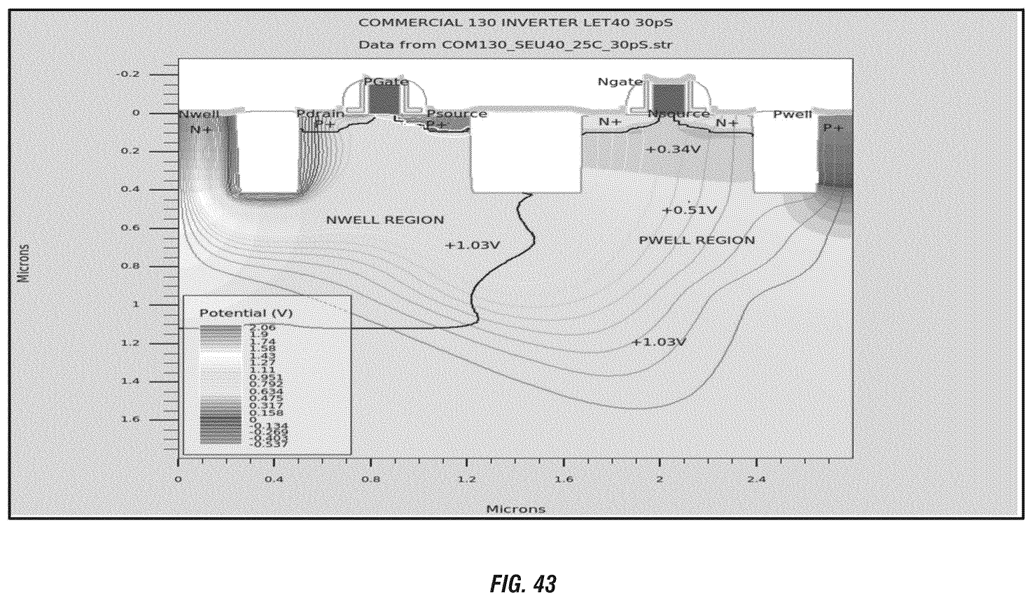

FIG. 43 shows a commercial CMOS inverter. The SEU (particle strike) is the same shown in FIG. 39-40 (SBGR upset recovered in <3 nS). However, a commercial PWELL region resistivity is high and whenever a transient upset occurs excess current sourced to PWELL region will cause a forward bias of the whole PWELL including the N+/p− diode which then activates the parasitic thyristor and triggers latchup. that shows the entire PWELL region is positive biased, except under small area under the PWELL PTAP.

### SBGR Pre Well Process Integration.

The high concentration boron doping implemented to form SBGR region can be implemented before the NWELL and PWELL regions are implanted (an abbreviated wafer processing example is described below) and is a non-invasive process integration.
1. Wafer manufacturing start;
2. Following AA photo and STI planarization process complete and AA alignment marks created;
3. SBGR Photo mask 1 is deposited and printed for the SBGR 500 Kev implant mask regions;
4. Boron (B11) is implanted at energy ranging from 50 to 1000 Kev and dose range (5e13 to 1e15);
5. After ion implant the photoresist is striped and wafer is cleaned;
6. SBGR Photo mask 2 is deposited and printed for the SBGR implant 2 mask regions;
7. Boron (B11) implants are performed at 50 Kev and 100 Kev with dose range 5e13 5 to 1e15;
8. Photoresist is stripped and cleaned;
9. The wafer is RTA anneal at >1050 C to dissolve implant defects; and
10. FIG. 20 shows the SBGR doping and STI region in silicon before the inverter wells are implanted;

FIG. 44 shows an example of the SBGR region implemented in PWELL region and extends (non-invasively) below the STI between the PTAP contact regions that extends to the inverter AA region spaced 2.6 microns. Yet, SBGR can be implemented into any inverter layout.

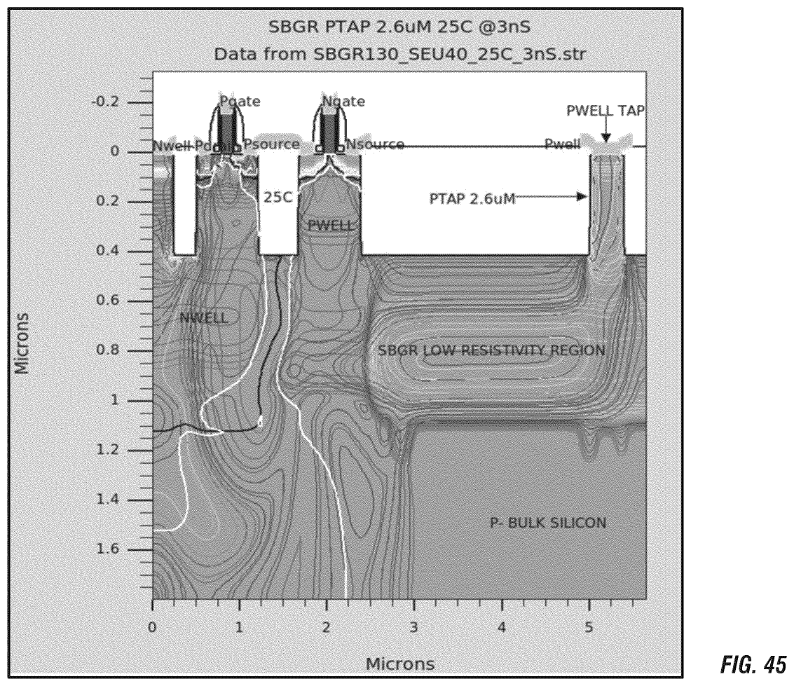

FIG. 45 shows 2D TCAD plot for an SBGR inverter spaced 2.6 microns away from the region that is upset by a radiation particle strike. The SBGR reduces the resistivity in the PWELL region below the dielectric oxide which increases hole upset current density conducted to the PTAP PWELL contact region without shifting the PWELL local potential above 0V. This prevents the N+/P− diode from forward biasing the J3 diode in the thyristor which cannot activate and latchup trigger is prevented. FIG. 45 shows the upset/recovery IV for the particle upset recovers at 2.2 nS, even with large PTAP spacing of 2.6 microns.

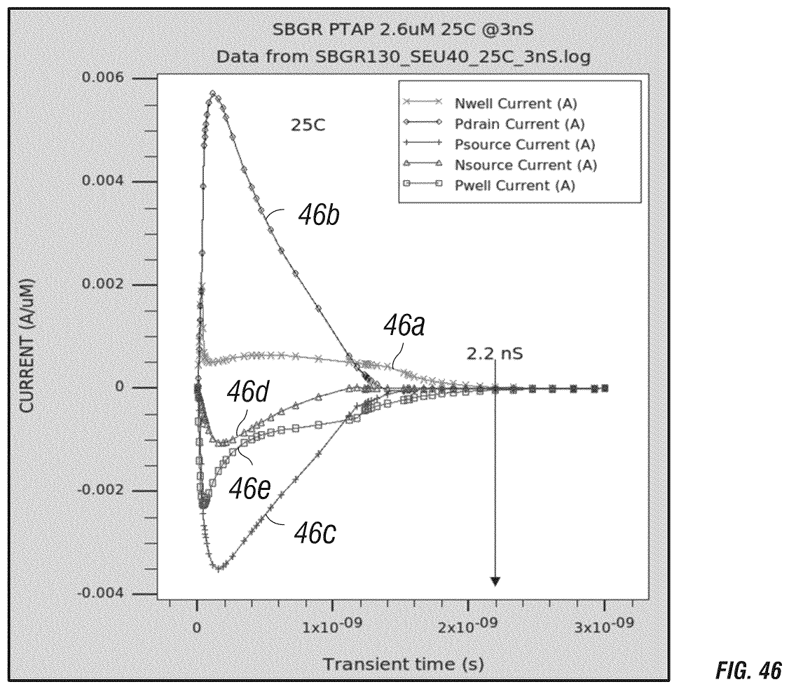

FIG. 46 depicts SBGR PTAP 2.6 micrometers at 25° C. and recovery time measurement extending to 3.0 ns where full recovery exists at 2.2 nS. As shown, currents are designated as the following: Nwell current 46a, Pdrain 46b, Psource 46c, Nsource 46d and Pwell 46e.

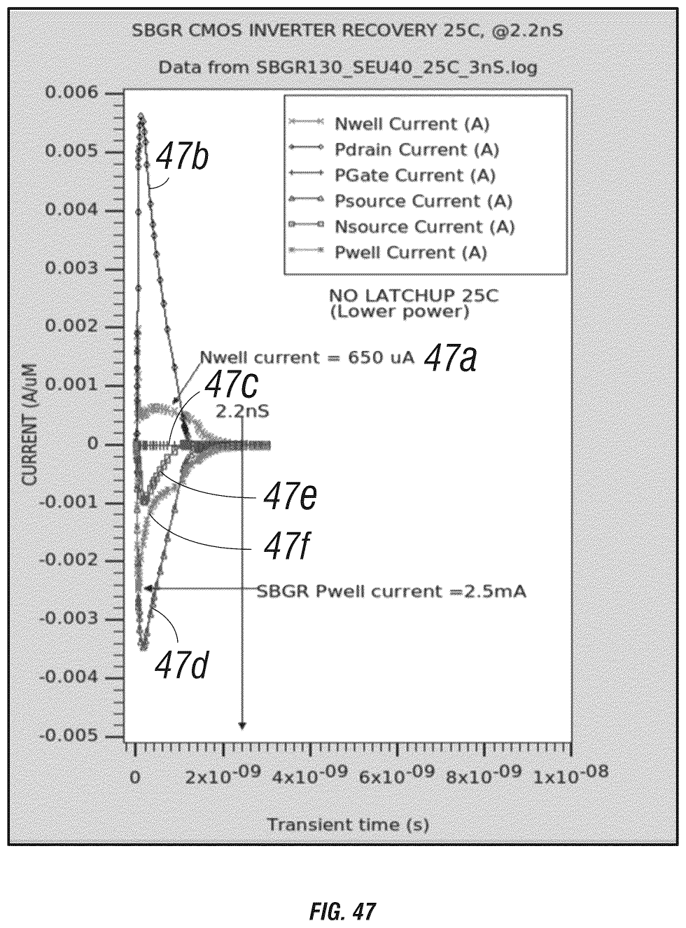

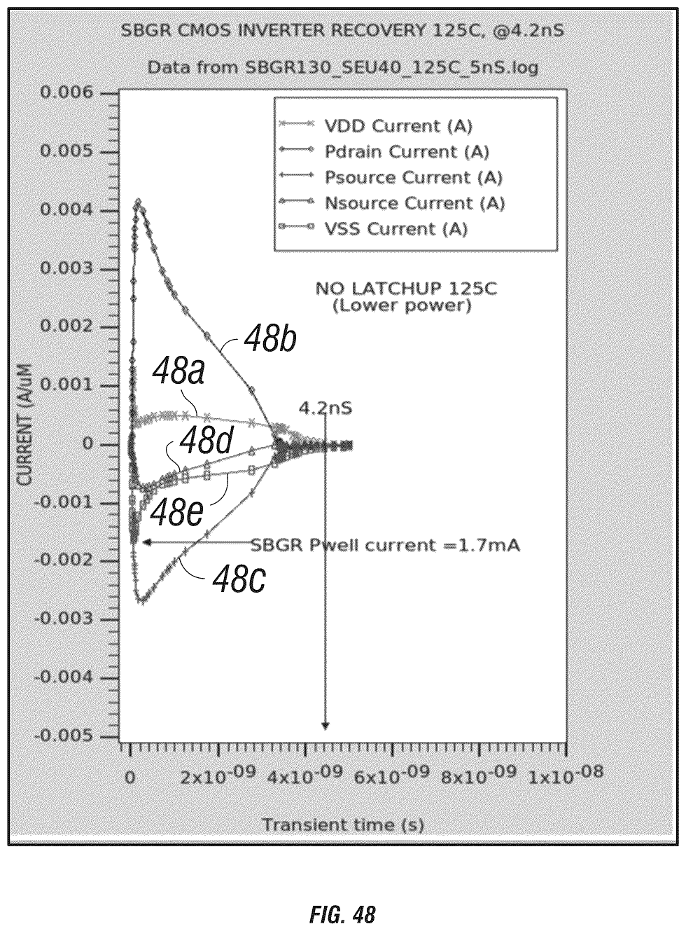

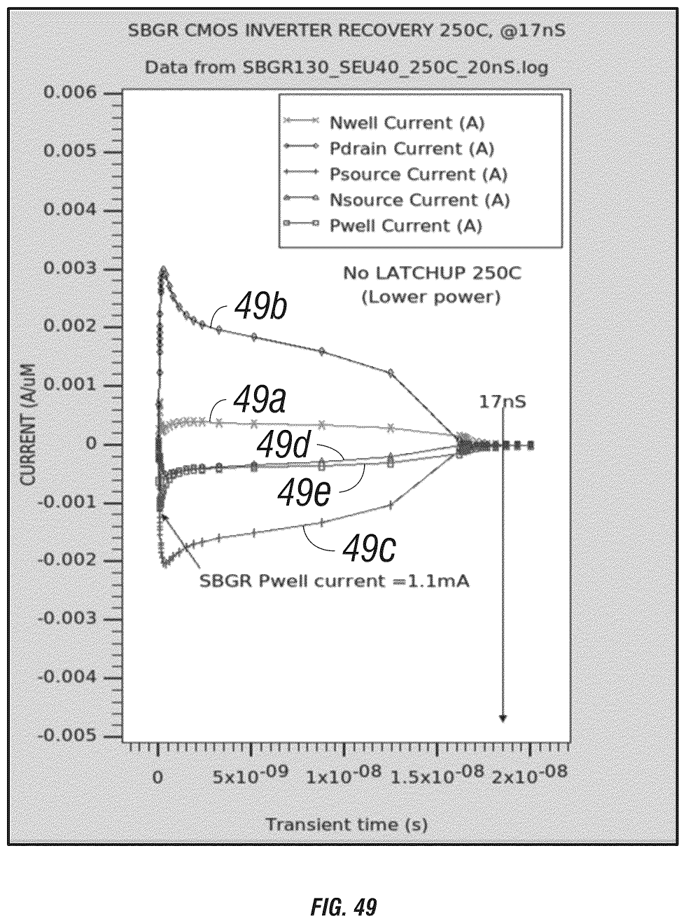

FIGS. 47, 48 and 49 shows transient upset recovery time (with no latch up) for 130 nm SBGR inverter that is operated at different temperatures, characterized by the same particle upset Linear Energy Transfer of 30 MeV, the strike with temperature equal to 25° C. (FIG. 47) recovers in 2.2 nS where currents are designated as follows: Nwell current 47a, Pdrain 47b, Pgate 47c, Psource 47d, Nsource 47e and Pwell 47f. For the same SEU strike at 125° C. (FIG. 48) the recovery time increased to 4.2 nS where currents are designated as follows: VDD (Nwell) current 48a, Pdrain 48b, Psource 48c, Nsource 48d and VSS (Pwell) 48e, and FIG. 49 shows that at 250° C. the SBGR low resistivity PWELL region prevents the thyristor J3 forward bias and triggering does not occur and the SEU upset recovery time is 17 nS where currents Nwell current 49a, Pdrain 49b, Psource 49c, Nsource 49d and Pwell 49e shown to extend as temperature increases but without latchup.

Previously shown in FIG. 25 compares PWELL resistivity for 5e17 doping concentration vs 8e14 doping concentration. The data plot shows as temperature increases, resistivity increases for the lower doped PWELL (i.e., 5e13) but not for the higher doped SBGR regions below the PWELL contact region which are doped at high concentrations (i.e., 8e14-1e15) resistivity does not increase even at 225° C. Implementing SBGR closer to the inverter layout (within PWELL) and any excess currents generated by the transient upsets do not induce a PWELL body dV shifts as temperature is increased to >250° C. the local potential (does not shift positively). This biasing caused by material properties that can be modified to prevent forward biasing of the N+/P− diode that remains in reverse bias blocking mode and latchup is avoided.

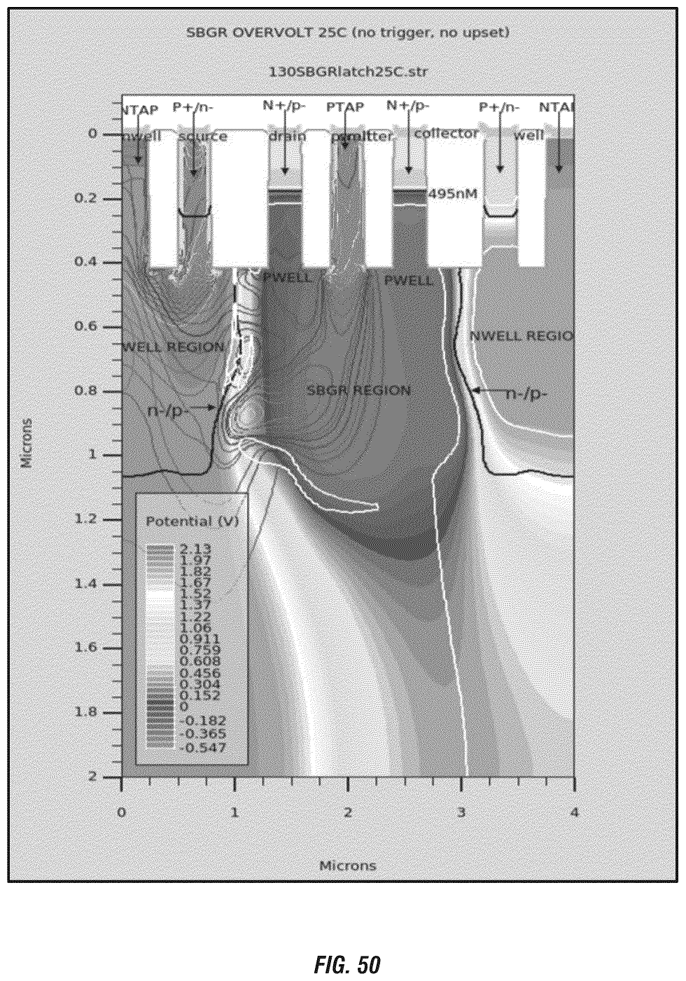

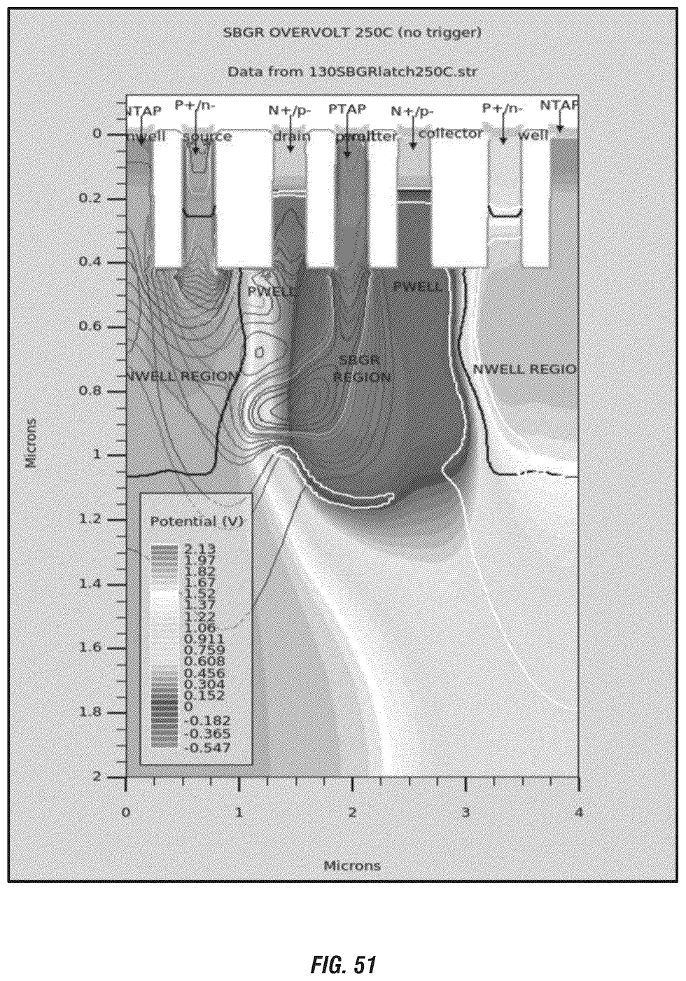

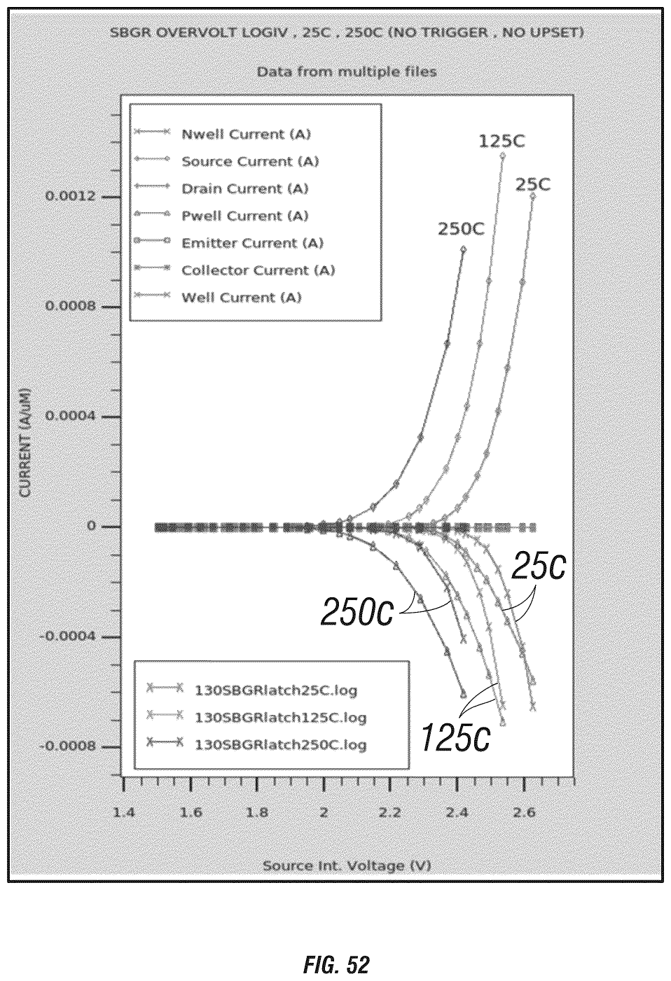

FIGS. 50, 51 show TCAD 2D data plots for an overvoltage transient upset for 25° C. and 250° C. that show the PWELL contact region below the dielectric isolation remain more negative voltage and does not shift (charging positively) during the upset. FIG. 52 shows the LOG IV overvolt data at 1 mA and for all temperature split cases (25° C. to 125° C. to 250° C.) does not trigger and no latchup upsets are observed for inverters operated even at the elevated temperatures.

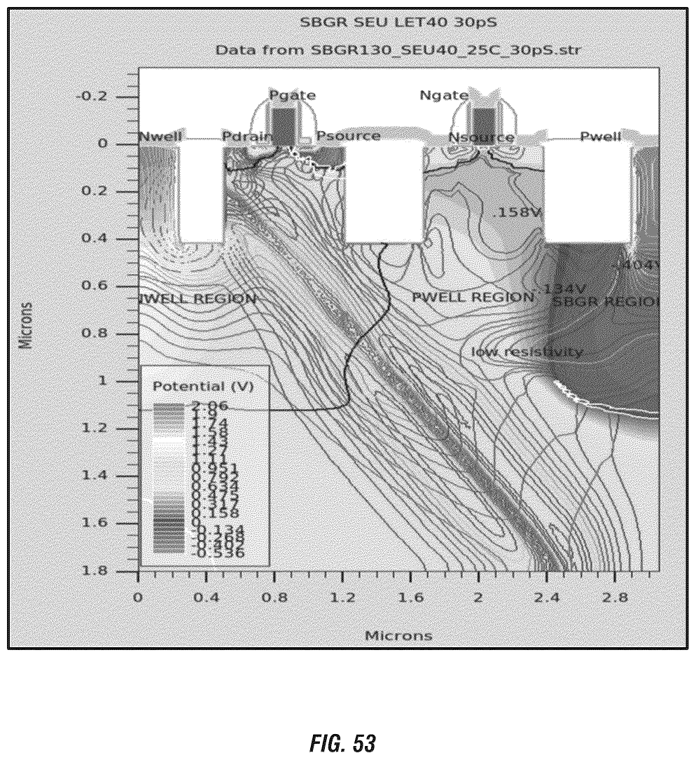

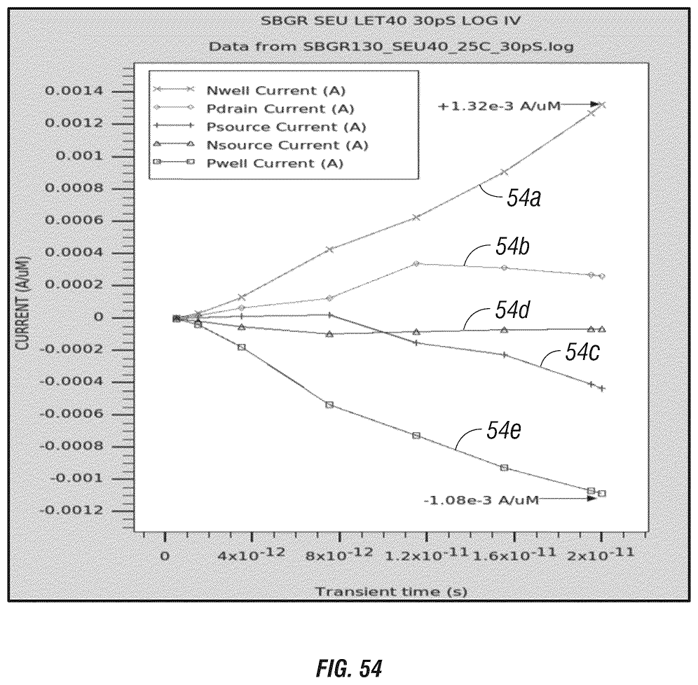

FIG. 53 shows SEU striking the CMOS inverter (25 C) and shows local potential increases in the PWELL region to +0.158V but do not shift to a positive potential for the SBGR PWELL region which remains at −1.34V and lower below the PTAP. Also note mobile upset currents are conducted to VSS across the PWELL region at 30 pS. The IV plot (FIG. 54) shows PWELL current conducted and terminated at VSS is >1 mA/uM and the entire upset fully recovers at 2.2 nS where currents are as follows: Nwell 54a, Pdrain 54b, Psource 54c, Nsource 54d and Pwell 54e.

SBGR structure is implemented closer to the active area which makes current conducted to VSS higher and more effective in withstanding SEU upsets far superior to prior art inventions because SBGR provides the following which prior art BGR shunt does not.
Latchup immunity for all extreme environments;
Higher operating temperature without latching up >250° C.;
Shorter transient recovery times to radiation particle strikes at all temperatures;
Prevents charge sharing between other nearby CMOS inverters (upset) and non-upset; and
Non-invasive chip integration to enable “re-purposing” applications of existing chip design without re-layout or limitations.

The SBGR manufacturability represents a simplified process modification vs prior art as follows:
Fewer process masking steps needed to implement;
Fewer ion implant steps required to implement;
Lower wafer processing cost to implement;
Can be fully implemented into any CMOS IC devices with no restrictions;
Non-invasive to inverter electrical behavior;
No counter doping of NWELL, no change in breakdown voltage and no change in leakage current; and
Simplified manufacturing.

SBGR solves the CHIP/sub-circuit integration problem and enabling reliable operation in extreme environments for all multifunctional CMOS IC device types such as BCD, mixed signal, Analog, RF, high voltage IO and ASIC logic, microprocessors with embedded (Flash) memory, and the like, which can be protected from latching up in extreme environments (e.g., high temperature and radiation).

SBGR structure implements a low resistor discrete region in PWELL (which behaves as a low R component) as an improved CMOS inverter that will not latchup and can operate reliably for thousands of hours at clock without failing. This represents the “technical breakthrough needed” as called for in SCR2 DECADAL-PLAN for “Extreme Environment IoT generation” as the use of CMOS expands beyond legacy CMOS device applications, PC's, cell phones and other existing CMOS devices can be “re-purposed” and could operate in extreme environments and new applications without re-designing the IC device itself.

### Side by Side Performance for SBGR Vs Commercial CMOS Inverter Upset/Recovery

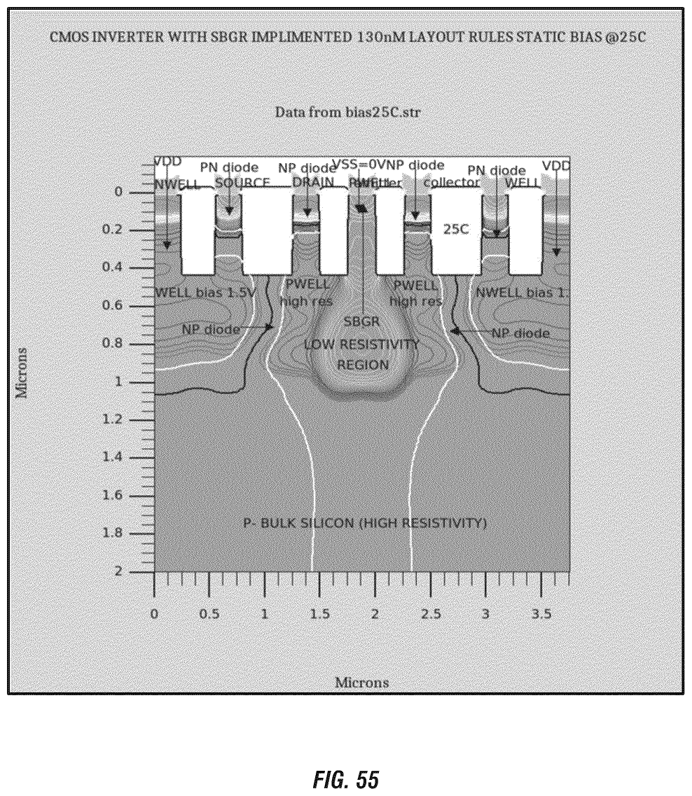

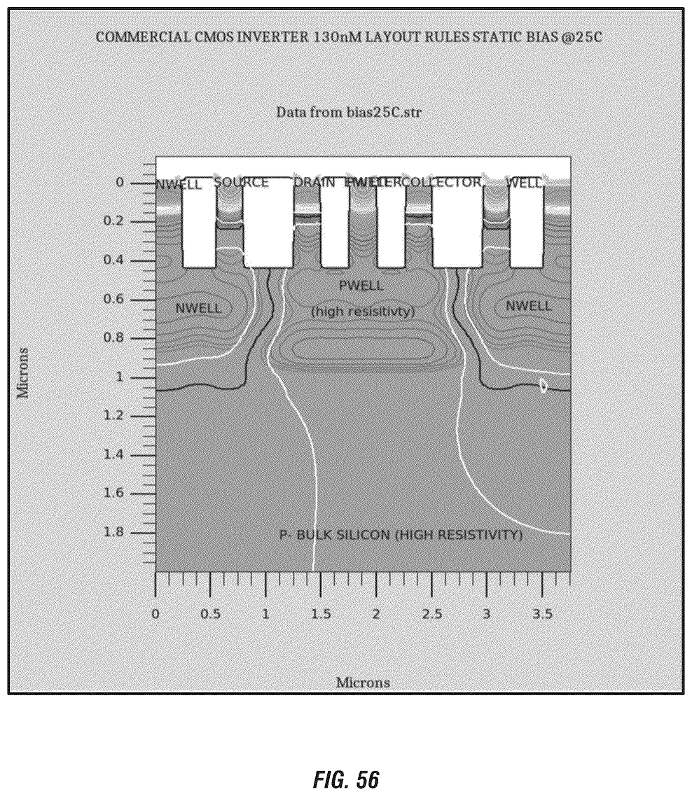

FIGS. 55-56 shows the SBGR innovative improved PWELL inverter layout which includes the SBGR doping region (increased doping) in a small area of the PWELL region to implementing a low resistivity P+ doping region within the PWELL below STI that will extend with PWELL length PTAP to PTAP (non-invasively) creating a low impedance current divider (shunt) that conducts excess positive currents at higher current densities to VSS at all temperatures up to 250° C. which prevents the PWELL (dV) body bias (shift in PWELL potential) and prevents the forward bias of the N+/P− diode (#3 NPN parasitic) keeping the diode in a reverse bias blocking state which eliminates the CMOS latchup trigger.

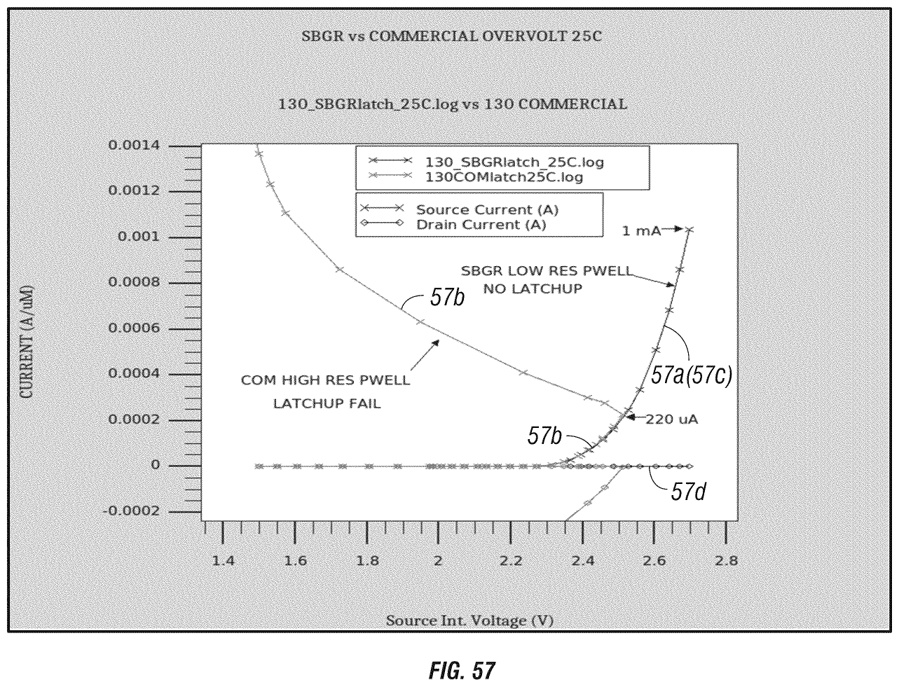

FIG. 57 shows a classic IV plot depicting the electrical overvoltage stress abr=(EOS) test utilized by the semi-conductor industry to determine the trigger current for a CMOS inverter, usually at 25° C. as depicted. The “trigger current” is the benchmark parameter to gauge overvoltage reliability. The red curve (the bifurcation of 57a from 57b) representing typical commercial inverter triggering showing the exact point the last J3 diode forward biases and “triggers into high current mode” going into runaway latching up”, in this case=220 um @ 2.5V (depicted as 220 uA), wherein latchup is an electrical “short.” Therefore, the voltage bias to get to the trigger current would be the maximum overvoltage the presented inverter can withstand before latching up, as would be disclosed in the specifications list. In contrast the identical inverter layout with SBGR implemented 57a (which is also the source current 57c) doesn't trigger or latchup. For SBGR the IV plot shows no “snap back” and current increase linearly with voltage increase to 1 mA which is more than 4 times higher than the commercial overvoltage stress test. Inverters operate a different voltage ranges, in this case it's a 130 nm core which is operated between 0V and 1.5V.

FIG. 57 further compares IV simulation data from an overvoltage electrical test (IV overlay) from a commercial overvolt trigger manufactured with a legacy commercial CMOS inverter which is high resistivity PWELL vs the same PWELL with SBGR implemented showing IV plot with SBGR PWELL which does not trigger even at high current >1 mA and overvoltage >2.6V (>1.1 Volts higher) than VDD (1.5V) where SBGR (low resistivity) Pwell 57a (source current 57c) is contrasted with 57b commercial CMOS 57b where Pdrain 57d remains constant.

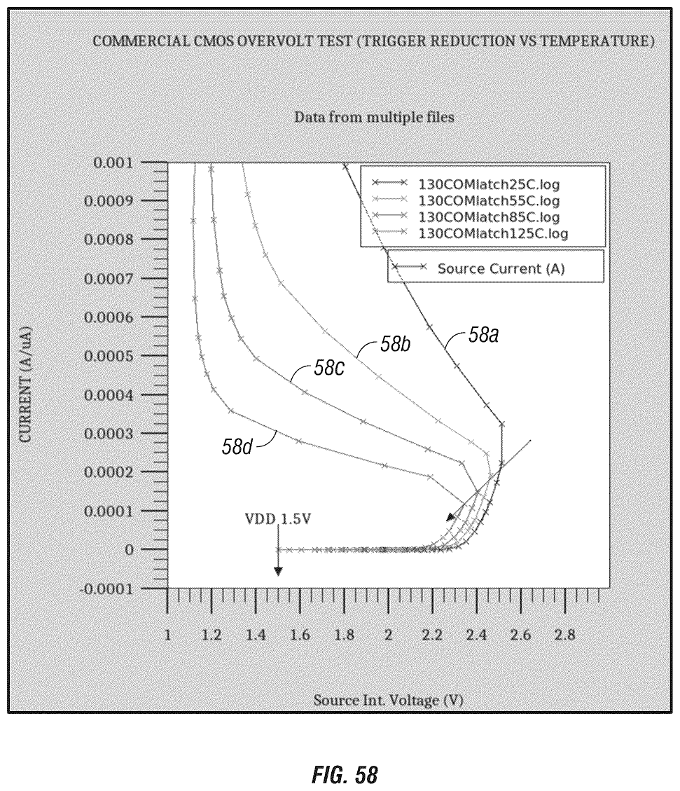

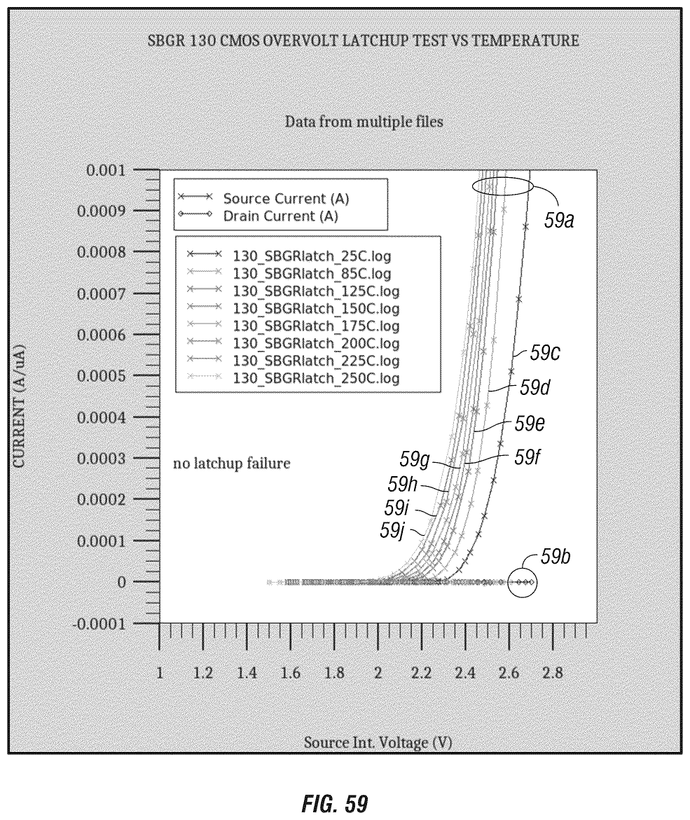

FIG. 58 represents commercial overvoltage showing trigger reduction for a commercial inverter at various temperatures (e.g., 25° C. 58a, 55° C. 58b, 85° C. 58c, and 125° C. 58d) vs SBGR inverter overvoltage shown in FIG. 59 which does not trigger or latchup for temperatures 25° C. to 250° C. For conventional commercial P-well, trigger current is reduced as temperature increase from 25° C. to 85° C., all fail. However, SBGR overvoltage shows no triggering for all temperatures 25° C. to 250° C. FIG. 58 further characterizes (EOS vs temperature) and shows as temperature is increased from 25° C. to 55° C. the trigger current decreases to 175 uA or about-20%. The reason for this is the silicon material resistivity also increases with temperature is (as also shown in FIG. 25), increasing temp increases resistivity (R) which reduces the magnitude of current needed to drive the J3 diode into forward bias as with a higher R, less current is required to forward bias and shift potential=dV. Therefore, resistivity (R) is critical wherein, as R lowers trigger current, when silicon is heated above 25° C. And all commercial inverters exhibit this feature where this is an inherent silicon material property. However, adding SBGR doping in PWELL changes resistivity in the PWELL region and facilitates conductance as shown in FIG. 25 for the SBGR (R) Resistivity plot.

TCAD data shows that, with identical layout and identical PWELL doping of the CMOS inverter implemented with SBGR (special masked doping), the 130 nM CMOS inverter (FIG. 59) does not fail at any temperature (25° C. to 250° C.) or at overvoltage >2.6V and P+ source current >1 mA/uM current. SBGR never triggers and does not fail permanently even if upset by extreme radiation particle energy of (LET86 Mev) while operating between 25° C. to 250° C. and remains latchup immune. Specifically, source currents 59a indicate no latchup failure (i.e., are latchup immune) even where temperatures increase as follows: 25° C. 59c to 85° C. 59d to 125° C. 59e to 150° C. 59f to 175° C. 59g to 200° C. 59h to 225° C. 59i to 250° C. 59j and drain current 59b remains constant.

FIG. 58 shows this effect of temperature increase on resistivity which increases and leads to reduction of the latchup trigger current. As shown in FIG. 58, at 25° C., the trigger current equals 220 uA, but at 55° C. the overvoltage trigger current is reduced to 175 uA and at 85 C trigger current is reduced to 150 uA, or 31% lower, with temperature increase. Semiconductors are specified to operate at 85° C. and, as shown, are expected to exhibit more latchup failures at 85° C. than at 25° C.

### 130 SEU Upset/Recovery

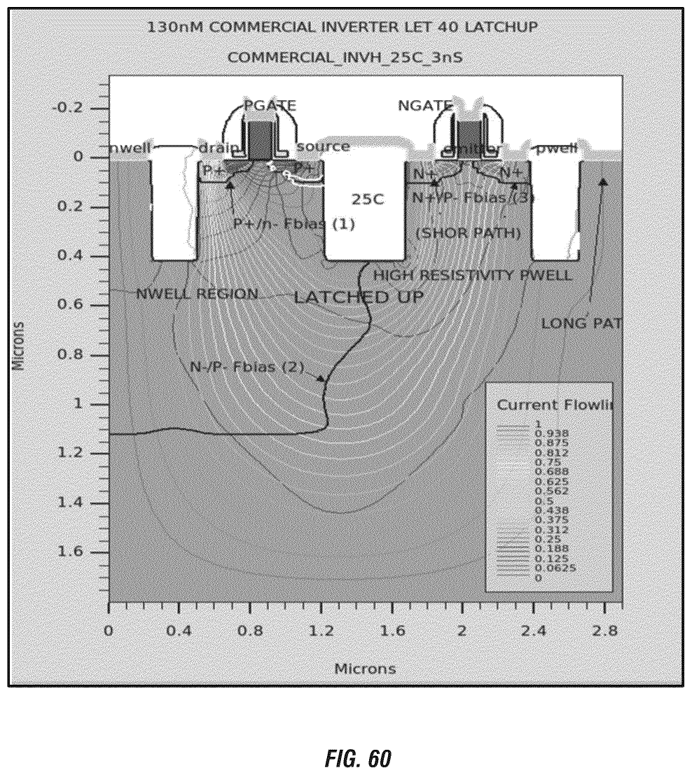

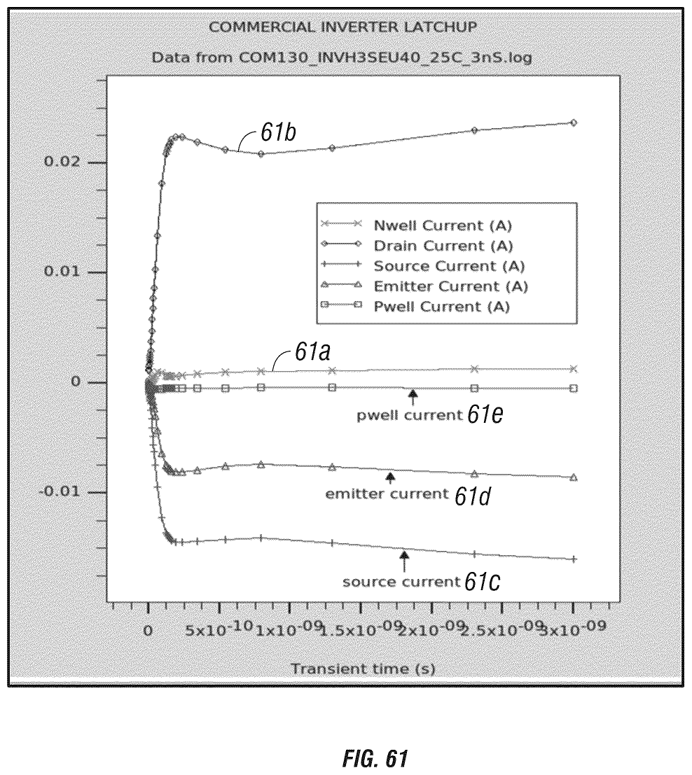

FIG. 60 and FIG. 61 show TCAD data for a Commercial inverter operating at 25° C. and triggered into permanent latchup from SEU particle strike (LET-86 MeV) which does not recover. Commercial 130 inverter struck by radiation particle trigger into permanent non-destructive latchup where currents are designated as follows: NWELL current 61a, Drain current 61b, Source current 61c, Emitter current 61d, and Pwell current 61e.

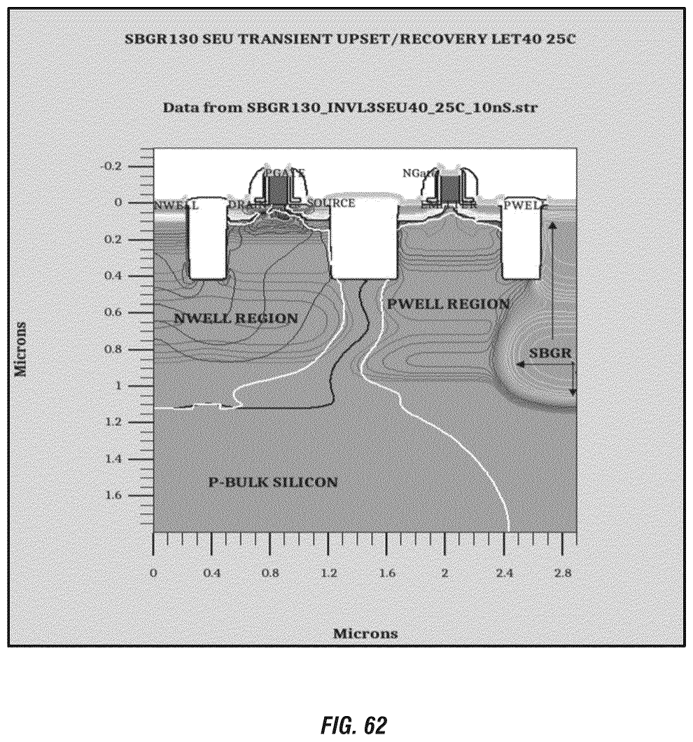

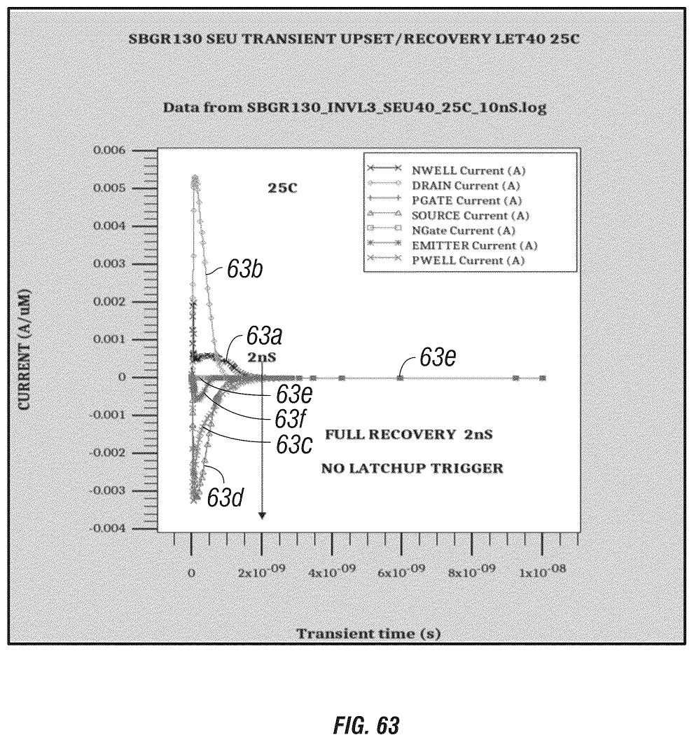

FIG. 62 shows 2D cross section for SBGR implemented into 130 nm Inverter with SBGR implemented that is recovered after being struck by SEU particle at 25° C., fully recovers in 2 nS. FIG. 63 shows the SBGR inverter IV transient upset current at 25° C. and recovery at 2 nS where NWELL current 63a, Drain current 63b, Pgate 63c, Source current 63d, Emitter current 63f and PWELL current 63g show recovery back to baseline Ngate 63e.

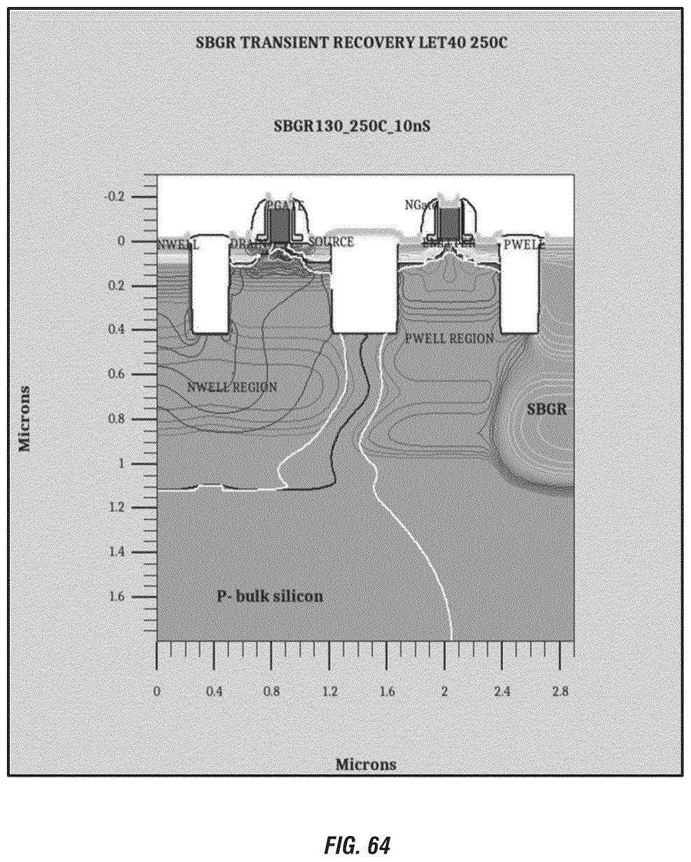

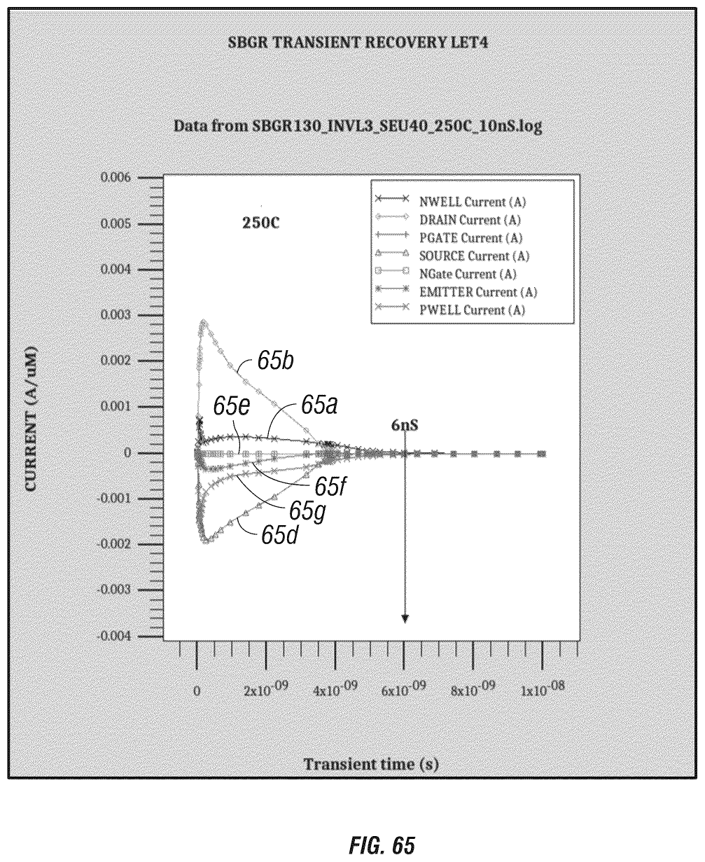

FIG. 64 shows 2D TCAD plot of a 130 nm Inverter with SBGR implemented struck by SEU fully recovered at 250° C., FIG. 65 shows IV upset at 250° C. and recovery time equals 6 nS where NWELL current 65a, Drain current 65b, Pgate 65c, Source current 65d, Emitter current 65f and PWELL current 65g show recovery back to baseline Ngate 65e. SBGR implements low resistivity region within PWELL below the contact region that will prevent thyristor activation at extreme ambient temperatures.

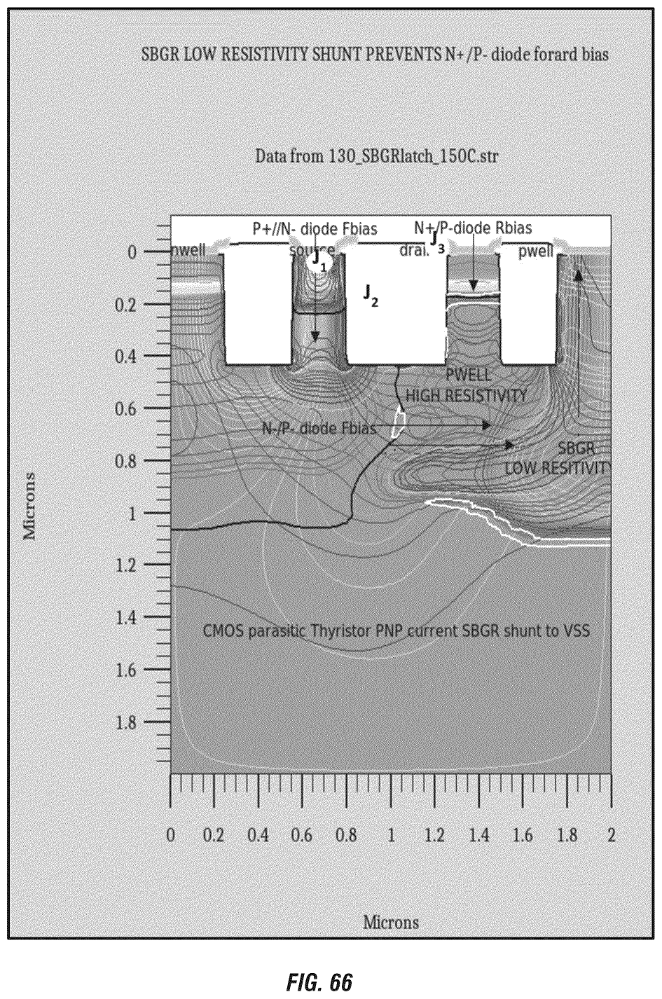

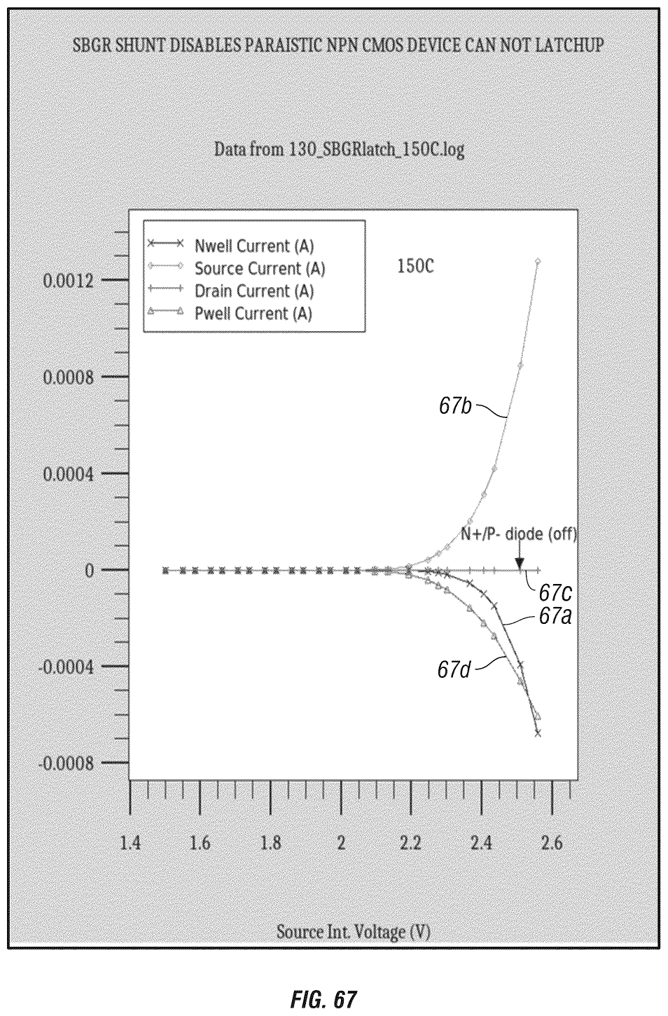

FIG. 66 shows TCAD 2D data for overvolt transient at 150° C., which shows high density upset currents flowing from NWELL J2 diode across high resistivity pwell region to the low resistivity SBGR region below the PWELL contact region. SBGR doping reduces the local potential below the PWELL contract region more negative which blocks forward bias of the N+/P− diode (J3). FIG. 66 slows the depletion regions are in (reverse biased) at the J3 diode which prevents activation of the parasitic thyristor and FIG. 67 shows overvolt IV current with no latchup triggering at 150° C. and overvoltage >2.6V with 1.2 mA current flowing to VSS, SBGR blocks J3 and enables latchup immunity where NWELL current 67a, Source current 67b, and PWELL current 67d are unaffected by latchup and N=/P− diode (drain) current 67c remains flat (off).

### 40 nm Characterization

SBGR can be integrated into the commercial wafer manufacturing process for 40 nM using the same architecture as described for 130 nm with the smaller layout rules to implement SBGR in the 40 nm inverter layout below the PWELL contact region. SBGR is implemented into the PWELL region of 40 nmM CMOS inverter layouts and reduces resistivity in the 40 nm PWELL contact region non-invasively to avoid PWELL self-biasing thereby deactivates the parasitic thyristor. In this case a CMOS latchup structure is used for both overvoltage and SEU transient upset recovery.

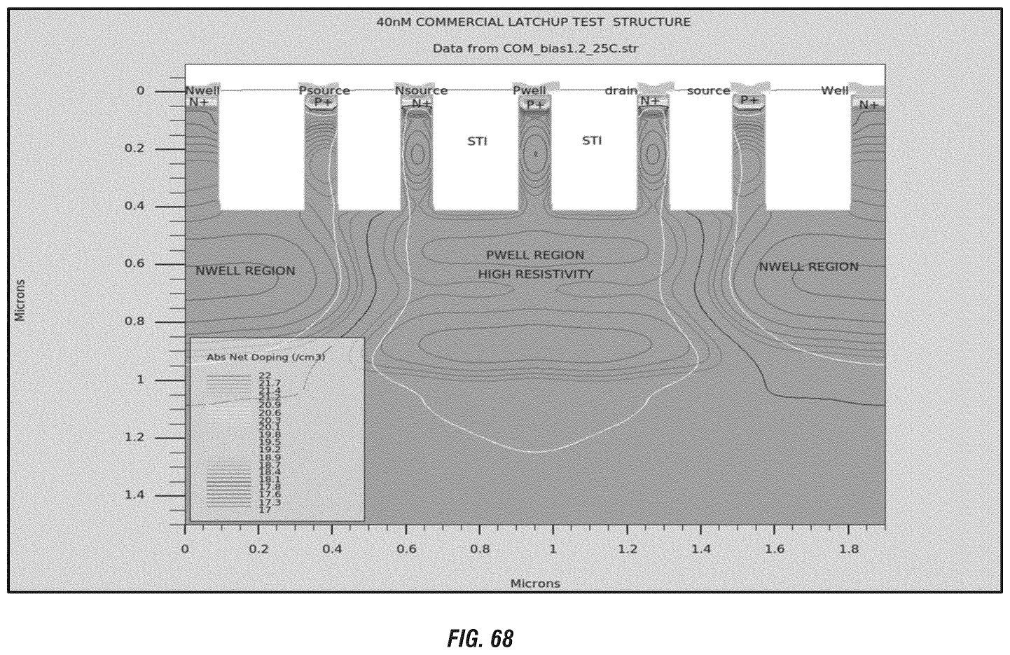

FIG. 68 shows a 40 nM commercial N-WELL/P-WELL/N-WELL latchup characterization test structure that is used to characterize overvoltage latchup and SEU upset recovery at higher temperatures.

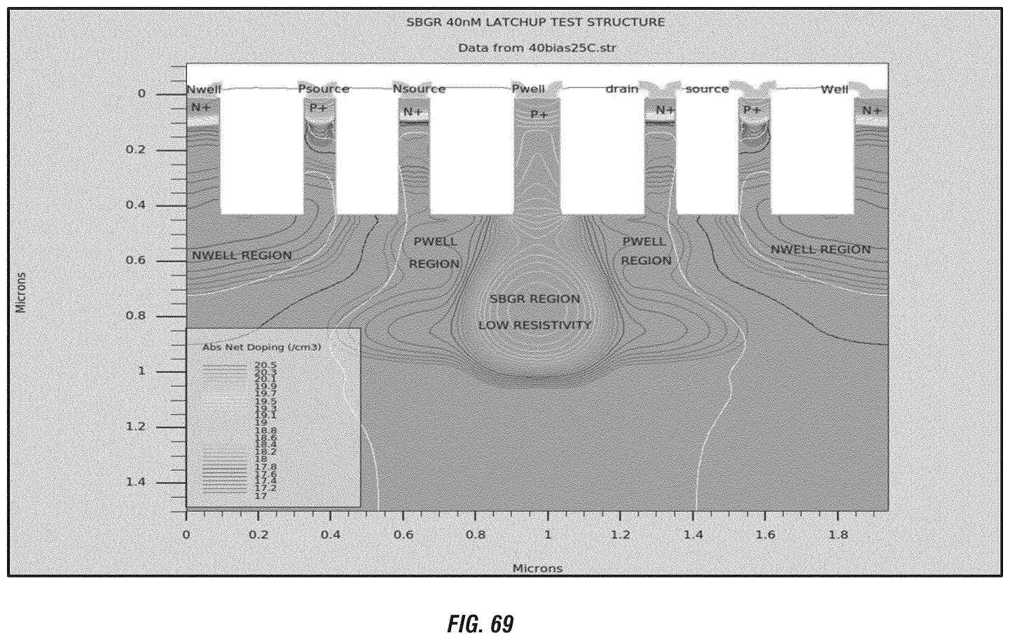

FIG. 69 shows a 40 nM (NWELL/PWELL/NWELL) test structure with SBGR implemented below the PWELL contract region.

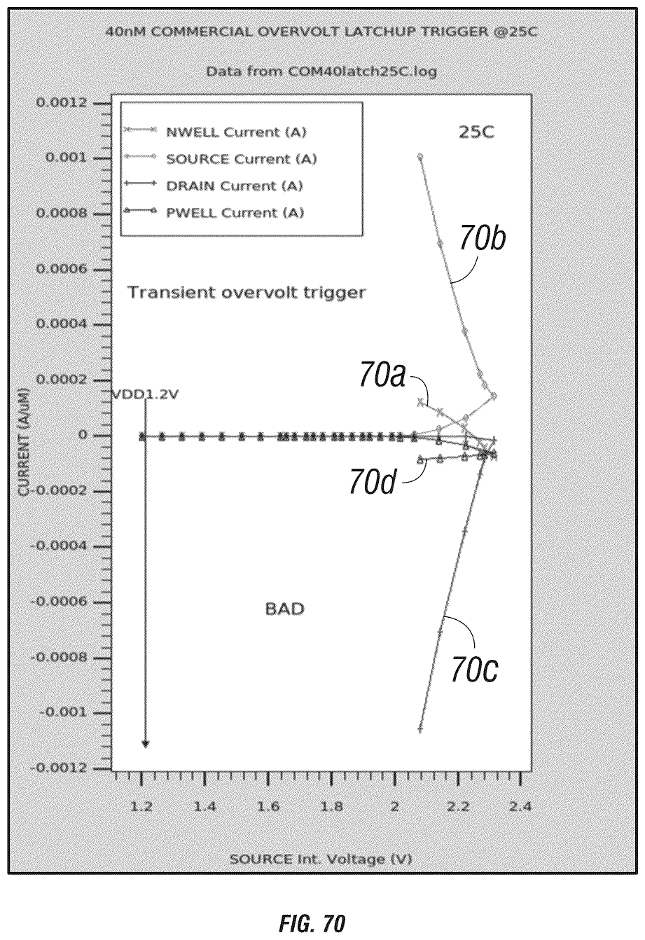

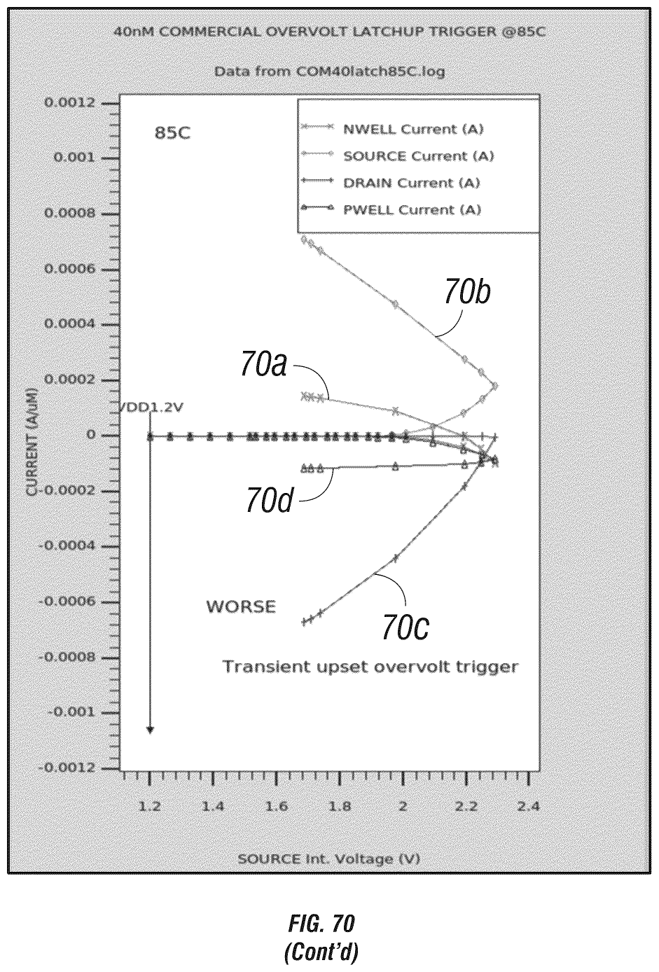

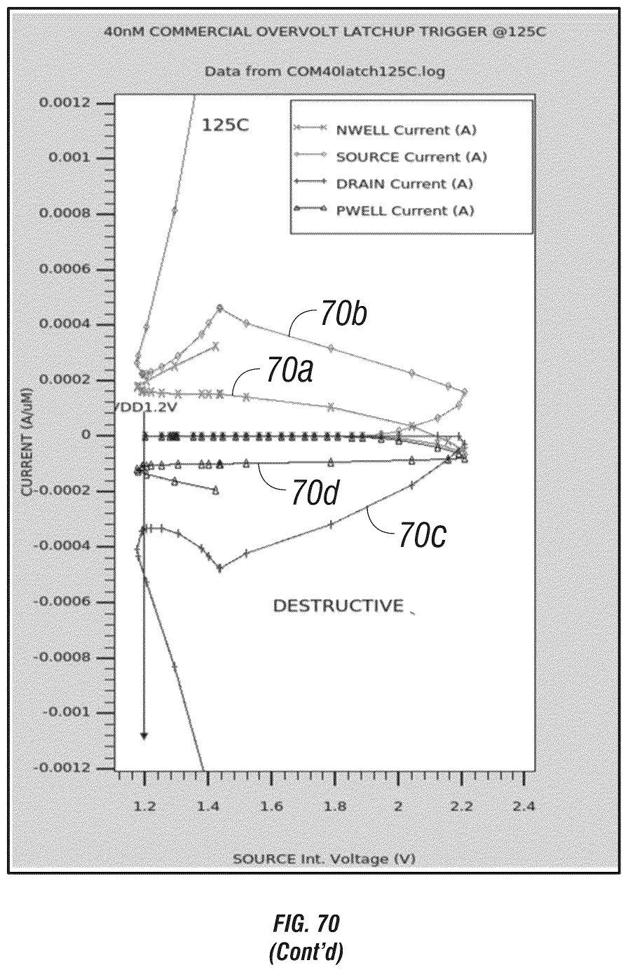

FIG. 70 shows the IV overvolt latchup trigger for the 40 nM commercial CMOS latchup test structure layout. The P+ source diffusion is overbiased to >0.7V above VDD to characterize triggering current IV at three temperatures (25° C. (left), 85° C. (middle) and 125° C. (right)), respectively. TCAD simulation data shows as temperature increases, latchup trigger current decreases and current snap back (negative resistance) increases where NEWLL current 70a, Source current 70b, Drain current 70c and PWELL current 70d all show indications of overvolt latchup.

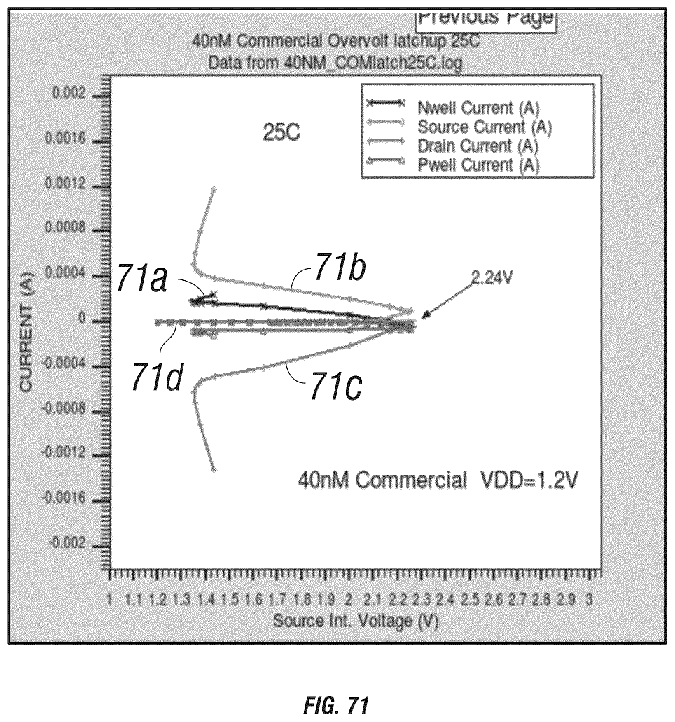

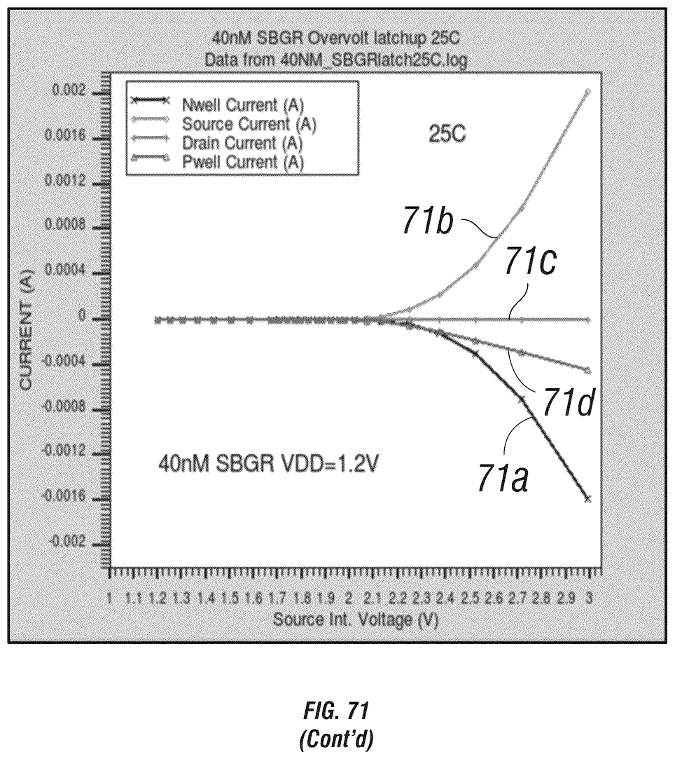

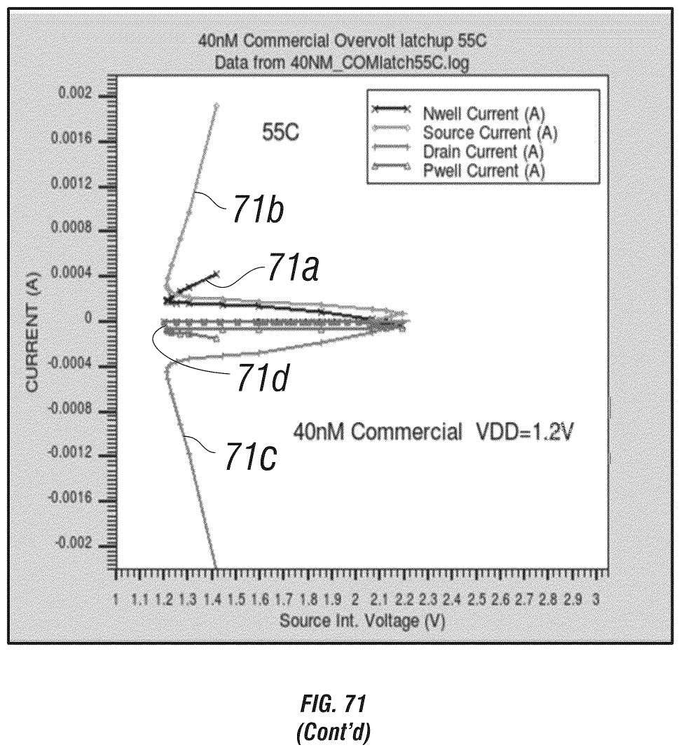

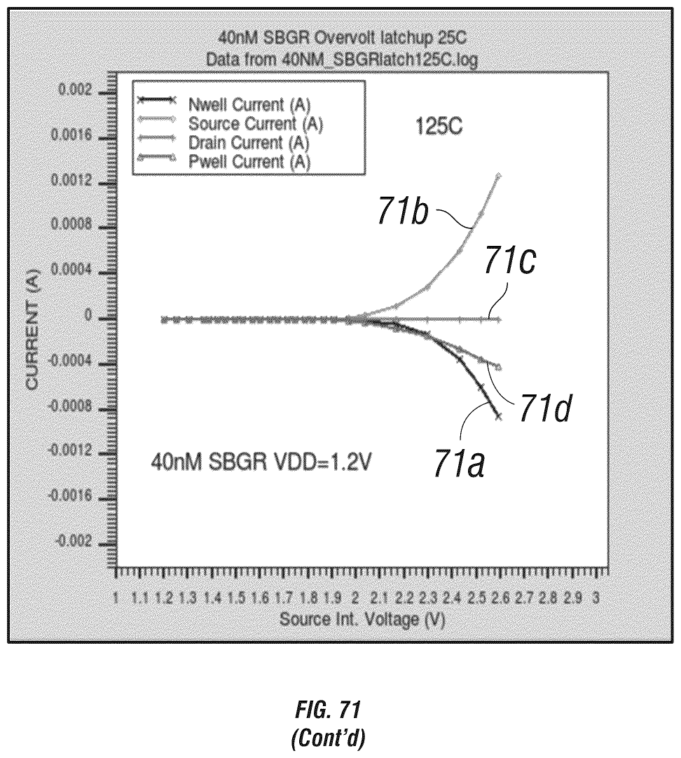

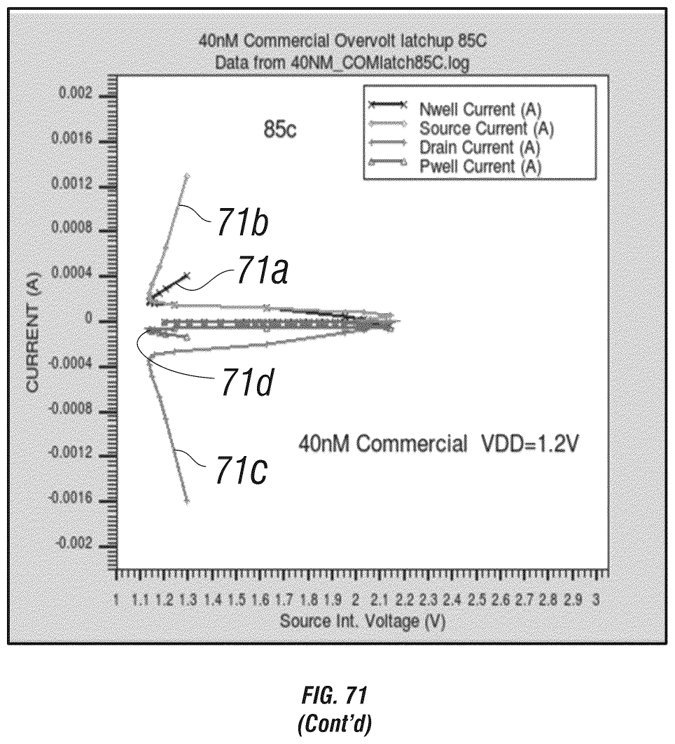

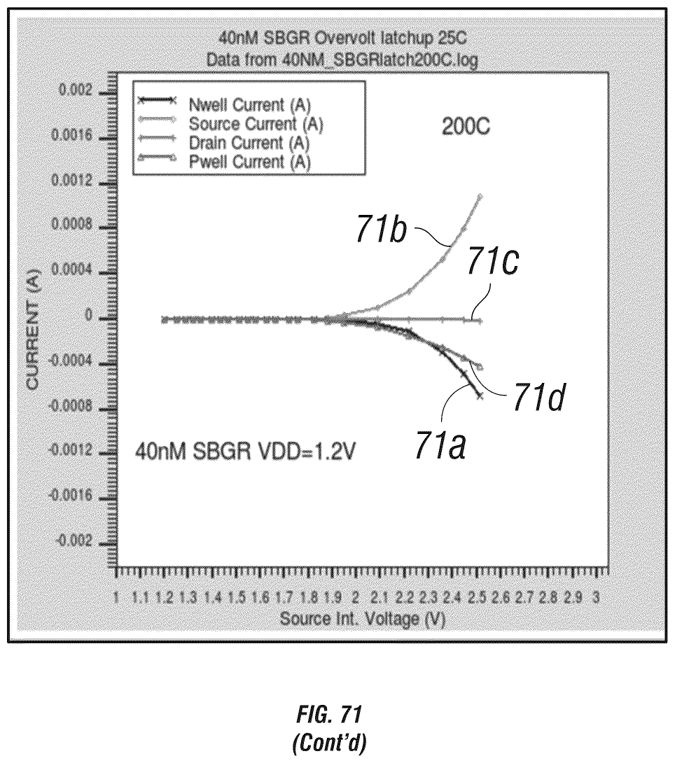

FIG. 71 (top row) shows latchup IV data for a 40 nm commercial latchup test structure, which has triggered into latchup at 3 different temperatures. The top row plots the IV current for the commercial that shows latchup failure for 25° C. (left), 55° C. (middle) and 85° C. (right) (i.e., CMOS commercial spec temperatures), respectively. Whereas the bottom row shows 3 SBGR IV plots for the SBGR modified CMOS latchup test structure which does not latchup at 25° C. (left), 125° C. (middle) or at 200° C. (right), respectively, where each of NWELL current 71a, Source current 71b, Drain current 71c and PWELL current 71d indicate latchup in the superior commercial CMOS inverter diagrams and non-latchup in the inferior SBGR doped region diagrams.

All 40 nm SBGR CMOS devices will be latchup immune and operate at 250° C. without latching up. All 40 nm commercial CMOS devices, conversely, will latchup even at 25° C.

### 40 nM SEU Transient Upset Recovery

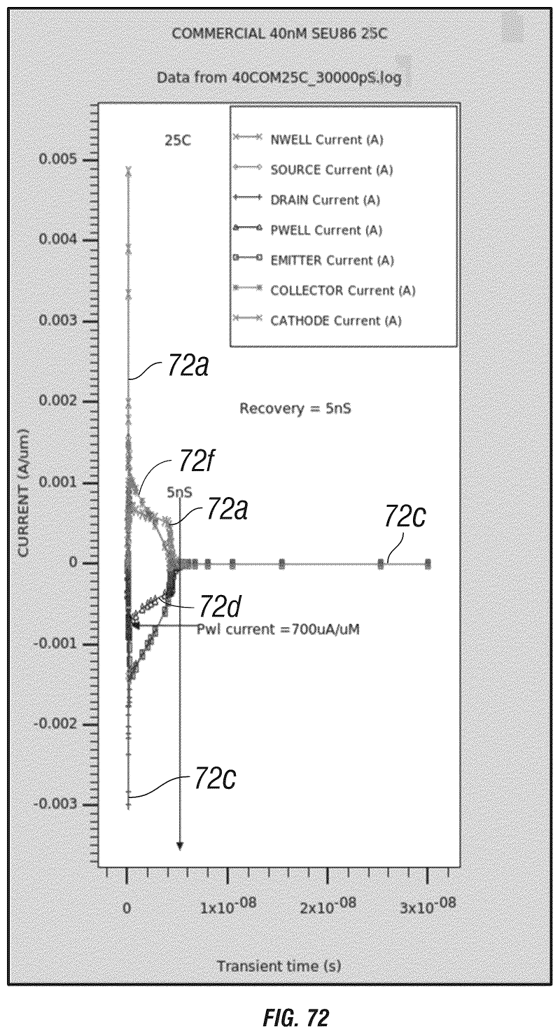

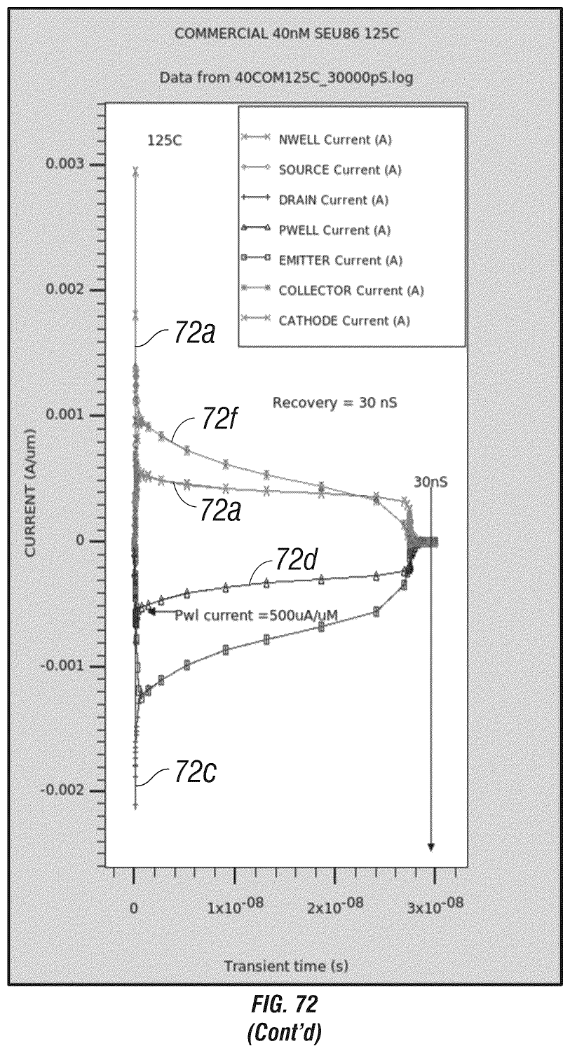

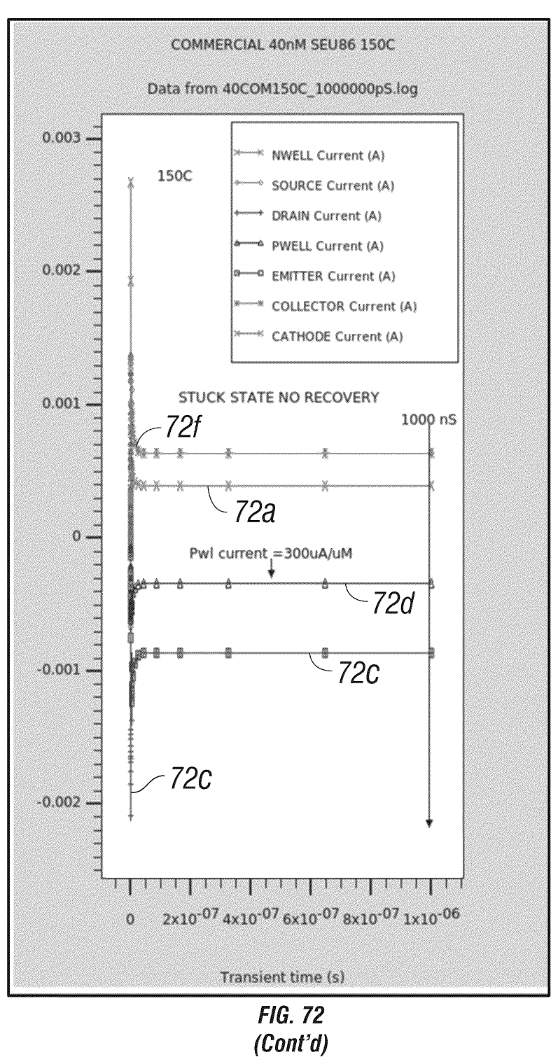

FIG. 72 shows a 40 nM commercial inverter SEU transient upset/recovery for different temperatures. TCAD data show as ambient temperature is increased from 25° C. (left) to 125° C. (middle) the transient upset recovery time increase from 5 nS to 30 nS which is 6× longer than at 25° C. And at 150° C. (right) the commercial transient never recovers and the CMOS device is a permanent upset state. Increasing temperature increases silicon resistivity which is inversely proportional to current conductance.

For each plot in FIG. 72 showing a commercial device's transient recovery time increase at 150° C. where the high PWELL resistivity makes the upset permanent which can only be improved by modifying PWELL doping and current conduction may be improved to prevent forward bias of J3 (as described herein). The TCAD characterization shows for commercial CMOS devices at 40 nm the lower core voltage and the operation temperature significantly changes transient latchup and transient recovery behavior as follows where NWELL current 72a, Source current 72b, Drain current 72c, PWELL current 72d, Collector current 72f exhibit latchup at 5 nS at 25° C., 30 nS at 125° C. and stuck state (no recovery) and >1000 nS at 150° C. where the following is observed:
1. lower Core voltage prevents permanent destructive latchup, normally observed;
2. lower core voltage increased transient recovery time for non-permanent upsets due to low drive strength of the CMOS devices; and
3. permanent non-destructive latchup is observed, namely a “permanent stuck state”, which can only be cleared by power cycling.

### SBGR Transient Upset Recovery (Simulation Data)

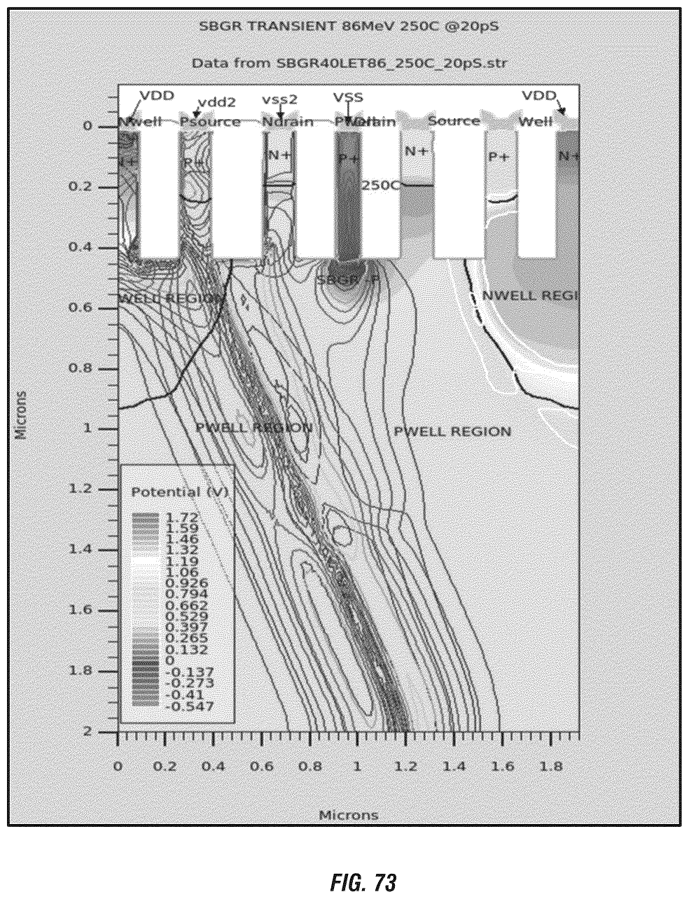

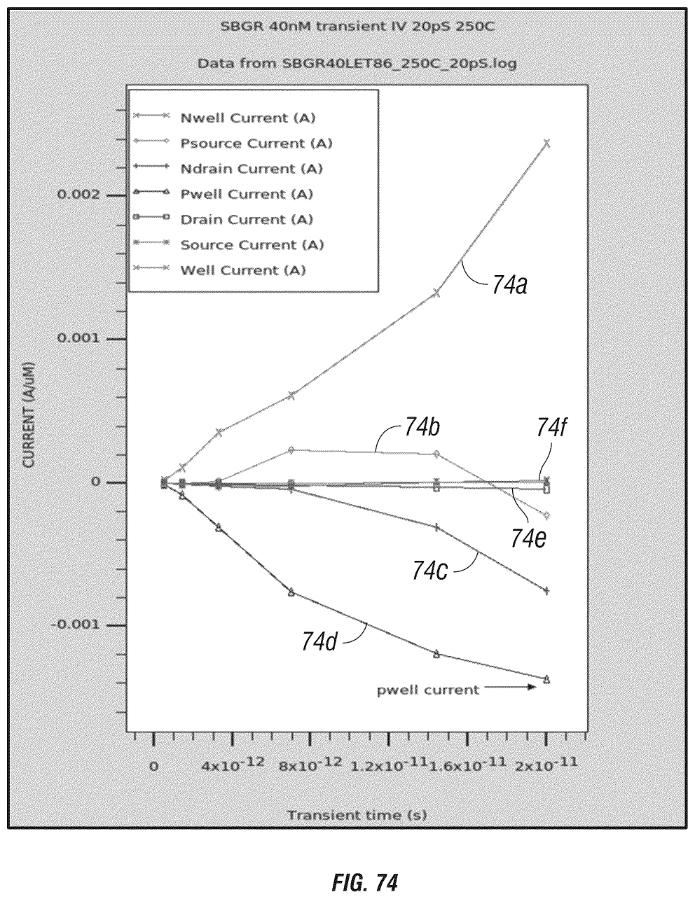

FIGS. 73-74 shows an SEU upset which is different with SBGR implemented into the PWELL discussed above. The left plot, FIG. 73, shows 2D data for a heavy ion particle track that causes an SEU upset at 20 pS time sequence and at silicon temperature is at 250° C. The 2D plot highlights the silicon potential shows the PWELL region is positively upset and is conducting mobile carriers (electrons and holes=excess current) generated by the particle strike. The right plot, FIG. 74, shows the terminal currents being conducted to the metalized terminals (7 different terminals: NWELL 74a, Psource 74b, Ndrain 74c, PWELL 74d, Drain current 74e, Source current 74f and Well current 74g) at 250° C. With SBGR implemented in the PWELL contact regions the terminal current is >1.7 mA (at 250° C.) more than 2× higher current conduction as compared to 700 uA for the commercial split upset data operating at 25 C. SBGR doping density increases conductivity and shunts the excess current away from J3 prevents triggering failure which reduces recovery time.

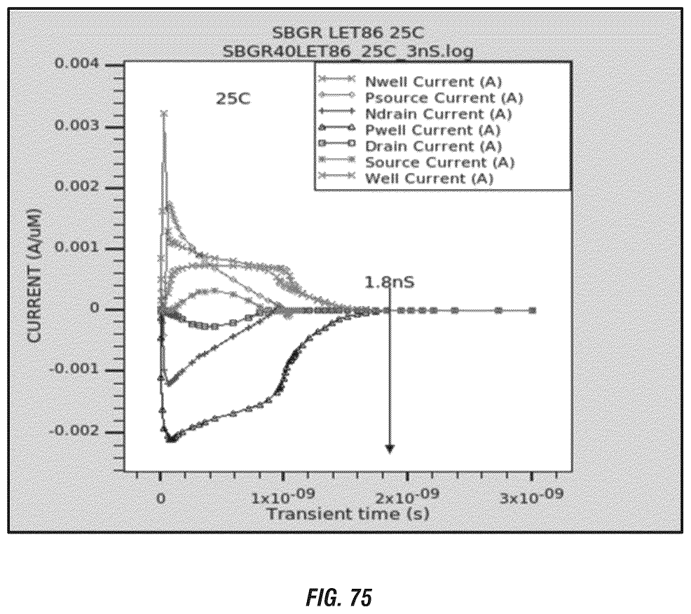

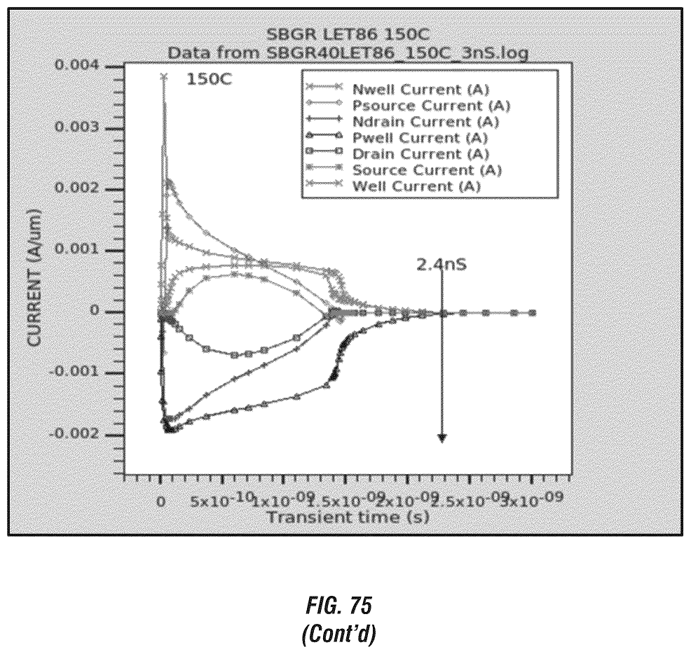

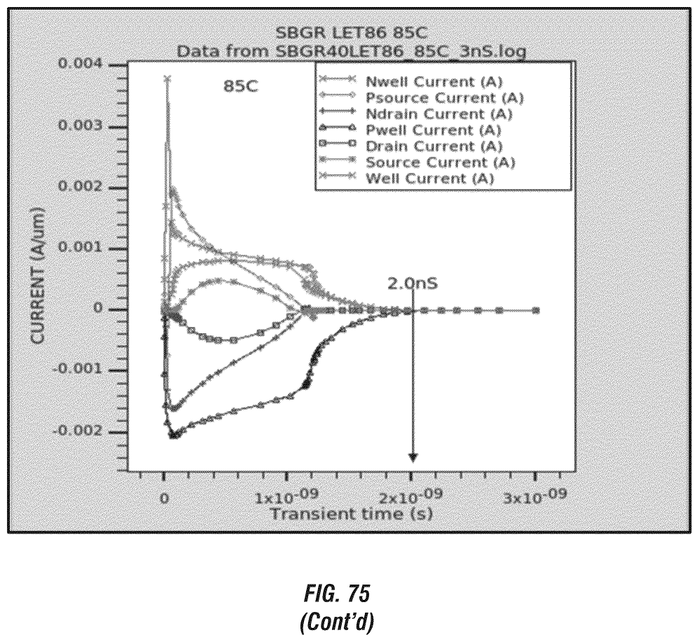

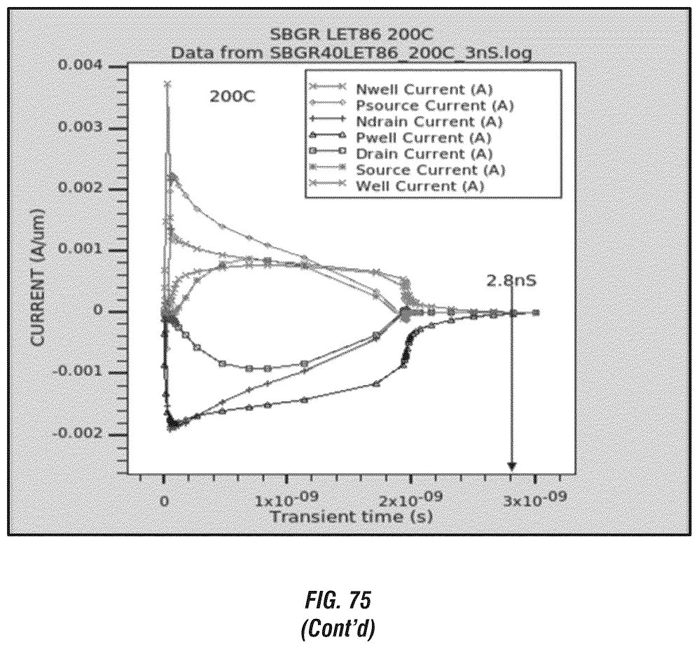

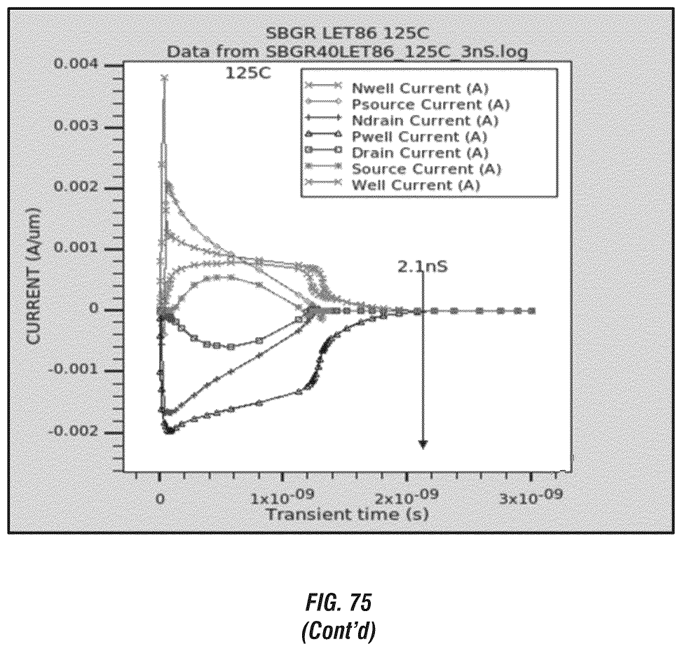

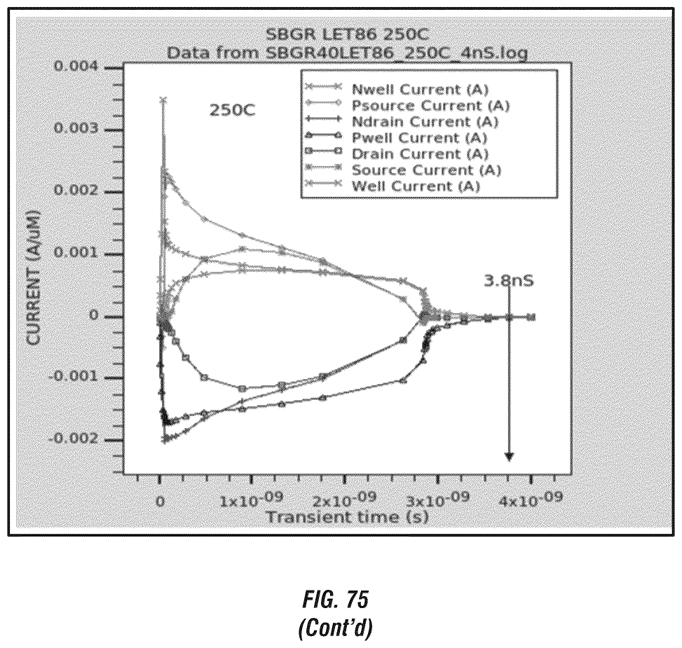

As can be seen in the recovery plots shown in FIG. 75, SBGR eliminates the parasitic thyristor (activation) by providing a low resistivity conductance region in the PWELL contact region that creates a shunt bypass to VSS that increases conduction of “excess upset currents” generated by transient overvoltage events or radiation particle upset events that enables the Inverter to recover from the upset and continue operating at normal operating voltage state as the excess charges are conducted away and out of the IC device to the VSS and VDD metal terminals. Now with the thyristor absent no permanent upset activation persists at 25° C. (upper left), 85° C. (upper middle), 125° C. (upper right), 150° C. (bottom left), 200° C. (bottom middle) and 250° C. (bottom right), from left to right and top to bottom, exhibiting 1.8 nS, 2.0 nS, 2.1 nS, 2.4 nS, 2.8 nS and 3.8 nS recovery times. With SBGR implemented into the PWELL contact region CMOS devices can operate at extreme temperatures which is impossible for commercial CMOS device.

SBGR also acts to offset increased temperature effects by increasing P+ doping in certain PWELL and other masked regions which that shifts p− region potential more negatively and lower resistivity which increase upset current conduction and speeds potential recovery. The characterization of SBGR (i.e., short recover times, operation at extreme temperatures, and no latchup is observed at 250° C.), shown for 130 nm and 40 nm in the claims and figures in this disclosure, consistently show that CMOS latchup can be prevented my modifying the CMOS wafer manufacturing process to add the SBGR doping regions (using masking) into PWELL select regions and can be done “non-invasively” enabling the use of SBGR to manufacture new types of CMOS IC devices that are capable of operation (latchup immune functionality) in both (1) low and high temperature settings and (2) high radiation environments thereby decreasing transient upsets and avoiding permanent failures in many different IC device applications. SBGR technology can be implemented into smaller CMOS generations also and can make 28 nm and FINFET CMOS generations latchup immune to radiation effects and operate more reliably at high temperature capable as shown in this disclosure.

SBGR is the solution and “a technology breakthrough” needed for future IOT applications that require more robust electronic devices which can operate in higher temperature and radiation environments without failure. This is possible for a least the following:
permanent latchup immunity in all extreme environment;
capability of operating in extreme temperatures (<−55° C. TO >250° C.);
manufactured on bulk wafers (mainstream, leading edge geometry at affordable lower costs will solve transient and temperature reliability issues to allow robust CMOS devices that are more effective for all apps);
can be manufactured by high volume silicon foundries (high yield, low die cost);
SBGR can be implemented into all CMOS device types (digital lotic, analog, mixed signal, memory, smart power);
most advanced CMOS devices (latchup immune FinFET IO regions);
all CMOS mosFET generations (FinFET IO's, 28 nm to >legacy generations >5 micron);
can be implemented into existing CMOS designs (over millions of proven CMOS designs);
all future SBGR CMOS device will be latchup immune and capable of operation in extreme environments;
all IOT terrestrial applications, smart grid, solar power improvements in efficiency by reducing current transport losses to anode and cathode can be improved, fail safe omni directional devices for auto drive, HT RFID devices for industrial manufacturing apps and enable automotive tracking guidance, precision navigation electronics that are more reliable;
reliable operation in radiation environments for all earth orbits, or deep space satellite applications, missions, planetary space craft explorations;
global satellite constellations at MEO flight levels that is required for space only global communications, and US national defense;
high reliability commercial applications (Automotive, Aviation and HT O&G downhole);
for >40 years CMOS technology has followed Moore's law, now in 2022, beyond the 12 nM node the limitation is current density self-heating limits CMOS devices that have to reduce data thruput to avoid latching up, SBGR would enable higher digital thruput and more reliable scaled CMOS devices that meet ITRS advanced goals to this next level; and
SEMI SCR consortium sees “extreme environments” as one of the next goals for semi-industry to overcome and advance and broaden CMOS applications for all earth and space applications.

### SBGR Non-Pilot, Machine Controlled Automation Applications:

While inventor has set forth the best mode or modes contemplated of carrying out the invention known to inventor such to enable a person skilled in the art to construct and practice the present invention, the preferred embodiments disclosed are, however, not intended to be limited in scope, but, in opposite, are included in a non-limiting sense apt to alterations and modifications and within the scope and spirit of the disclosure and appended claims.

### PREFERRED EMBODIMENTS

As highlighted for CMOS generations 130 nm and below is the potential for non-destructive permanent latchup that will destroy digital data or digital control to the electronic system that can't be recovered except by power cycle. As such this is disruptive event and risk to fail safe operations for automation in the IoT generation. SBGR has in this spec shown proofs of the benefits of avoiding latchup trigging in that any CMOS system will not require “power recycle and rebooting” to restore control and performance. SBGR recovery times are orders of magnitude faster with SBGR implemented and prevents latchup triggering.

SBGR prevents latchup triggering by either overvoltage and radiation upset transients for any bias for both core and IO voltages bulk for all CMOS generations, legacy >10 μm to FinFET nodes that operate at extreme temperatures >85° C. to >than 250° C. will not trigger and will not latchup thus providing the highest reliability.

Various industries will benefit from the advancements above for all CMOS device types including: Automotive electronics HT_IC with SBGR, Space satellites RH_IC with SBGR, Missile defense RH_IC with SBGR, Aviation electronics HT_IC with SBGR, and/or High Temperature industrial electronics with SBGR that operate >125 C.

SBGR applied to solar PVC apps to increase both current and power outputs by reducing mobile carrier losses caused by recombination effects, will add to an overall increases the PVC power efficiency

### Example 1

A semiconductor device comprising a substrate region with first type doping impurity with high resistivity and an active area layout region for CMOS inverter that includes shallow trench dielectric isolation and two well contact regions with (1) a first and second photo mask wherein a first SBGR photo mask is aligned to integrated circuit patterned silicon active areas and dielectric regions layout with ion implantation of first p-type impurity to expressly implement a high concentration of p-type impurity with an implant concentration greater than first well impurity concentration in first well contact regions, implemented below dielectric isolation regions and at peak depth extending below dielectric isolation regions and implemented into first well silicon substrate layout regions before first well is implemented and (2) a second SBGR photo mask having a mask opening width smaller than first SBGR mask width which is aligned to first well active area layout regions and dielectric region in first well contact regions and is implanted with p-type impurity at high implant dose implementing a SBGR p-type impurity concentration greater than 1st well impurity concentration and below first well contact regions extending from the silicon surface and below dielectric isolation regions and forming ohmic doping contact with the first SBGR impurity region, below the first well contact regions and select dielectric regions, before first well is implemented that may exceed first well depth and maximum concentration doping level into the silicon substrate concentration region The first well implant mask aligned to first well active area regions where implantations of first impurity type implements a first well impurity region in silicon substrate which includes a shallow buried guard ring fully implemented in first well contact regions and a second well implant mask aligned to first well region active area with multiple implantations of second impurity type implements in the second well region with shallow buried guard ring implemented in first well contact regions.

This Example 1 of a semiconductor device where a shallow buried guard ring (SBGR) impurity structure expressly implemented in first well regions creating a uniquely low resistivity doping shunt region below said first well contact region that acts to prevent forward bias of the 1st well region keeping the thyristor J3 (N+/p− diode) in first well active areas in a reverse bias state by shunting excess hole currents throughout the low resistivity SBGR bypass low R regions to the first well contact region and VSS terminal ground and keeping the J3 diode in reverse bias block state throughout the transient upset thereby deactivating the CMOS parasitic THYRISTOR permanently and preventing latchup while operating in any extreme environment (e.g., radiation particle strike and high temperatures) without permanent failures where the SBGR type 1 conductive region comprises a unique low resistivity vertical implanted region not otherwise present within the first well and where the semiconductor (CMOS inverter) may, but does not necessarily include the following features:
a unique low resistivity conductive region is comprised with ohmic fill materials;
a shallow buried guard ring conductive regions below a first well contact further comprises a conductance over its entire vertical and horizontal extent corresponding to a p-type impurity region concentration greater than 3E17 ions/cm-3 through-out its length;
a first and second well regions exhibiting a SBGR impurity region implemented in first well contact regions, normally manufactured with bulk silicon substrate wafers, is alternatively manufactured with silicon epitaxial layer grown on a bulk silicon wafer and therein formed in the silicon epitaxy layer to manufacture the CMOS inverter devices.
a silicon substrate material with a suitable silicon layer thickness which is bonded to a dielectric insulating material to form a Silicon on Insulator (SOI) wafer substrate including a shallow buried guard ring impurity region in the first well region;
electric coupling to a positive voltage rail by one or all the second well contact regions at the substrate surface terminal;
electric coupling to a negative voltage rail by one or all the second well contact regions at the substrate surface terminal; and
SBGR vertical layer impurity regions formed by high-energy ion implantation (e.g., boron);

Additionally, the semiconductor device as recited in claim above in Example 1 wherein the unique SBGR low resistivity shunt region (i.e., conductive region) comprises a vertical impurity region of the first conductivity type having an impurity concentration that may increase with implantation depth to a local maximum width and length below STI regions in first well and may vary with increasing depth, to form a retrograde impurity concentration of higher magnitude than first well impurity concentration.

The semiconductor device as recited above wherein the SBGR type 1 impurity conductive region implemented in first well contact regions is manufactured using bulk silicon wafers of different diameters.

The SBGR type 1 impurity region described above in Example 1 forming a low resistive, low impedance current bypass path below first well contact regions of a CMOS inverter that conducts excess transient upset currents to the VSS ground terminal thereby preventing latchup triggering, normally caused by high resistivity body biasing in first well, that causes the forward bias of the J3 thyristor diode regions during electrical overvoltage stress in CMOS inverter devices.

This same semiconductor device further exhibiting a SBGR type 1 impurity region forms a low resistive low impedance current path below first well contact regions of a CMOS inverters that conducts excess transient upset currents to the VSS ground terminal thereby preventing latchup triggering normally caused by high resistivity body biasing in first well causing a forward bias of the J3 thyristor diodes during a radiation particle strikes in CMOS inverters devices.

The same semiconductor device further displaying an SBGR type 1 impurity region forming a low resistive low impedance current path below first well contact regions of a CMOS inverters that conducts excess transient upset currents to the VSS ground terminal thereby preventing latchup triggering normally caused by the high resistivity body biasing in first that causes a forward bias of the J3 thyristor diodes operating at higher temperatures greater than 25° C. up to 250° C. and temperatures below −55 C.

### Example 2

A semiconductor device comprising a silicon substrate of first P-type conductivity and including active area regions and dielectric regions exhibiting a first and second photo mask well wherein (a) said first well photo mask is aligned to active areas and with P− impurity type ion implantation implements in a first well impurity doping concentration region that is greater than the silicon substrate which includes a first well contract region where said a first SBGR photo mask is aligned to a first well active area contact regions implanted with P type impurity ions which expressly implements a low resistivity SBGR impurity region that extends below the first well contact region, and below dielectric regions at silicon depth greater than dielectric region depths, implementing an SBGR impurity concentration greater than the first well impurity regions which is extendable below said first well maximum concentration to the silicon substrate concentration region and (b) the second SBGR photo mask has a mask opening diameter width greater than the first SBGR mask diameter width and is aligned to first well active area regions and multi implantations of first impurity that extends the high concentration p-type impurity region within first well contact region silicon surface to deep SBGR doping regions to make ohmic doping contact below the first well contact regions and select dielectric regions. Expressly the second well PR mask is aligned to first well active area and with implantation of n-second impurity type to implements in the second n-well region that is butted to first well and forms the CMOS twin well inverter layout which includes a first well region with a first well contact region that includes a SBGR doping region below first well contact region. Said SBGR doping region may be implemented into all CMOS generations and will prevent latchup triggering and permanent electrical failures in bulk CMOS inverter devices thereafter enabling reliable CMOS inverters and devices that can operate in extreme radiation environments and high temperatures greater than 25 C to 250 C.

The semiconductor device, specifically, illustrates a shallow buried guard ring (SBGR) impurity structure expressly implemented in first well regions creating a uniquely low resistivity doping shunt region below first well contact region that acts to prevent forward bias of the 1^{st} well region that keeping the thyristor J3 (N+/p− diode) in first well active areas in a reverse bias state by shunting excess hole currents throughout the low resistivity SBGR bypass low R regions to the first well contact region and VSS terminal ground and keeping the J3 diode in reverse bias block state throughout the transient upset thereby deactivating the CMOS parasitic thyristor permanently and preventing latchup while operating in any extreme environment without permanent failures.

This SBGR type 1 conductive region comprises a unique low resistivity vertical implanted region not otherwise, present within the first well wherein the unique low resistivity conductive region is comprised with ohmic fill materials where the shallow buried guard ring conductive regions exists below a first well contact which comprises a conductance over its entire vertical and horizontal extent corresponding to a p-type impurity region concentration greater than 3E17 ions/cm-3 through-out its length

The first and second well regions with a SBGR impurity region implemented in first well contact regions are normally manufactured with bulk silicon substrate wafers but may be alternatively manufactured with silicon epitaxial layer grown on a bulk silicon wafer and therein formed in the silicon epitaxy layer to manufacture the CMOS inverter devices wherein the silicon substrate material with a suitable silicon layer thickness is bonded to a dielectric insulating material to form a Silicon on Insulator (SOI) wafer substrate does include a shallow buried guard ring impurity region in the first well region.

As in Example 1, one or all the second well contact regions at the substrate surface terminal may be electrically coupled to a positive voltage rail, a negative voltage rail, or a combination of both. In one embodiment of Example 2, at least one of the Shallow buried guard ring vertical layer impurity regions may be formed by high-energy ion implantation (e.g., boron). Further, the unique SBGR low resistivity shunt region conductive region may also comprises a vertical impurity region of the first conductivity type having an impurity concentration that may increase with implantation depth to a local maximum width and length below STI regions in first well, and varies with increasing depth, forms a retrograde impurity concentration of higher magnitude than first well impurity concentration.

In terms of manufacturing, the SBGR type 1 impurity conductive region implemented in first well contact regions may additionally be manufactured using bulk silicon wafers of different diameters

In operation, the SBGR type 1 impurity region forms a low resistive low impedance current by pass path below first well contact regions of a CMOS inverters that conducts excess transient upset currents to the VSS ground terminal thereby prevents latchup triggering normally caused by high resistivity body biasing in first well that causes the forward bias of the J3 thyristor diode regions during electrical overvoltage stress in CMOS inverter devices and the SBGR impurity region forms a low resistive low impedance current path below first well contact regions of a CMOS inverters that conducts excess transient upset currents to the VSS ground terminal thereby preventing latchup triggering normally caused by high resistivity body biasing in first well that causes a forward bias of the J3 thyristor diodes during a radiation particle strikes in CMOS inverters devices.

Importantly, the SBGR type 1 impurity region forms a low resistive low impedance current path below first well contact regions of a CMOS inverters that conducts excess transient upset currents to the VSS ground terminal thereby preventing latchup triggering normally caused by the high resistivity body biasing in first that causes a forward bias of the J3 thyristor diodes operating at higher temperatures greater than 25° C. up to 250° C. and temperatures below −55° C.

### Example 3

The silicon substrate of first P-type conductivity that includes dielectric oxide regions of certain widths, lengths and depth may be used to form at the silicon substrate surface a photovoltaic (PVC) layout with an anode contact region formed at the silicon surface exhibiting a first photo mask, a second phot mask and a third photo mask. The first photo mask is aligned to an anode contact region and multiple ion implantation of P-type ion impurity to implement a shallow buried guard ring (SBGR) p-type doping region into silicon region or regions below the anode contact region that extends continuously from the silicon surface to or below the maximum depth of the dielectric isolation regions that implements a SBGR region comprising a high concentration p-type doping region, below the PVC anode contact region, with P-type doping impurity concentration >5e17 and, following mask strip and clean, is thermally annealed. The second photo mask aligned to PVC cathode regions and with ion implantation of n-type doping impurity into a PVC cathode layout regions of which some are butted to the anode dielectric regions and extend across the surface to the cathode contact region implementing an n-type doping impurity within the PVC cathode layout regions and forming a junction diode with electric field depletion region between opposite dopant types. The anode and cathode contact regions etch and with metal deposition layer across the PVC wafer. The third photo mask is aligned to anode and cathode contact regions with a metal etch forming the PVC metal layout regions which includes an SBGR PVC low resistivity doping region below the PVC anode contact regions not otherwise present in PVC anode contact regions that increases hole carrier lifetime by forming a low resistivity low hole current impedance transport path to anode metal contact regions with an SBGR PVC.

In this third example, the silicon SBGR PVC device exhibits a shallow buried guard ring (SBGR) impurity structure which is expressly implemented below the anode contact regions at the top of the wafer thereby creating a uniquely low resistivity doping shunt region below the PVC anode contact regions that may extend below the dielectric isolation regions which increases the negative local potential of SBGR silicon doping region, below the anode contact regions, thereby increasing hole current density that is transported to anode metal contact and increases the cathode reverse bias breakdown voltage.

The SBGR PVC silicon device described herein in Example 3 exists wherein the SBGR type 1 conductive region comprises a unique low resistivity vertical implanted region not otherwise, present within PVC devices containing a unique low resistivity conductive region is comprised with multiple or mixture of different ohmic fill materials where conductive regions are present below the PVC anode contact regions further comprising a conductance over its entire vertical and horizontal extent corresponding to a p-type impurity region concentration greater than 3E17 ions/cm-3 through-out its vertical depth extension and layout lengths.

As is seen in Example 1 and 2, the SBGR PVC device of Example 3 may exhibit one or more cathode contact regions located at the substrate surface terminal regions are electrically coupled to a positive voltage rail, one or more anode contact regions at the substrate surface terminal are electrically coupled to a negative voltage rail, or a combination thereof.

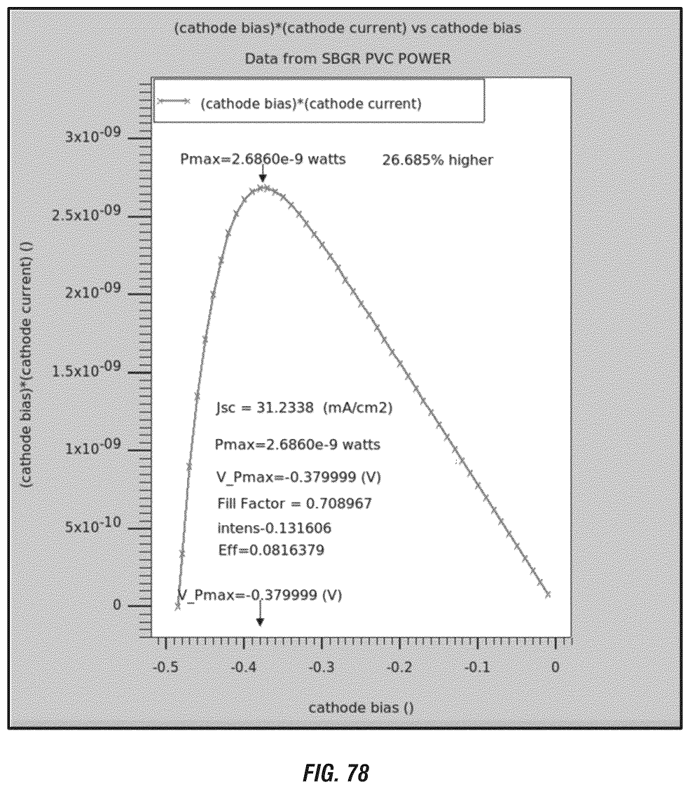

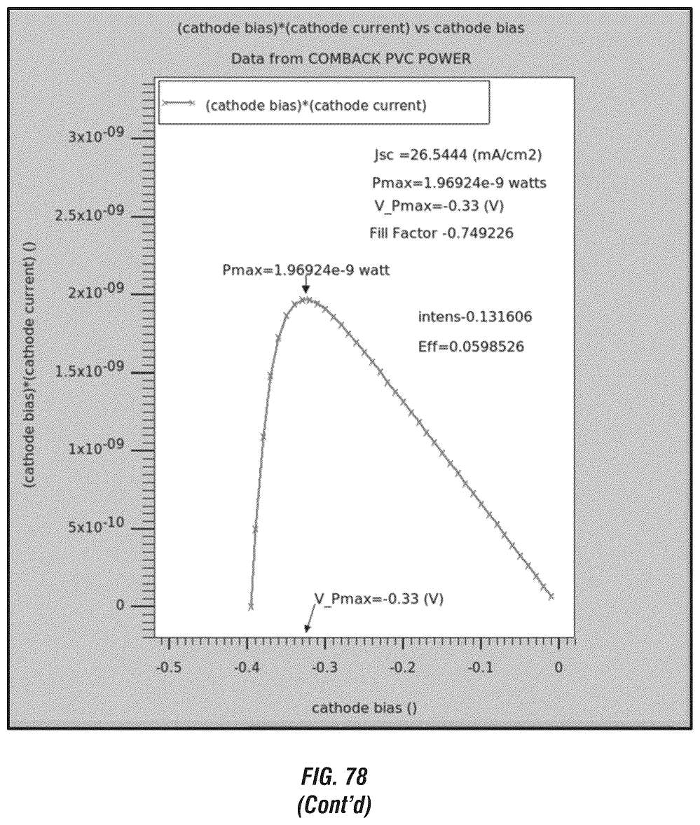

The SBGR PVC device described has at least one of the Shallow Buried Guard Ring vertical impurity regions formed by a high-energy ion implant (e.g., boron) where the first conductivity type has an impurity concentration that may increase with implantation depth to a local maximum widths and lengths below dielectric isolation regions below anode contract regions, and may vary with increasing depth, forming a retrograde p-type impurity concentration. Moreover, the SBGR PVC device as s exemplified is made to exhibit the SBGR p-type impurity conductive region implemented below anode contact regions can be manufactured using bulk silicon wafers with multiple diameters, is effective in collecting mobile hole vacancy carriers at depths greater than 8 microns below the silicon surface and forms a low resistive low impedance current path below the PVC anode contact regions that increases current collection for solar spectrum wavelengths greater than 700 nm and high quantum efficiency (as shown in FIG. 78).

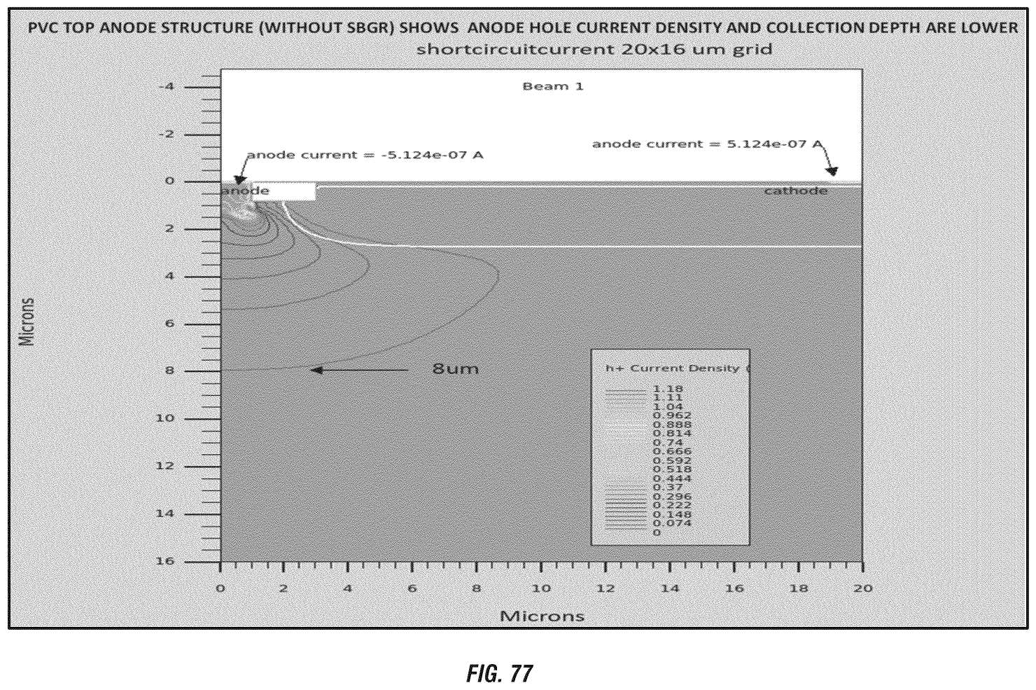

The SBGR PVC device as disclosed forms a low resistive low impedance current path below the PVC anode contact region that (1) increases Pmax peak power output by more than 26% and shown in FIGS. 77 and (2) enables high density hole current transport to anode regions at higher temperatures.

This Example 3 is defined and described below.

### Solar Photovoltaic Cell Applications:

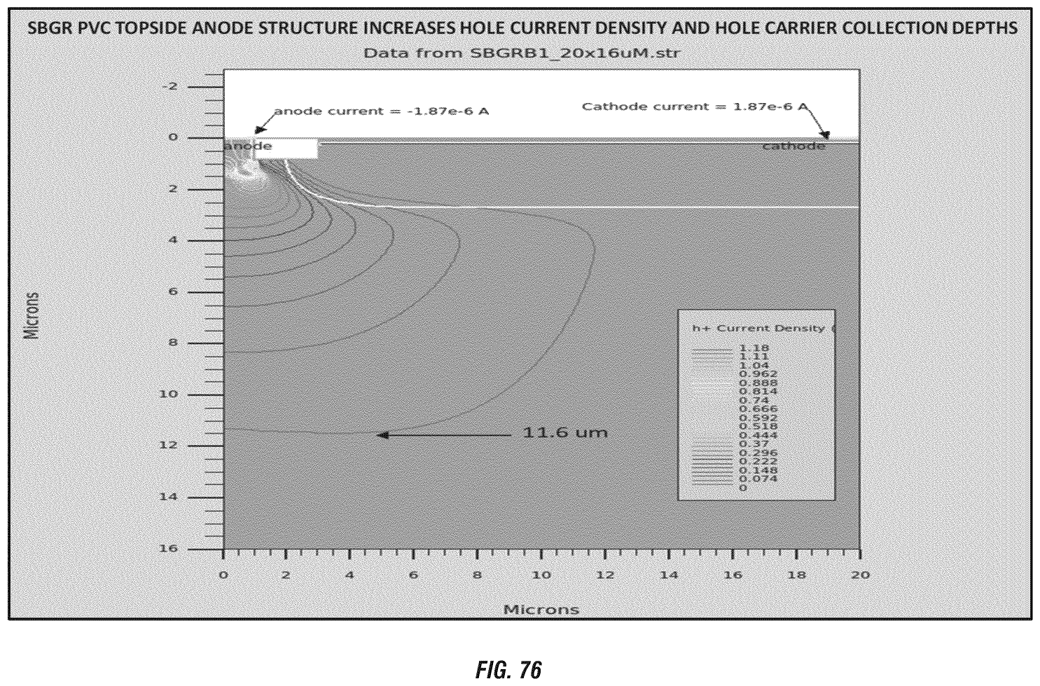

FIG. 76 shows the SBGR photovoltaic cells (PVC) layout that includes STI or other dielectric isolation region and a silicon substrate with SBGR boron doping structure implemented below anode contact region. Cathode diffusion regions are formed with n-type impurity phosphorous doping impurity at a high concentration >1e19 ions/cm3.

Firstly, the SBGR doping structure combined with processing architecture can be applied a new type of PVC that increases both PVC short circuit current and cathode voltage biasing. Larger wafers (increasing silicon area) can used to manufactured SBGR PVC using silicon wafer manufacturing conventional processing to implement the SBGR structure and make a higher performance PVC that is implements below the anode contact region similar to SBGR latchup structure. SBGR increases mobile carrier current by reducing recombination losses from high resistivity effects. Mobile hole charge carriers can be recombined and causes shorter lifetimes which then increases current losses during mobile charge current transport to the anode/cathode metal terminals. Electrons are high mobility charge carriers and flow to nearest positive charge terminal. Hole carriers are “vacancy carriers” and charge transport requires atomic P-type dopants activated into silicon regions to enable increased carrier mobility (transport current) within the silicon lattice by P-type vacancy carriers (hopping). By increasing mobility using SBGR doping impurity implemented below anodes both mobility and voltage biasing is increased to yield more “WATTS” from the SBGR PVC device. Once the charge carrier is collected in metal, recombination ceases and current losses are minimized.

FIG. 77 compares a SBGR PVC Pmax IV plot to a Conventional PVC Pmax IV plot. The IV plots show Pmax watt magnitude is increased by 35% higher for SBGR PVC vs Conventional PVC. The SBGR provides a positive technology effect in several ways, (1) reducing P− RESISTIVITY near anode contacts to enhances hole current transport density which decreases recombination losses and more mobile hole carriers are collected at anode terminal without degradation to electron mobile carrier lifetimes. Total increase in hole current flowing to anode is more than 17% increased and (2) The SBGR “P+ doping effect” acts to negatively increase magnitude of the SBGR region local potential implemented below anode by −0.25 V. This effect increases the PVC diode breakdown voltage and enables higher cathode current bias. The combined effect of increased current (Amps) and increased negative bias (volts) increases Pmax peak power (watts) by >26%.

### SBGR Solar Wavelength Effect

Conventional PVC currents decrease at larger wavelengths >700 nm (IR spectrum) which then shortens the PVC sunlight energy duty cycle as the afternoon solar spectrum shifts to IR wavelengths. SBGR PVC architecture aforementioned (reduces recombination effects) that enables increase current at IR wavelengths to yield more current collection at wavelengths >700 nm and TCAD simulation show increases quantum efficiency of the SBGR PVC vs Conventional PVC. SBGR doping combined with PVC top side dielectric isolation structures increases the PVC diode break down voltage. With the anode PVC terminal increased more negatively (−0.2V) by SBGR doping effect higher hole currents is observed at wavelengths >600 nM. The TCAD simulation also shows the electron current is increased at longer wavelengths (vs conventional that is not increased) due to negative potential in anode and closer proximity acts by field deflection of electrons (oppositely charged HALL effects) to increase transport to cathode terminal within lifetime losses at wavelengths >700 nM figure S3 shows electron current is near 100% overlapped with available current from B1 beam (red) for SBGR case and not for Commercial PVC case.

The Silicon substrate thickness used for manufactured semiconductor devices is approximately 725 microns. For PVC applications the silicon substrate thickness is thinned to 160 microns. Thinning decreases the hole carrier transport distance to the anode contacts formed at the back side of the PVC substrate. PVC substrates are intrinsic which is low p-type doping with high resistivity and imparts low hole carrier mobility that increases hole recombination rate.

The solar spectrum peak intensity is near 800 nM that has a penetration depth of (10 uM), the deepest absorption depth is 1000 nm at IR wavelengths. This means hole carrier transport from the P/N diode generation region to the back side anode contact is transporting thru absorption layers where electrons are being generated that hole carriers would recombine with and not optimum.

Firstly, the SBGR doping structure can be combined with wafer processing techniques used in semiconductors to implement SBGR doping regions below the anode contact region formed at the top of the PVC with a dielectric isolation region that would decrease carrier transport distance to the anode.

FIGS. 76 and 77 show TCAD 2D layouts for top side anode contact regions implemented by forming Shallow Trench Isolation (STI) into the anode contact current regions with SBGR doping implanted into the silicon substrate region that is butted to a dielectric isolation region (non-conductive) used to isolate the anode contact region from the PVC P/N diode regions. FIG. 76 shows the SBGR top side anode contact region that includes SBGR high concentration P-type impurity extending to or below the dielectric contact isolation region. FIG. 77 shows an alternative top side anode contract region with STI regions but does NOT include the SBGR high concentration doping regions implemented below or within the anode contact.

FIG. 77 shows an anode top side contact with dielectric isolation region but does not include the SBGR doping region below the anode contact region. The hole current flow lines extend out from the hole charge collection region below anode to a maximum depth and width is approximately 8 microns. The hole current magnitude collected by the anode contact equals 5.12e-7 A.

FIG. 76 shows the anode top side contact that includes an SBGR doping region below the anode with hole current flow lines from the hole charge collection with maximum depth and width is approximately 11.8 microns and the hole current magnitude collected at the anode equals 1.87e-6 A which is 264.8% higher.

Combining the SBGR doping with a dielectrically isolated top side anode contact region increases the hole current collection volume (area) more than 46% and anode hole current magnitude by more than 260% (1.87e-6 A vs 5.12e-7 A) as is compared in FIGS. 76 and 77 for a Z length of only 100 um. While the % differences remain the same with the SBGR implemented into 300 mm, the Z length=wafer diameter and a PVC anode current would proportionally be increased by Z length, for this example, with a 12 um width that extended to 300 mm (300,000 microns) wafer diameter hole current exceeding 5 mA. Larger 300 mm wafers would increase PVC area and PVC output compatible with semiconductor wafer manufacturing and can be used to manufacture the SBGR PVC.

The photoelectric effect first explained and published by A. Einstein stated electron/hole pair emission will occur in materials whenever irradiated by light or energetic photons. This is also true for heavy ions shown in FIG. 53.

For PVC, the material used is silicon and a single photon can be absorbed with energy transfer that generates a Positive and Negative charge pair in which the negative charge carriers are electrons and mobile positive charge carriers are “vacancy carriers”. Hole charge transport in silicon requires atomic P-type dopants activated in the silicon lattice that increases doping carrier density needed to enhance mobile charge conduction (hole current). By placing the anode contact at the surface, this reduces the hole transport distance between the hole photo generation regions that are collected by the anode terminal contact region before they are recombined with electrons, becoming a neutral charge and reduces PVC hole current losses.

FIG. 78 shows SBGR increasing the cathode bias voltage by more than 22% from −0.4 V to −0.49 Volts compared with the conventional PVC. SBGR PVC also increases Pmax peak power (watts) by more than 26% vs a commercial backside anode PVC where SBGR PVC having increased Pmax by more than 26% and short circuit current by more than 22% would thereby increase solar PVC efficiency.

### SBGR Solar Wavelength Effects

Conventional PVC current output decrease at larger wavelengths >700 nm (IR spectrum) which shortens the PVC sunlight duty cycle as the peak solar spectrum shifts to longer wavelengths. SBGR PVC architecture is shown increase anode current by decreasing transport current path to top side anode and increasing extraction volume regions.

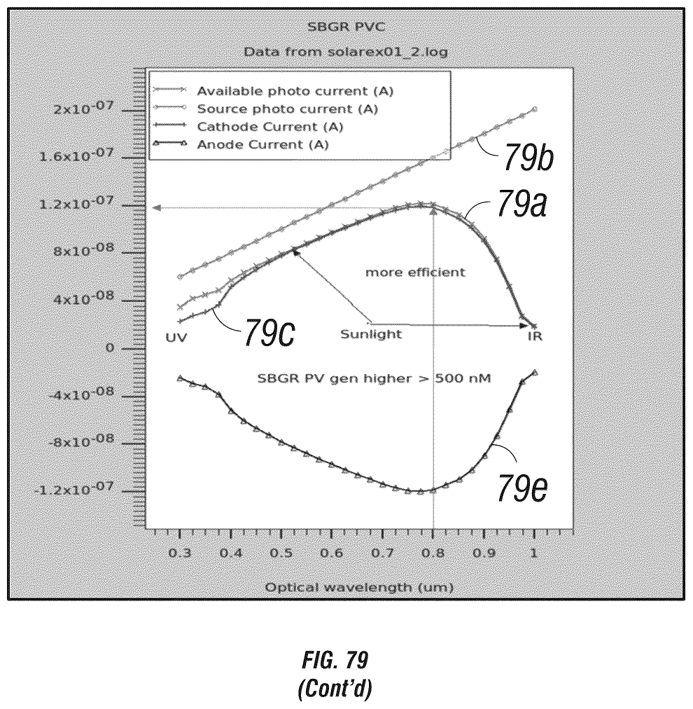

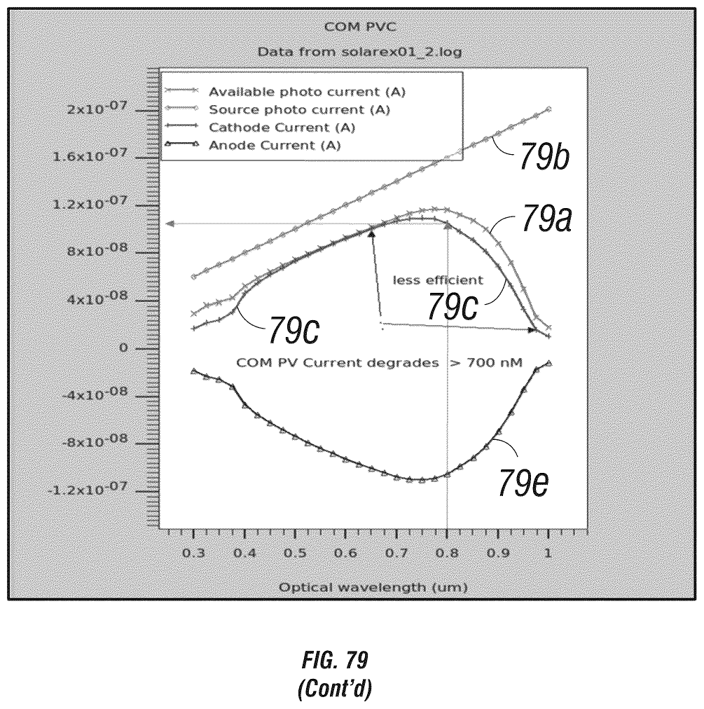

FIG. 79 characterizes a commercial PVC anode current vs SBGR PVC anode current vs spectrum wavelength from 300 nm to 1000 nm. The right-side plot in FIG. 79 compares a commercial PVC backside anode current and positive cathode current vs the SBGR PVC (left-side plot). The data shows decreases in current for the commercial PVC beginning at 700 nm and decreasing current at longer wavelength is plotted whereas the SBGR PVC anode and cathode currents do not decrease at any wave length. SBGR PVC when compared to available photo current is near unity (100%) throughout the spectrum 400 nm to 1000 nm to be exact. The reason is because longer wavelengths are absorbed at deeper silicon depths. FIG. 76 shows the SBGR PVC hole currents originating from or below 11.8 microns which are being conducted to the SBGR anode. At this silicon depth, spectrum wavelengths that are absorbed are in the 800-1000 nm long wavelength IR range.

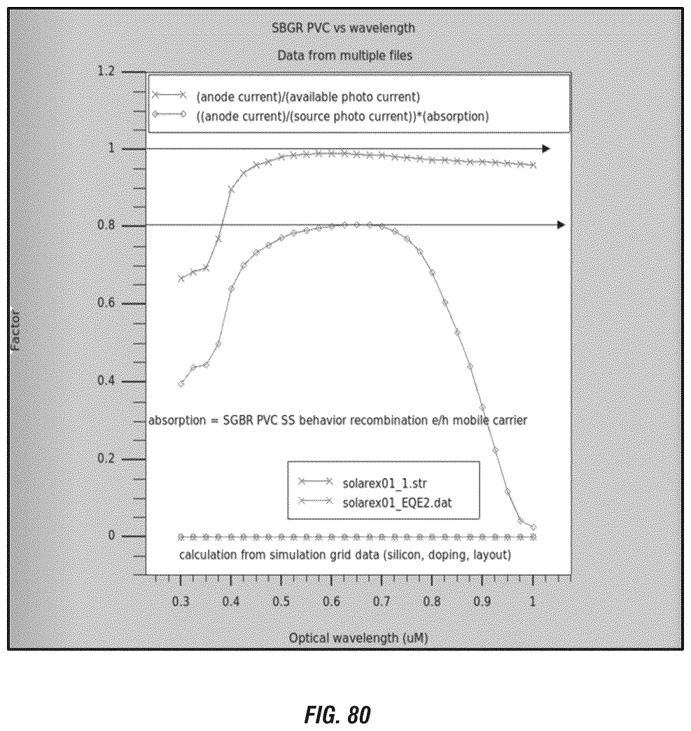

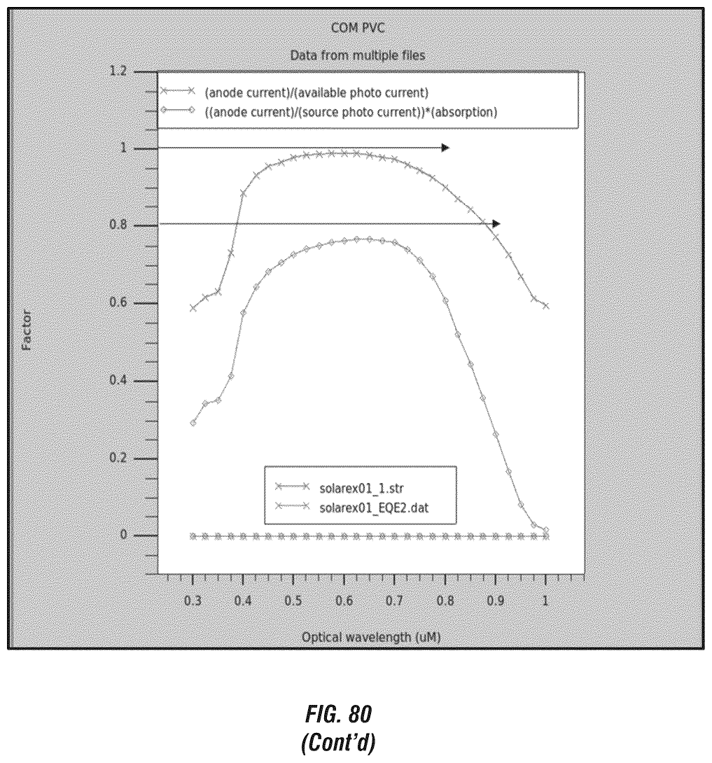

FIG. 80 shows the simulation of the SBGR PVC. The top curve plots the ratio of anode current/available photo current which is the quantum efficiency vs the solar wavelength spectrum between 300 nM to 1000 nM. The SBGR PVC quantum efficiency is plotted on the left side and shows small decrease in quantum efficiency at wavelengths greater than 700 nM to 1000 nM full spectrum. In contrast, the commercial PVC (right side plot) shows Quantum efficiency sharp declines beginning at wavelengths >650 which is less than 0.6 ratio at 1000 nm. In contrast SBGR PVC quantum efficiency is maintained near 95% for solar wavelengths from 425 nM up to 1000 nM. SBGR applied to solar PVC applications increases both current and power output by reducing mobile carrier losses caused by recombination effects. Hole currents are more sensitive to recombination due to low mobility where SBGR is implemented in top side anode increasing the SBGR PVC anode currents and power output.

This detailed description refers to specific examples in the drawings and illustrations. These examples are described in sufficient detail to enable those skilled in the art to practice the inventive subject matter. These examples also serve to illustrate how the inventive subject matter can be applied and amendable to various purposes or embodiments. Other embodiments are included within the inventive subject matter, as logical, mechanical, electrical, and other changes can be made to the example embodiments described herein. Features of various embodiments described above, however essential to the example embodiments in which they are incorporated, do not limit the inventive subject matter as a whole, and any reference to the invention, its elements, operation, and application are not limiting as a whole, but serve only to define these example embodiments. Thus, the scope of this disclosure should be determined by the appended claims, in light of the present disclosure, along with their legal equivalents. All structural and functional equivalents to the elements of the above-described invention(s) will be known to a person having ordinary skill in the art and are expressly incorporated herein by reference as is to be read into the present claims. This detailed description does not, therefore, limit embodiments of the invention, which are defined only by the appended claims. Each of the embodiments described herein are contemplated as falling within the inventive subject matter, which is set forth in the following claims.

1. A semiconductor device comprising:
a silicon substrate region with first type doping impurity
said substrate region exhibiting a high resistivity, active area layout region CMOS inverter that includes shallow trench dielectric isolation or dielectric isolation regions and two well contact regions;
said two well contact regions comprising a first PWELL (VSS anode) contact region and a second NWELL (VDD cathode) contact region;
a first Shallow Buried Guard Ring (SBGR) structure
said SBGR structure masked over a photoresist comprising aligned to an integrated circuit patterned silicon active area and dielectric regions layout;
said SBGR structure constructed of an ion implantation of a first p-type impurity to expressly implement a high concentration of p-type impurity;
said SBGR structure displaying an implant impurity concentration greater than a first well impurity concentration in surrounding first well contact region or plurality of regions implemented below dielectric isolation regions;
said SBGR structure implemented into said first well silicon substrate layout region or plurality of regions before said first well is implemented;
a second SBGR;
said second SBGR structure over a photoresist having a mask opening width smaller than first SBGR mask width;
said second SBGR structure aligned to said first well active area layout regions, dielectric region in said first well contact region or regions;
said second SBGR structure implanted with p-type impurity at high implant dose implementing a SBGR p-type impurity concentration greater than said first well impurity concentration;
said second SBGR structure existing below said first well contact region or plurality of regions that extends from the silicon surface to below a dielectric isolation region or plurality of regions;
said second SBGR structure forming ohmic doping contact with the first SBGR impurity region below said first well contact region or plurality of regions, select dielectric regions, or both;
said second SBGR structure that may exceed said first well depth and doping concentration in the silicon substrate concentration region;
said first SBGR structure aligned to said first well active area region or plurality of regions and implantations of said first impurity type implements in a first well impurity region in said silicon substrate region exhibiting a SBGR structure implemented in said first well contact region or plurality of regions; and
said second well structure aligned to second well region active area with implantations of second impurity type implements in the second well region;

2. The semiconductor device of claim 1 wherein the shallow buried guard ring impurity structure is implemented in said first well region or plurality of regions creating a low resistivity doping shunt region below said first well contact region that acts to prevent forward bias of said first well region;
said SBGR structure establishing a reverse bias state in the thyristor J3 diode by shunting excess hole currents throughout the low resistivity SBGR bypass to the VSS terminal, low resistivity regions to said first well contact region and keeping the thyristor in reverse bias block state throughout a transient upset thereby deactivating the CMOS parasitic thyristor and thereby preventing latchup while operating in extreme temperatures, radiation, or both, without latchup or permanent failure.

3. The semiconductor device of claim 2 wherein said device operating in a range between-55° C. to 250° C.

4. The semiconductor device as recited in claim 2 wherein said SBGR structure conductive region comprises a low resistivity vertical implanted impurity region doping impurity concentration >5e17.

5. The semiconductor device as recited in claim 4 wherein the low resistivity conductive region is comprised of ohmic fill materials.

6. The semiconductor device of claim 5 wherein the shallow buried guard ring conductive regions below said first well contact region further comprises a conductance over an area corresponding to a p-type impurity region concentration greater than 5E17 ions/cm-3.

7. The semiconductor device of claim 1 where CMOS inverters are created with said first and second well regions exhibiting a SBGR impurity region implemented in said first well contact regions are-manufactured with a bulk silicon substrate or a silicon epitaxial layer grown on a bulk silicon wafer formed into said silicon epitaxy layer to manufacture the CMOS inverter devices that include SBGR impurity regions in first well contact regions.

8. The semiconductor device of claim 7 wherein said SBGR impurity, conductive region implemented in said first well contact regions is manufactured using bulk silicon wafers of different diameters

9. The semiconductor device of claim 1 wherein said silicon substrate material is constructed of a silicon epitaxial layer of certain thickness bonded to a dielectric insulating material to form a silicon on insulator (SOI) wafer and within the silicon epitaxial layer a CMOS inverter layout is formed that includes dielectric regions and first well with a first well contact region and a second well with said second well contact region and said shallow buried guard ring p-type impurity region is implemented below first well contact regions.

10. The semiconductor device of claim 1 wherein at least one of the shallow buried guard ring vertical layer impurity regions is formed by high-energy ion implantation.

11. The semiconductor device of claim 10 wherein said high-energy ion implantation is boron.

12. The semiconductor device as recited in claim 2 wherein said second SBGR low resistivity shunt region comprises a vertical impurity region having an impurity concentration that may increase with implantation depth to a local maximum width and length below STI regions in first well, varying with increasing depth, to form a retrograde impurity concentration of higher magnitude than said first well impurity concentration.

13. A semiconductor CMOS twin well inverter layout comprising: a silicon substrate of first P-type conductivity, a first well with first well contact regions, a second well with second well contact regions, dielectric regions, and one to a plurality of SBGR doped regions implemented in the first well contact region;
said CMOS twin well inverter layout which includes said first well region with a first well contact region and said second well region with a second well contact region;
said first well contact region exhibiting a shallow buried guard ring (SBGR) structure masked over a photoresist;
said first well contact region implanted with a high concentration, impurity P+ doped region;
said first well impurity doped region having doping concentration region greater than the silicon substrate;
said first well contact SBGR structure extending below said first well contact region and below dielectric regions at a silicon depth greater than dielectric region depths implementing an SBGR impurity concentration greater than the first well impurity regions;
said SBGR structure aligned to first well active area regions that extends the high concentration p-type impurity region within first well contact region silicon surface to said first SBGR structure doping regions to make ohmic doping contact below the first well contact regions and select dielectric regions;
said second contact region aligned to said first well active area and with implantation of second impurity concentration implemented in said second contact region that is butted to said first well region;
said SBGR ring impurity structure implemented in said first well region or plurality of regions creating a low resistivity doping shunt conductive region below said first well contact region that acts to prevent forward bias in said first well active areas in a reverse bias state by shunting excess hole currents throughout the low resistivity SBGR bypass regions to said first well contact region and VSS terminal preventing latchup; and
said second contact region exhibiting a SBGR doping region below first well contact region to prevent latchup triggering and permanent electrical failures in bulk CMOS inverter devices enabling CMOS inverters and devices that can operate in extreme radiation environments and high temperatures ranging from negative 55° C. to 250° C.

14. The semiconductor CMOS twin well inverter layout of claim 13 wherein said P+ doped region doping agent is boron high-energy ion implantation.

15. The semiconductor CMOS twin well inverter layout of claim 14 wherein well doping concentration is in the range of doping impurity concentration >1e17 to less than 8e17.

16. The semiconductor CMOS twin well inverter layout in claim 13 wherein the unique low resistivity conductive region is comprised with ohmic fill materials.

17. The semiconductor CMOS twin well inverter layout of claim 13 wherein said SBGR conductive further comprises a conductance corresponding to a p-type impurity region concentration greater than 3E17 ions/cm-3.

18. The semiconductor CMOS twin well inverter layout of claim 13 wherein the first and second well regions and with a SBGR impurity region implemented below first well contact regions are manufactured with bulk silicon substrate wafers, manufactured with silicon epitaxial layer grown on a bulk silicon wafer, or a combination thereof to manufacture said CMOS inverter layouts.

19. The semiconductor CMOS twin well inverter layout of claim 13 wherein said silicon substrate material is of a silicon layer thickness bonded to a dielectric insulating material to form a silicon on Insulator (SOI) wafer substrate including said shallow buried guard ring impurity region in the first well contact region.

20. The semiconductor CMOS twin well inverter layout as recited in claim 13 wherein the unique SBGR low resistivity shunt region comprises a vertical impurity region having an impurity concentration that may increase with implantation depth below STI regions in said first well, varying with increasing depth, to form a retrograde impurity concentration of higher magnitude than said first well impurity concentration.

21. A PVC semiconductor device having a silicon substrate of P-type conductivity that includes dielectric oxide regions formed at a silicon substrate surface defining a photovoltaic cell (PVC) layout with an anode contact region, a cathode contact region and dielectric isolation regions formed at the silicon surface and a third aligned region formed at a metal deposition layer across a silicon surface comprising;
a first photo mask aligned to said anode contact region;
multiple ion implantation of P-type ion impurity to implement a shallow buried guard ring (SBGR) p-type doping region into a silicon substrate region;
said silicon substrate region exhibited below said anode contact region and extending continuously from said silicon substrate surface to or below the maximum depth of the dielectric isolation regions;
said SBGR p-type doping region existing below said PVC anode contact region;
said p-type doping impurity concentration equal to or above >5e17 following mask strip and thermally annealed;
a second photo mask aligned to said PVC cathode regions;
and ion implantations of n-type phosphorous doping impurity into the PVC cathode layout regions;
cathode doping regions being butted to the anode dielectric regions and extend across the surface to the cathode contact region;
said cathode regions implementing an n-type doping impurity within the PVC cathode layout regions and forming a junction diode with electric field depletion region between opposite dopant types;
said anode and cathode contact regions etched with metal deposition layer across said PVC wafer; and
a third photo mask aligned to anode and cathode contact regions;
said third photo mask defining metal etch regions across said PVC metal layout regions including an SBGR PVC low resistivity doping region below the PVC anode contact regions increasing hole carrier lifetime by forming a low resistivity low hole current impedance transport path to anode metal contact regions with an SBGR impregnated PVC.

22. The PVC semiconductor device as recited in claim 21 wherein the shallow buried guard ring impurity structure is implemented below the anode contact regions formed at the surface of the wafer thereby creating a low resistivity doping shunt region below the PVC anode contact region or regions that may extend below the dielectric isolation regions which increases the negative local potential of SBGR silicon doping region below the anode contact regions, thereby increasing hole current density that is transported to anode metal contact and increases the cathode reverse bias breakdown voltage.

23. The PVC semiconductor device of claim 21 wherein the shallow buried guard ring conductive regions below the PVC anode contact regions further comprises a conductance over its entire vertical and horizontal extent corresponding to a p-type impurity region concentration greater than 3E17 ions/cm-3 through-out its vertical depth extension and layout lengths.

24. The PVC semiconductor device of claim 23 wherein at least one of the SBGR vertical impurity regions are formed by a high-energy ion implant in the form of boron.

25. The PVC semiconductor device as recited in claim 21 wherein the unique SBGR low resistivity shunt region comprises an impurity conductive region having an impurity concentration that increases with implantation depth below dielectric isolation regions below anode contract regions, varying with increasing depth, and forming a retrograde p-type impurity concentration.

26. The PVC semiconductor device as recited in claim 21 wherein the SBGR is effective in collecting mobile hole vacancy carriers at depths greater than 8 microns below the silicon surface.

27. The PVC semiconductor device as recited in claim 21 wherein the SBGR impurity region forms a low resistive, low impedance current path below the PVC anode contact regions that increases current collection for solar spectrum wavelengths greater than 700 nm.

28. The PVC semiconductor device as recited in claim 21 wherein the SBGR impurity region forms a low resistive low impedance current path below the PVC anode contact region that increases Pmax peak power output by more than 26%.

29. The PVC semiconductor device as recited in claim 21 wherein the SBGR type 1 impurity region forms a low resistive low impedance current path below the PVC anode contact that enables high density hole current transport to anode regions at temperatures ranging from −55° C. to 250° C.
